(19) United States
(12) Patent Application Publication
(10) Pub. No.: US 2026/0136618 A1
(43) Pub. Date: May 14, 2026

(54) METHOD FOR FORMING METAL OXIDE LAYER

(71) Applicant: Semiconductor Energy Laboratory Co., Ltd., Atsugi-shi (JP)

(72) Inventors: Masami JINTYOU, Shimotsuga (JP); Junichi KOEZUKA, Tochigi (JP); Yasutaka NAKAZAWA, Tochigi (JP)

(21) Appl. No.: 19/371,154

(22) Filed: Oct. 28, 2025

(30) Foreign Application Priority Data
Nov. 8, 2024 (JP) 2024-195959

(51) Int. Cl. H10D 62/40; H01L 21/02; H01L 21/465; H10D 30/01; H10D 30/67; H10D 86/60

(52) U.S. Cl. CPC H10D 62/405; H10D 30/0314; H10D 30/0318; H10D 30/6728; H10D 30/6731; H10D 30/6736; H10D 30/6755; H10D 30/6757; H10D 86/60; H10P 14/22; H10P 14/3802; H10P 14/3806; H10P 50/20; H10P 52/00; H10P 95/70

(57) ABSTRACT

A method for forming a metal oxide layer with high carrier mobility. The method for forming a metal oxide layer includes a first step of forming a first amorphous film, a second step of forming a first crystallized film from the first amorphous film by first heat treatment, a third step of removing a part of the first crystallized film by wet etching to form a seed crystal layer, a fourth step of forming a second amorphous film over the seed crystal layer, and a fifth step of forming a second crystallized film from the second amorphous film by second heat treatment. Each of the first amorphous film, the first crystallized film, the seed crystal layer, the second amorphous film, and the second crystallized film includes indium and oxygen. The first crystallized film includes crystal grains having random orientations. The seed crystal layer has a first crystal orientation with respect to a formation surface. The second crystallized film is formed of crystal grains having the first crystal orientation.

### BACKGROUND OF THE INVENTION

### 1. Field of the Invention

One embodiment of the present invention relates to a metal oxide layer, a transistor, a semiconductor device, a display device, a memory device, and an electronic device. One embodiment of the present invention relates to a method for forming a metal oxide layer, a method for forming a transistor, and a method for manufacturing a semiconductor device.

Note that one embodiment of the present invention is not limited to the above technical field. Examples of the technical field of one embodiment of the present invention include a semiconductor device, a display device, a light-emitting apparatus, a power storage device, a memory device, a lighting device, an input device (e.g., a touch sensor), an input/output device (e.g., a touch panel), an electronic device including any of them, a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, a display device with high definition has been required. vices for virtual reality (VR), augmented reality (AR), substitutional reality (SR), or mixed reality (MR) are given as examples of devices requiring high-definition display devices and have been actively developed.

Examples of the display device include a display device including a liquid crystal element and a display device including a light-emitting element (also referred to as a light-emitting device). Examples of the light-emitting element include an organic electroluminescent (EL) element and a light-emitting diode (LED). Patent Document 1 discloses a high-definition display device including an organic EL element.

A technique relating to a transistor using a semiconductor thin film has attracted attention. The transistor is used in a wide range of electronic devices such as integrated circuits (ICs) or display devices. As semiconductor materials usable for the transistor, silicon-based semiconductor materials have been widely known, but oxide semiconductors (OSs, also referred to as metal oxides) have been attracting attention as alternative materials.

Examples of an oxide semiconductor that can be used in a transistor include an indium oxide (also referred to as InO_{X}) and an indium gallium zinc oxide (also referred to as In—Ga—Zn oxide or IGZO). Non-Patent Document 1 and Non-patent Document 2 each disclose a thin film transistor including an indium oxide.

### REFERENCE

### Patent Document

[Patent Document 1] International Publication No. 2016/038508

### Non-Patent Document

[Non-Patent Document 1] Dhananjay & Chu, C. W. Realization of In₂O₃ thin film transistors through reactive evaporation process. Appl. Phys. Lett. 91, 1-4 (2007).
[Non-Patent Document 2]Y. Magari et al., “High-mobility hydrogenated polycrystalline In₂O₃ (In₂O₃:H) thin-film transistors”, nature COMMUNICATIONS, 13, 1078 (2022).
[Non-Patent Document 3] Takashi Koida, “High-mobility transparent conductive film”, National Institute of Advanced Industrial Science and Technology, AIST Photovoltaic Technology Research Symposium 2019, Internet URL: https.//unit.aist.go.jp/rpd-envene/PV/ja/results/2019/oral/T13.pdf.

### SUMMARY OF THE INVENTION

An object of one embodiment of the present invention is to provide a metal oxide layer with high carrier mobility. Another object of one embodiment of the present invention is to provide a metal oxide layer formed of crystal grains with uniform crystal orientations. Another object of one embodiment of the present invention is to provide a novel metal oxide layer. Another object of one embodiment of the present invention is to provide a transistor, semiconductor device, display device, or memory device including the metal oxide layer. Another object of one embodiment of the present invention is to provide a transistor having high field-effect mobility. Another object of one embodiment of the present invention is to provide a transistor with a high on-state current. Another object of one embodiment of the present invention is to provide a semiconductor device, display device, or memory device with a high operation speed.

Another object of one embodiment of the present invention is to provide a method for forming a metal oxide layer with high carrier mobility. Another object of one embodiment of the present invention is to provide a method for forming a metal oxide layer formed of crystal grains with uniform crystal orientations. Another object of one embodiment of the present invention is to provide a method for forming a novel metal oxide layer. Another object of one embodiment of the present invention is to provide a method for forming a transistor or semiconductor device including the metal oxide layer. Another object of one embodiment of the present invention is to provide a method for forming a transistor having high field-effect mobility. Another object of one embodiment of the present invention is to provide a method for forming a transistor with a high on-state current.

Note that the description of these objects does not preclude the existence of other objects. One embodiment of the present invention does not necessarily achieve all of these objects. Other objects can be derived from the description of the specification, the drawings, and the claims.

One embodiment of the present invention is a method for forming a metal oxide layer, including a first step of forming a first amorphous film, a second step of forming a first crystallized film from the first amorphous film by first heat treatment, a third step of removing a part of the first crystallized film by wet etching to form a seed crystal layer, a fourth step of forming a second amorphous film over the seed crystal layer, and a fifth step of forming a second crystallized film from the second amorphous film by second heat treatment. Each of the first amorphous film, the first crystallized film, the seed crystal layer, the second amorphous film, and the second crystallized film includes indium and oxygen. The first crystallized film includes crystal grains having random orientations. The seed crystal layer has a first crystal orientation with respect to a formation surface. The second crystallized film is formed of crystal grains having the first crystal orientation.

In the above, each of the first amorphous film and the second amorphous film is preferably formed by a sputtering method in an atmosphere containing oxygen and hydrogen at a substrate temperature higher than or equal to 25° C. and lower than or equal to 140° C. Each of the first heat treatment and the second heat treatment is preferably performed in an atmosphere containing one or both of nitrogen and oxygen at a temperature higher than or equal to 150° C. and lower than or equal to 650° C. The wet etching is preferably performed using one or more of phosphoric acid, oxalic acid, nitric acid, and hydrochloric acid.

In the above, it is preferable that the first crystal orientation be <111> and that the second crystallized film have a crystal orientation of <111> with respect to a top surface of the seed crystal layer.

Another embodiment of the present invention is a transistor including a metal oxide layer formed by the above-described method for forming a metal oxide layer, an insulating layer, and a conductive layer. The metal oxide layer includes a region overlapping with the conductive layer with the insulating layer therebetween. The metal oxide layer is configured to serve as a channel formation region of the transistor. The insulating layer is configured to serve as a gate insulating layer of the transistor. The conductive layer is configured to serve as a gate electrode of the transistor.

With one embodiment of the present invention, a metal oxide layer with high carrier mobility can be provided. With one embodiment of the present invention, a metal oxide layer formed of crystal grains with uniform crystal orientations can be provided. With one embodiment of the present invention, a novel metal oxide layer can be provided. With one embodiment of the present invention, a transistor, semiconductor device, display device, or memory device including the metal oxide layer can be provided. With one embodiment of the present invention, a transistor having high field-effect mobility can be provided. With one embodiment of the present invention, a transistor with a high on-state current can be provided. With one embodiment of the present invention, a semiconductor device, display device, or memory device with a high operation speed can be provided.

With one embodiment of the present invention, a method for forming a metal oxide layer with high carrier mobility can be provided. With one embodiment of the present invention, a method for forming a metal oxide layer formed of crystal grains with uniform crystal orientations can be provided. With one embodiment of the present invention, a method for forming a novel metal oxide layer can be provided. With one embodiment of the present invention, a method for forming a transistor or semiconductor device including the metal oxide layer can be provided. With one embodiment of the present invention, a method for forming a transistor having high field-effect mobility can be provided. With one embodiment of the present invention, a method for forming a transistor with a high on-state current can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A to 1C are perspective views illustrating a method for forming an indium oxide layer.

FIGS. 2A1 and 2B1 are perspective views illustrating a method for forming an indium oxide layer. FIGS. 2A2 and 2B2 are cross-sectional views illustrating the method for forming the indium oxide layer.

FIG. 3 is a flow chart showing a method for forming an indium oxide layer.

FIGS. 4A and 4B show the dependence of the Hall mobility on the carrier concentration.

FIG. 4C is a cross-sectional view illustrating an indium oxide film.

FIGS. 5A to 5C illustrate a crystal structure of an indium oxide.

FIG. 6A is a plan view illustrating an example of a transistor. FIGS. 6B and 6C are cross-sectional views illustrating the example of the transistor.

FIG. 7A is a plan view illustrating an example of a transistor. FIG. 7B is a cross-sectional view illustrating the example of the transistor.

FIG. 8A is a cross-sectional view illustrating an example of a transistor. FIG. 8B is a perspective view illustrating the example of the transistor.

FIG. 9A is a plan view illustrating an example of a transistor. FIGS. 9B and 9C are cross-sectional views illustrating the example of the transistor.

FIGS. 10A to 10C are perspective views illustrating examples of a transistor.

FIGS. 11A to 11C are cross-sectional views illustrating an example of a method for forming a transistor.

FIGS. 12A to 12C are cross-sectional views illustrating the example of the method for manufacturing the transistor.

FIGS. 13A to 13C are cross-sectional views illustrating the example of the method for manufacturing the transistor.

FIGS. 14A to 14C are cross-sectional views illustrating the example of the method for manufacturing the transistor.

FIG. 15 is a block diagram of a display device.

FIGS. 16A to 16C are circuit diagrams illustrating structure examples of a pixel circuit.

FIGS. 17A to 17C are circuit diagrams illustrating structure examples of a pixel circuit.

FIG. 18 is a block diagram illustrating a structure example of a semiconductor device.

FIGS. 19A to 19E each illustrate a circuit structure example of a memory cell.

FIGS. 20A to 20C each illustrate a circuit structure example of a memory cell.

FIGS. 21A and 21B each illustrate an example of an electronic component.

FIGS. 22A to 22C each illustrate an example of a large computer. FIG. 22D illustrates an example of a device for space. FIG. 22E illustrates an example of a storage system that can be used in a data center.

FIGS. 23A to 23F illustrate examples of electronic devices.

FIGS. 24A to 24G illustrate examples of electronic devices.

FIGS. 25A to 25F illustrate examples of electronic devices.

FIGS. 26A to 26D are surface SEM images of indium oxide layers in Example.

FIG. 27A is a surface SEM image of an indium oxide layer in Example. FIG. 27B shows the EBSD measurement results of the indium oxide layer in Example.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Ordinal numbers such as “first” and “second” in this specification and the like are used in order to avoid confusion among components. Thus, the terms do not limit the number of components or the order of components (e.g., the order of steps or the stacking order of layers). A term without an ordinal number in this specification and the like may be described with an ordinal number in a claim in order to avoid confusion among components. A term with an ordinal number in this specification and the like may be described with a different ordinal number in a claim. A term with an ordinal number in this specification and the like may be described without an ordinal number in a claim.

In this specification, the drawings, and the like, when a plurality of components are denoted by the same reference numeral, and, particularly when they need to be distinguished from each other, identification signs such as “_1”, “[n]” or “[m,n]” are sometimes added to the reference numeral, for example. When matters common to a plurality of components with identification signs are described or they do not need to be distinguished from each other, no identification sign is added in some cases.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

A transistor is a kind of semiconductor element and enables amplification of current or voltage, switching operation for controlling conduction or non-conduction, and the like. A transistor in this specification includes, in its category, an insulated-gate field effect transistor (IGFET) and a thin film transistor (TFT).

The functions of a “source” and a “drain” are sometimes replaced with each other when a transistor of different polarity is used or when the direction of current flow is changed in circuit operation, for example. Thus, the terms “source” and “drain” can be used interchangeably in this specification and the like. Note that the source and the drain of a transistor can also be referred to as a source terminal and a drain terminal or a source electrode and a drain electrode, for example, as appropriate depending on the situation.

The expression “connection” in this specification includes “electrical connection”, for example. Note that the expression “electrical connection” is used in some cases to specify the connection relation of a circuit element as an object. The term “electrical connection” includes “direct connection” and “indirect connection”. The expression “A and B are directly connected” means that A and B are connected to each other without a circuit element (e.g., a transistor or a switch; a wiring is not a circuit element) therebetween. By contrast, the expression “A and B are indirectly connected” means that A and B are connected to each other with at least one circuit element therebetween. Note that A and B each denote an object such as an element, a circuit, a wiring, an electrode, a terminal, a semiconductor layer, or a conductive layer.

For example, assuming that a circuit including A and B is in operation, the circuit can be specified as “A and B are indirectly connected” as an object when electric signal transmission and reception or electric potential interaction between A and B occurs at some point during the operation period of the circuit. Note that even when neither electric signal transmission and reception nor electric potential interaction between A and B occurs at some point during the operation of the circuit, the circuit can be specified as “A and B are indirectly connected” as long as electric signal transmission and reception or electric potential interaction between A and B occurs at another point during the operation period of the circuit.

Examples of the case where the expression “A and B are indirectly connected” can be used include the case where A and B are connected to each other through a source and a drain of at least one transistor. By contrast, examples of the case where the expression “A and B are indirectly connected” cannot be used include the case where an insulator is present on the path from A to B. Specific examples thereof include the case where a capacitor is connected between A and B and the case where a gate insulating film of a transistor or the like is present between A and B. In such cases, the expression “a gate (A) of a transistor and a source or a drain (B) of the transistor are indirectly connected” cannot be used.

Another example of the case where the expression “A and B are indirectly connected” cannot be used is the case where a plurality of transistors are connected through their sources and drains on the path from A to B and a constant electric potential V is supplied from a power source, GND, or the like to a node between one of the transistors and another one of the transistors.

Unless otherwise specified, an on-state current in this specification and the like refers to a drain current (also referred to as Id) of a transistor in an on state (also referred to as a conduction state). Unless otherwise specified, the on state of an n-channel transistor means that a voltage between its gate and source (also referred to as V_{g} or V_{gs}) is higher than or equal to the threshold voltage (also referred to as Vth), and the on state of a p-channel transistor means that V_{g} or V_{gs} is lower than or equal to Vth.

Unless otherwise specified, an off-state current in this specification and the like refers to a leakage current between a source and a drain generated when a transistor is in an off state (also referred to as a non-conduction state or a cutoff state). Unless otherwise specified, the off state of an n-channel transistor means that a voltage between its gate and source is lower than the threshold voltage, and the off state of a p-channel transistor means that V_{g} or V_{gs} is higher than Vth.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The term “substantially perpendicular” indicates that the angle formed between two straight lines is greater than or equal to 600 and less than or equal to 120°.

In this specification and the like, a top surface shape of a component means the outline of the component in a plan view (a top view). A plan view means that the component is observed from a direction normal to a surface where the component is formed or from a direction normal to a surface of a support (e.g., a substrate) where the component is formed.

In this specification and the like, the expression “having the same top surface shape” or “having substantially the same top surface shapes” means that the outlines of stacked layers at least partly overlap with each other. For example, the case of processing an upper layer and a lower layer with the use of the same mask pattern or mask patterns that are partly the same is included. The expression “having the same top surface shape” or “having substantially the same top surface shapes” also sometimes includes the case where the outlines do not completely overlap with each other; for instance, the edge of the upper layer may be positioned on the inner side or the outer side of the edge of the lower layer. The state of “having the same top surface shape” or “having substantially the same top surface shapes” can be rephrased as the state where “end portions are aligned with each other” or “end portions are substantially aligned with each other”.

In this specification and the like, the term “island shape” refers to a state where two or more layers formed using the same material in the same step are physically separated from each other. For example, the term “island-shaped metal oxide layer” refers to a state where the metal oxide layer and the adjacent metal oxide layer are physically separated from each other.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

In this specification and the like, a space group with the symmetry of the crystal structure is represented using the short symbol of the international notation (or the Hermann-Mauguin notation). In addition to this, a space group number in International Tables for Crystallography Volume A (hereinafter also referred to as ITA) is sometimes described. The Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual direction that shows an orientation in crystal is denoted by “[ ]”, a set direction that shows all of the equivalent orientations is denoted by “< >”, an individual plane that shows a crystal plane is denoted by “( )”, and a set plane having equivalent symmetry is denoted by “{ }”. Even when the same space group number is used, the expression of a space group differs depending on the way of determining a crystal axis in some cases.

In this specification and the like, a crystal grain boundary refers to a boundary between adjacent crystal grains with different crystal orientations, for example. Thus, in this specification and the like, a crystal grain boundary does not include a boundary between adjacent crystal grains with the same crystal orientation. For example, in the case where a boundary is observed between two crystal grains in a transmission electron microscope (TEM) image but the crystal orientations of the two crystal grains are aligned or substantially aligned with each other, the boundary is not referred to as a crystal grain boundary in some cases. In the case where a difference in crystal orientation between adjacent measurement points is small (e.g., the difference in crystal orientation is less than 5°) in electron backscatter diffraction (EBSD) or electron backscatter diffraction pattern (EBSP), these measurement points can be regarded as belonging to the same crystal grain.

In this specification and the like, a crystal structure of a cubic crystal system is sometimes referred to as a cubic crystal, a cubic crystal structure, or the like. The same applies to the other crystal systems (e.g., a hexagonal crystal system, a trigonal crystal system, a tetragonal crystal system, an orthorhombic crystal system, a monoclinic crystal system, and a triclinic crystal system).

In this specification and the like, a “crystallized film” refers to a film having crystallinity that is formed by crystallizing an amorphous film.

In this specification and the like, a “seed crystal layer” includes at least one crystal grain (a seed crystal or a seed crystal grain). In the case where a plurality of crystal grains exist, these are collectively referred to as a “seed crystal layer”. The plurality of crystal grains may be apart from each other. Accordingly, a “seed crystal layer” can also be referred to as a “group of seed crystals” or a “group of seed crystal grains”.

### Embodiment 1

One embodiment of the present invention is a method for forming a metal oxide layer formed of crystal grains with uniform crystal orientations.

The metal oxide layer is a crystalline indium oxide layer containing indium (In) and oxygen (O). The crystal grains included in the indium oxide layer have the <111> orientation with respect to a formation surface.

In the formation method of one embodiment of the present invention, an amorphous indium oxide film (a first amorphous film) is formed first.

Next, the first amorphous film is subjected to first heat treatment to be crystallized, whereby a first crystallized film is formed. The first crystallized film is a polycrystalline film formed of crystal grains having random orientations.

Next, the first crystallized film is subjected to wet etching with an etchant containing acid to remove part of the first crystallized film, whereby a seed crystal layer is formed. The seed crystal layer is a layer in which a plurality of crystal grains having the <111> orientation with respect to the formation surface remain, among the crystal grains having random orientations included in the first crystallized film.

Next, an amorphous indium oxide film (a second amorphous film) is formed over the seed crystal layer.

Next, the second amorphous film is subjected to second heat treatment to be crystallized, whereby a second crystallized film is formed. The second crystallized film is formed by crystal growth of the second amorphous film in the <111> orientation with respect to the top surface of the seed crystal layer. The second crystallized film has a crystal structure reflecting the crystal structure of the seed crystal layer.

The second crystallized film is formed of crystal grains aligned in the <111> orientation with respect to a formation surface. Thus, the second crystallized film is expected to have higher carrier mobility than the first crystallized film formed of crystal grains having random orientations.

The second crystallized film can be employed as a semiconductor layer including a channel formation region of a transistor, for example. In the case where the second crystallized film is used as a semiconductor layer of a transistor, the transistor can be expected to have higher field-effect mobility and a higher on-state current than in the case where the first crystallized film is used as the semiconductor layer.

A method for forming an indium oxide layer, which is a metal oxide layer of one embodiment of the present invention, the characteristics of indium oxide, the crystal structure of indium oxide, and the like will be described below with reference to drawings.

### <Method for Forming Indium Oxide Layer>

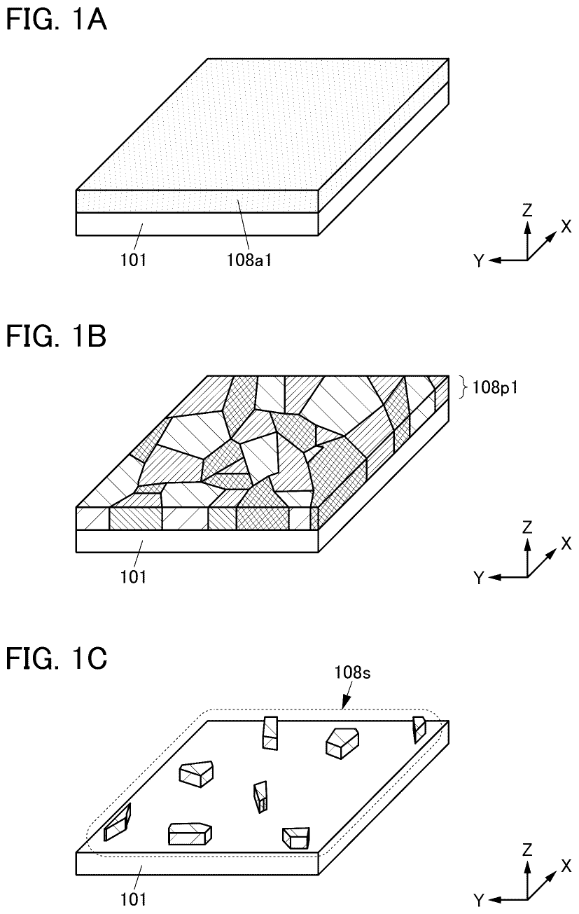

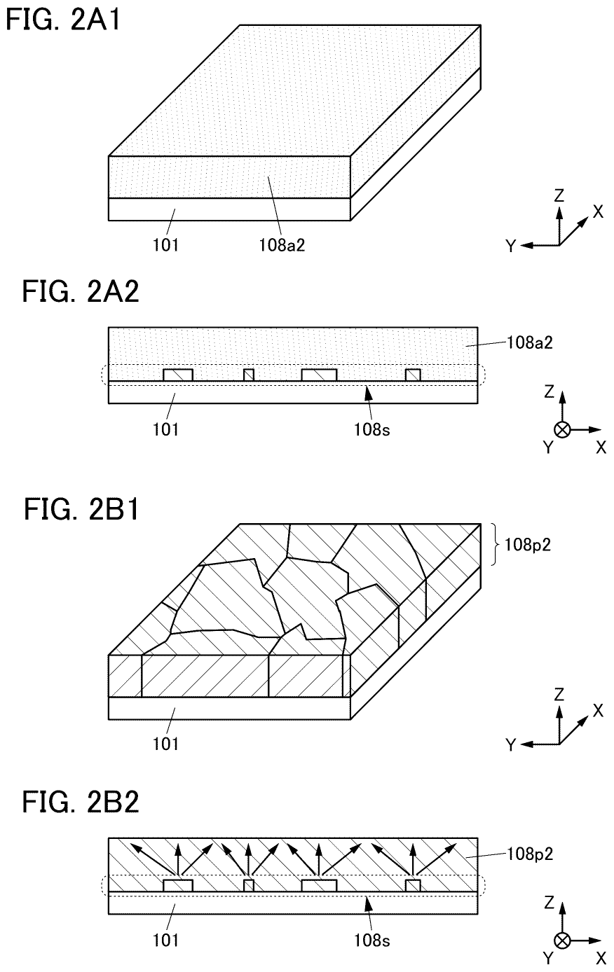

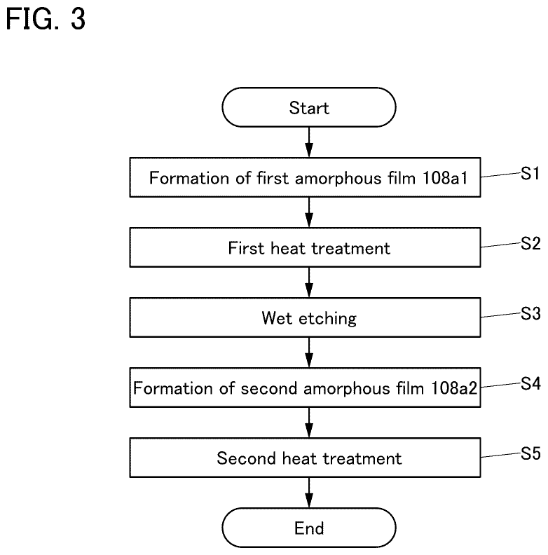

A method for forming an indium oxide layer having crystallinity, which is a metal oxide layer of one embodiment of the present invention, will be described below with reference to FIGS. 1A to 1C, FIGS. 2A1 to 2B2, and FIG. 3. FIG. 1A, FIG. 1B, FIG. 1C, FIG. 2A1, and FIG. 2B1 are perspective views of a stack in each step of the formation method. FIG. 2A2 is a cross-sectional view of the stack in the step corresponding to FIG. 2A1. FIG. 2B2 is a cross-sectional view of the stack in the step corresponding to FIG. 2B1. FIG. 3 is a flow chart showing a series of steps of the formation method.

First, in Step S1 shown in FIG. 3, a first amorphous film 108a1 is formed over a substrate 101 (FIG. 1A).

The substrate 101 preferably has heat resistance high enough to withstand heat treatment performed later. The substrate 101 is preferably formed using a material that does not affect the crystallinity of a film formed over the substrate. For example, when an amorphous film is formed over the substrate 101 and crystallized by heat treatment or the like performed later, the crystal structure or the like of the substrate 101 is preferably not reflected in the crystallization. For example, it is not preferable that a crystalline film formed using the same material as an amorphous film formed over the substrate 101 be used as the substrate 101.

A quartz substrate can be used as the substrate 101, for example. Although the substrate 101 has a single-layer structure in FIG. 1A and the like, a stacked-layer structure of two or more layers can also be employed. For example, a glass substrate over which an inorganic insulating film of silicon oxide, silicon nitride, or the like is formed can be used as the substrate 101. The substrate 101 can be provided with a semiconductor element.

The first amorphous film 108a1 is an amorphous indium oxide film. The first amorphous film 108a1 can be formed by a sputtering method using a target containing indium and oxygen, for example.

In the case where the first amorphous film 108a1 is formed by a sputtering method, a single gas of a noble gas (typically, argon) or oxygen, a mixed gas of a noble gas and oxygen, or the like can be used as a sputtering gas. The proportion of a noble gas (typically, argon) in the whole sputtering gas is, for example, higher than or equal to 50% and lower than or equal to 100%, preferably higher than or equal to 70% and lower than or equal to 100%, further preferably higher than or equal to 90% and lower than or equal to 100%. By increasing the proportion of the noble gas (typically, argon) in the whole sputtering gas, the first amorphous film 108a1 with low crystallinity can be formed.

Note that the sputtering gas can also contain hydrogen (H₂). By introducing hydrogen when the first amorphous film 108a1 is formed by a sputtering method, the first amorphous film 108a1 with low crystallinity can be formed. In addition, at the time of forming the first amorphous film 108a1, generation of crystal nuclei can be suppressed or the disappearance of the crystal nuclei can be promoted.

The substrate temperature during the formation of the first amorphous film 108a1 is preferably higher than or equal to room temperature (25° C.) and lower than or equal to 140° C., further preferably higher than or equal to room temperature and lower than or equal to 100° C., further preferably room temperature. For example, the substrate temperature is preferably set to room temperature, in which case the productivity is increased. When the first amorphous film 108a1 is formed with the substrate temperature set at room temperature or without heating the substrate, the first amorphous film 108a1 can have low crystallinity.

The first amorphous film 108a1 can be formed also by an atomic layer deposition (ALD) method. The first amorphous film 108a1 can be formed using a first precursor and a first oxidizer. The first precursor preferably contains indium. At this time, an indium oxide film is formed as the first amorphous film 108a1. That is, an oxide film containing a single element besides oxygen is formed. In the case where the first precursor contains indium, a thermal ALD method can be used as the ALD method.

As the precursor containing indium, it is possible to use trimethylindium, triethylindium, ethyldimethylindium, tris(1-methylethyl)indium, tris(2,2,6,6-tetramethyl-3,5-heptanedionato)indium, cyclopentadienylindium, indium(III) acetylacetonate, (3-(dimethylamino)propyl)dimethylindium, (diethylphosphino)dimethylindium, chlorodimethylindium, bromodimethylindium, dimethyl(2-propanolato)indium, or the like.

As the precursor containing indium, an inorganic precursor not containing hydrocarbon can also be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide). The decomposition temperature of indium trichloride is approximately higher than or equal to 500° C. and lower than or equal to 700° C. Thus, with the use of indium trichloride, film formation can be performed by an ALD method while a substrate is being heated at approximately higher than or equal to 400° C. and lower than or equal to 600° C., e.g., at 500° C.

The first amorphous film 108a1 is preferably formed using a precursor with a low impurity concentration, i.e., a high purity. For example, the purity of the precursor is preferably higher than or equal to 3N (99.9%), further preferably higher than or equal to 4N (99.99%), further preferably higher than or equal to 5N (99.999%), further preferably higher than or equal to 6N (99.9999%). The use of a high-purity precursor can reduce impurities in the first amorphous film 108a1.

As the first precursor, a precursor purified by two or more times of distillation (also referred to as “rectification” or “precision distillation”) is preferably used. The use of such a precursor is preferable because it facilitates formation of a metal oxide containing few impurities. Distillation is preferably performed a plurality of times, in which case impurities due to a starting material used to produce the precursor can be inhibited from remaining in the precursor. Note that the present invention is not limited to the above, and a precursor purified by one distillation step, i.e., single distillation, can be used. The single distillation is preferable in terms of a reduction in manufacturing cost.

Ozone (O₃), oxygen (O₂), water (H₂O), hydrogen peroxide (H₂O₂), or the like can be used as the first oxidizer. The first oxidizer preferably contains at least one of ozone and oxygen. The first oxidizer can contain at least one of water and hydrogen peroxide. Thus, the first amorphous film 108a1 with low crystallinity can be formed.

In this specification and the like, unless otherwise specified, ozone, oxygen, and water that can be used as an oxidizer include not only those in gas or molecular states but also those in plasma, radical, and ion states.

The pulse time for introducing the first oxidizer is preferably longer than or equal to 0.1 seconds and shorter than or equal to 30 seconds, further preferably longer than or equal to 0.3 seconds and shorter than or equal to 15 seconds, further preferably longer than or equal to 0.3 seconds and shorter than or equal to 10 seconds. The pulse time for introducing the first oxidizer is shortened to reduce the amount of introduced first oxidizer, so that a larger amount of hydrogen contained in the first precursor remains in the film. When a larger amount of hydrogen remains in the film, generation of crystal nuclei can be inhibited and some crystal nuclei in the film can be eliminated; accordingly, the number of crystal nuclei in the film can be reduced.

Here, the substrate heating temperature at the time of introducing the first precursor into a reaction chamber is preferably a temperature corresponding to the decomposition temperature of the first precursor. In the case of a thermal ALD method in which triethylindium is used as the precursor containing indium, the substrate heating temperature can be higher than or equal to room temperature (25° C.) and lower than or equal to 350° C., preferably higher than or equal to room temperature and lower than or equal to 200° C., further preferably higher than or equal to room temperature and lower than or equal to 150° C., for example. By lowering the substrate heating temperature, the first amorphous film 108a1 with low crystallinity can be formed.

Next, in Step S2 shown in FIG. 3, the first amorphous film 108a1 is subjected to the first heat treatment to be crystallized, whereby a first crystallized film 108p1 is formed (FIG. 1).

The first crystallized film 108p1 is a polycrystalline indium oxide film formed by crystal growth of the first amorphous film 108a1 through the first heat treatment. FIG. 1B schematically illustrates a state where the first crystallized film 108p1 is formed of crystal grains with random orientations and a variety of particle diameters by applying different hatching patterns to the crystal grains.

The heat treatment temperature is preferably higher than or equal to 150° C. and lower than or equal to 650° C., further preferably higher than or equal to 150° C. and lower than or equal to 550° C., further preferably higher than or equal to 150° C. and lower than or equal to 450° C., further preferably higher than or equal to 150° C. and lower than or equal to 350° C., further preferably higher than or equal to 150° C. and lower than or equal to 300° C., further preferably higher than or equal to 150° C. and lower than or equal to 250° C. The heat treatment can be performed in an atmosphere containing one or more of a noble gas, nitrogen, and oxygen. As a nitrogen-containing atmosphere or an oxygen-containing atmosphere, clean dry air (CDA) can be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the first crystallized film 108p1 can be prevented as much as possible. The heat treatment in an oxygen-containing atmosphere sometimes increases the effect of reducing defects in the first crystallized film 108p1. An oven or a rapid thermal annealing (RTA) apparatus can be used for the heat treatment, for example. With the RTA apparatus, the heat treatment time can be shortened.

Next, in Step S3 shown in FIG. 3, the first crystallized film 108p1 is subjected to wet etching. By the wet etching, part of the first crystallized film 108p1 is removed, whereby a seed crystal layer 108s is formed (FIG. 1C). As described in <Crystal structure of indium oxide>, crystal grains with random orientations included in the first crystallized film 108p1 might have different etching rates for wet etching depending on their crystal orientations with respect to the formation surface (here, the top surface of the substrate 101). For example, crystal grains oriented in the <111> direction with respect to the formation surface might have a lower etching rate for wet etching than crystal grains oriented in the <001> direction with respect to the formation surface. Therefore, for example, in the case where the first crystallized film 108p1 includes crystal grains oriented in the <111> direction and crystal grains oriented in the <001> direction with respect to the formation surface, the crystal grains oriented in the <001> direction can be removed earlier by wet etching, allowing the crystal grains oriented in the <111> direction to remain on the substrate 101. FIG. 1C schematically illustrates that, among the crystal grains with random orientations included in the first crystallized film 108p1 illustrated in FIG. 1B, only crystal grains having a specific crystal orientation are left by the wet etching. That is, the seed crystal layer 108s is an indium oxide layer formed of a plurality of crystal grains having a specific crystal orientation (e.g., the <111> orientation) with respect to the formation surface.

An etchant used for the wet etching preferably contains acid. For example, one or more of phosphoric acid, oxalic acid, nitric acid, and hydrochloric acid can be used. When wet etching using the above-described etchant containing acid is performed on the first crystallized film 108p1, which is a polycrystalline indium oxide film, crystal grains having a crystal orientation with a low etching rate can remain as the seed crystal layer 108s by utilizing a difference in etching rate depending on the crystal orientation or crystallinity of the crystal grains included in the first crystallized film 108p1.

Note that since the seed crystal layer 108s is a layer that functions as a seed crystal for a crystallized film (a second crystallized film 108p2) formed in a later step, the seed crystal layer 108s is preferably formed of a plurality of crystal grains uniformly aligned in a specific crystal orientation with respect to a formation surface (here, the top surface of the substrate 101). For example, in the case where the concentration of an etchant used for wet etching is too low, the temperature is too low, or the processing time is too short, a plurality of crystal grains with different crystal orientations remain even after the wet etching. In contrast, in the case where the concentration of the etchant used for the wet etching is too high, the temperature is too high, or the processing time is too long, all the crystal grains included in the first crystallized film 108p1 disappear after the wet etching. Thus, the concentration of the etchant, temperature, processing time, or the like for wet etching are preferably set under a condition in which among crystal grains with random orientations included in the first crystallized film 108p1, crystal grains having a crystal orientation indicating the lowest etching rate with respect to the etchant remains.

Next, in Step S4 shown in FIG. 3, a second amorphous film 108a2 is formed over the seed crystal layer 108s and the substrate 101 (FIGS. 2A1 and 2A2).

For the formation of the second amorphous film 108a2, the description of the formation of the first amorphous film 108a1 can be referred to.

Although FIG. 2A2 and the like illustrate an example in which the top surface of a film formed over the seed crystal layer 108s (here, the second amorphous film 108a2) is flat or substantially flat, one embodiment of the present invention is not limited thereto. The top surface of the film formed over the seed crystal layer 108s may have an uneven shape depending on the size (a height from the substrate surface) of the seed crystal layer 108s, the thickness of the film formed over the seed crystal layer 108s, or the like.

Next, in Step S5 shown in FIG. 3, the second amorphous film 108a2 is subjected to the second heat treatment to be crystallized, whereby the second crystallized film 108p2 is formed (FIGS. 2B1 and 2B2).

The second crystallized film 108p2 is a polycrystalline indium oxide film formed by crystal growth of the second amorphous film 108a2 through the second heat treatment. The second crystallized film 108p2 is formed in such a manner that the second amorphous film 108a2 grows in the crystal orientation (here, the <111> orientation) reflecting the crystal structure of the seed crystal layer 108s with respect to the top surface of the seed crystal layer 108s having a specific crystal orientation (e.g., the <111> orientation) with respect to the formation surface (here, the top surface of the substrate 101).

When the second amorphous film 108a2 is crystallized, first, a region in contact with the seed crystal layer 108s is crystallized, and then crystallization proceeds to grow laterally toward the region not in contact with the seed crystal layer 108s. FIG. 2B2 schematically illustrates a state where crystal growth progresses, using arrows. Crystal grains grown from a plurality of seed crystals included in the seed crystal layer 108s formed on the substrate 101 grow until they reach the surface of the second amorphous film 108a2, at which point adjacent crystal grains collide with each other and stop growing, and the formation of the second crystallized film 108p2 is terminated. A collision portion (a boundary between crystal grains) between adjacent crystal grains serves as a crystal grain boundary. FIG. 2B1 schematically illustrates a state where the second crystallized film 108p2 is formed of a plurality of crystal grains reflecting the crystal orientation of the seed crystal layer 108s, by applying the same hatching pattern to the crystal grains included in the seed crystal layer 108s and the crystal grains included in the second crystallized film 108p2.

Note that although the second crystallized film 108p2 is illustrated as a polycrystalline film having a crystal grain boundary in FIG. 2B1, the second crystallized film 108p2 can be a single crystal film in some cases. In that case, the second crystallized film 108p2 does not have a crystal grain boundary; thus, carriers flowing through the second crystallized film 108p2 are not affected by carrier scattering in the crystal grain boundary. Accordingly, the carrier mobility can be higher than that in the case where the second crystallized film 108p2 is a polycrystalline film.

The crystallinity of the second crystallized film 108p2 can be analyzed by X-ray diffraction (XRD), TEM, or electron diffraction (ED), for example. Alternatively, these methods can be combined for the analysis.

In the case where the second crystallized film 108p2 is a polycrystalline film, the particle diameter of the crystal grain included in the second crystallized film 108p2 is preferably large. With the use of a polycrystalline film having a large crystal grain diameter, the number of crystal grain boundaries in the second crystallized film 108p2 can be reduced. Thus, the influence of carrier scattering from the crystal grain boundary can be reduced in the second crystallized film 108p2 formed of a polycrystalline film with a large particle diameter, achieving high carrier mobility.

In the case where a polycrystalline indium oxide film is used as the second crystallized film 108p2, the particle diameter of a crystal grain included in the indium oxide film is preferably greater than or equal to 0.1 μm, further preferably greater than or equal to 0.2 μm, further preferably greater than or equal to 0.3 μm, further preferably greater than or equal to 0.4 μm, further preferably greater than or equal to 0.5 μm, further preferably greater than or equal to 0.6 μm, further preferably greater than or equal to 0.7 μm, for example. The particle diameter of the crystal grain is preferably large and the upper limit thereof is not particularly provided. Note that the particle diameter of the crystal grain is not limited to the above range.

The particle diameter of the crystal grain included in the second crystallized film 108p2 can be analyzed with an optical microscope, a scanning electron microscopy (SEM), a TEM, a scanning transmission electron microscopy (STEM), or EBSD, for example. Alternatively, these methods can be combined as appropriate for the analysis. As the particle diameter, for example, the average of the particle diameters of a plurality of crystal grains can be used. The particle diameter of the crystal grain can be, for example, the diameter of a circle that is the same as the area of the crystal grain. The diameter here is sometimes referred to as an equivalent circular area diameter or the like.

Note that in the case where the second crystallized film 108p2 has a small thickness, the crystallinity and the particle diameter of the crystal grain cannot be evaluated in some cases.

For the temperature, atmosphere, apparatus, and the like that can be used for the second heat treatment, the description of the temperature, atmosphere, apparatus, and the like that can be used for the first heat treatment can be referred to.

Note that when the temperature of the second heat treatment is too high, crystal nuclei that are not attributed to the seed crystal layer 108s are generated in the second amorphous film 108a2 (e.g., crystal grains having crystal orientations different from those in the seed crystal layer 108s), and crystal growth using the natural nuclei as seed crystals might be induced. By contrast, when the temperature of the second heat treatment is too low, the speed of crystal growth of the crystal grain due to the seed crystal layer 108s might be decreased, lowering the productivity of the stack. Therefore, the temperature, treatment time, and the like of the second heat treatment are preferably set within the range where a natural nucleus is not generated and the allowable range of productivity of the stack is satisfied. The second heat treatment can be performed under the same conditions as the first heat treatment, and can be performed under conditions different from those for the first heat treatment.

### <Characteristics of Indium Oxide>

The properties, characteristics, and the like of a crystalline indium oxide layer, which is a metal oxide layer of one embodiment of the present invention, will be described below.

In this specification and the like, indium oxide including at least a crystal part or a crystal region in a film is referred to as crystal IO or crystalline IO. Examples of crystal IO or crystalline IO include single crystal indium oxide, polycrystal indium oxide, and microcrystal indium oxide. Indium oxide is a semiconductor material having physical properties completely different from those of an oxide semiconductor such as IGZO or zinc oxide. Indium oxide is preferably used for a semiconductor layer including a channel formation region of a transistor because of its properties and characteristics, for example. For example, when indium oxide is used for the semiconductor layer, transistor characteristics (e.g., high field-effect mobility and high on-state current) can be expected to be better than those in the case where another oxide semiconductor material such as IGZO or zinc oxide is used.

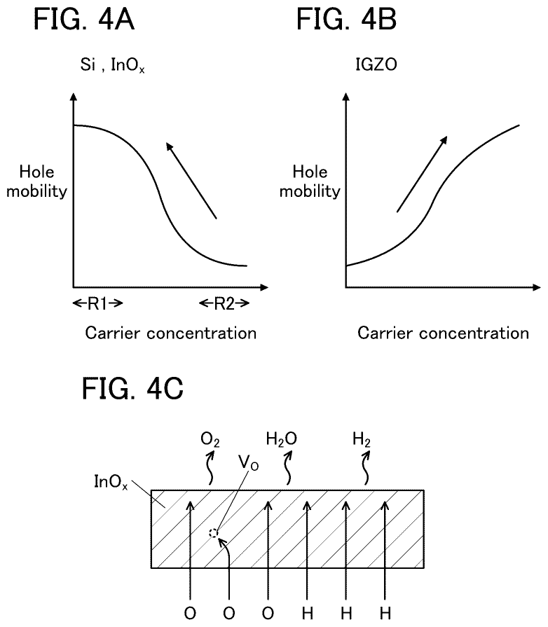

The dependence of the Hall mobility on the carrier concentration of indium oxide, silicon, and IGZO will be described. FIG. 4A is a schematic view showing the dependence of the Hall mobility on the carrier concentration of silicon (Si) and indium oxide (InO_{X}), and FIG. 4B is a schematic view showing the dependence of the Hall mobility on the carrier concentration of IGZO.

As indicated by an arrow in FIG. 4B, IGZO has a tendency in which the Hall mobility is higher as the carrier concentration is higher. By contrast, as indicated by an arrow in FIG. 4A, indium oxide has a tendency in which the Hall mobility is higher as the carrier concentration is lower (see Non-Patent Document 3). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 4B are based on the assumption of single crystal indium oxide; thus, the characteristics of non-single-crystal (e.g., polycrystal) indium oxide are sometimes different from those in FIG. 4A.

In FIG. 4A, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω·cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, zirconium, hafnium, tantalum, tungsten, molybdenum, tin, silicon, and boron. It is particularly preferable that an oxide of the element have conductivity or semiconductor properties.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. As for IGZO, distortion due to stress of an electrode in contact with IGZO is formed in a source region and a drain region and n-type regions are formed in some cases. Since a valence electron can be controlled in indium oxide unlike in IGZO, formation of distortion can be inhibited in a film of indium oxide. The film with less distortion will have higher reliability. For example, when the region where the carrier concentration falls within the range R1 and the region where the carrier concentration falls within the range R2, which are shown in FIG. 4A, are separately formed in an indium oxide film, what is called an n-i-n junction (a junction between an n-type region, an i-type region, and an n-type region) can be formed. Although valence electron control in a transistor containing silicon is generally known, valence electron control in a transistor containing indium oxide is a novel technical idea that cannot be conceived usually.

With the use of the above technical idea, a transistor containing indium oxide in this specification and the like has two or more, preferably three or more, further preferably four or more, and most preferably all of the following characteristics (1) to (5): (1) high on-state current (i.e., high mobility); (2) low off-state current; (3) normally-off characteristics; (4) high reliability; and (5) high cutoff frequency (fT). For example, the transistor containing indium oxide in this specification and the like has high mobility, low off-state current, and normally-off characteristics. This transistor is different from a normally-on transistor having high mobility.

Next, an indium oxide film used for a transistor will be described. The indium oxide film preferably has crystallinity (i.e., has a crystal grain). Examples of a film having a crystal grain include a single crystal film, a polycrystal film, and an amorphous film having a crystal grain (also referred to as a microcrystal film). In particular, the indium oxide film is preferably a polycrystal film, further preferably a single crystal film. A single crystal film does not have a crystal grain boundary (also referred to as a grain boundary). Impurities that block the carrier flow (typically, an insulating impurity, an insulating oxide, or the like) are likely to be segregated at a crystal grain boundary. The use of a single crystal film can inhibit carrier scattering or the like at the crystal grain boundary, thereby achieving a transistor having high field-effect mobility. In addition, the use of a single crystal film produces an excellent effect of reducing a variation in transistor characteristics caused by the crystal grain boundary.

A polycrystal film is preferable because it can reduce carrier scattering as compared with a microcrystal film or an amorphous film and enables a transistor to have high field-effect mobility. In the case of using a polycrystal film, it is preferable to use a film that has as large a crystal grain size as possible and few crystal grain boundaries. In the case where the crystal grain boundary is neither included nor observed in a channel formation region of a transistor including a polycrystal indium oxide film, the channel formation region is positioned in a single crystal region included in the polycrystal film and thus the transistor can be regarded as a transistor containing single crystal indium oxide.

Note that the crystallinity of indium oxide can be analyzed by XRD, TEM, or ED, for example. Alternatively, two or more of these methods may be combined for the analysis.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. A semiconductor layer where the direction of a crystal axis is continuously changed with another crystal axis or a crystal orientation as a rotation axis in one crystal grain in a channel formation region can also be referred to as a single crystal film.

A channel formation region refers to a region of a semiconductor layer that overlaps with (or faces) a gate electrode with a gate insulating layer therebetween and is positioned between a region in contact with a source electrode and a region in contact with a drain electrode. A current path in a channel formation region is the shortest distance between a source electrode and a drain electrode. Thus, a crystal grain, a crystal grain boundary, a crystal axis, a crystal orientation, or the like in a channel formation region can be confirmed in observation of a cross section including a semiconductor layer, a source electrode, and a drain electrode.

The impurity concentration in an indium oxide film in a channel formation region is preferably as low as possible. Impurities in the indium oxide film in the channel formation region can function as a carrier scattering source and cause a reduction in field-effect mobility. Such impurities might inhibit crystal growth of the indium oxide film. Examples of the impurities for the indium oxide film include boron and silicon. The concentrations of these impurities in the indium oxide film are each preferably lower than or equal to 0.1%, further preferably lower than or equal to 0.01% (100 ppm). Note that carbon, hydrogen, and the like are elements that would be contained in a film formation gas or a precursor in film formation, and the amounts of these elements remaining in the indium oxide film might be larger than those of the impurities.

The indium oxide film in the channel formation region may contain an element that can form a trivalent cation like indium as long as the cubic crystal structure (bixbyite structure) is retained. Examples of the element include Group 13 elements such as gallium and aluminum and Group 3 elements in the periodic table. Since these elements exist mainly as trivalent cations in oxides, the carrier concentration of indium oxide can be kept low.

A transistor including the above indium oxide film can have a field-effect mobility higher than or equal to 50 cm²/(V·s), preferably higher than or equal to 100 cm²/(V·s), further preferably higher than or equal to 150 cm²/(V·s), further preferably higher than or equal to 200 cm²/(V·s), further preferably higher than or equal to 250 cm²/(V·s).

One characteristic of an indium oxide film is to have a higher property of transmitting (diffusing) oxygen than an IGZO film. As shown in FIG. 4C, oxygen (O) diffusing in an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (V_{O}), the oxygen vacancies are filled with diffusing oxygen atoms. Since oxygen easily diffuses in the indium oxide film, oxygen vacancies in the indium oxide film are filled with oxygen more easily than those in an IGZO film.

As described above, the oxygen vacancies in the indium oxide film are reduced more easily than those in the IGZO film; thus, a transistor including such an indium oxide film can have extremely high reliability.

As shown in FIG. 4C, hydrogen diffuses in the indium oxide film. Hydrogen diffusing into the indium oxide film from the outside is transmitted through the indium oxide film and is released as a hydrogen molecule (H₂). When reacting with oxygen contained in the film, hydrogen is released as a water molecule.

A transistor including an indium oxide film is an accumulation-type transistor in which electrons are majority carriers. Assuming that the relaxation time of carriers is constant, the electron (carrier) mobility is higher as the effective mass of electrons (carriers) is smaller. That is, a transistor in which an indium oxide with a small effective mass of electrons is used for a semiconductor layer can have a high on-state current or high field-effect mobility.

Table 1 shows the effective mass in each of single crystal indium oxide (here, In₂O₃) and single crystal silicon (Si). As shown in Table 1, indium oxide has characteristics of a small effective mass of electrons and a large effective mass of holes. In addition, the effective mass of electrons in indium oxide hardly depends on the crystal orientation. Thus, a transistor containing indium oxide having crystallinity can have high field-effect mobility and high frequency characteristics (also referred to as f characteristics). A large effective mass of holes allows a transistor to have an extremely low off-state current. For example, the off-state current per micrometer of channel width of a vertical transistor including an indium oxide film can be lower than or equal to 1 fA (1×10⁻¹⁵ A) or lower than or equal to 1 aA (1×10⁻¹⁸ A) at 125° C., and can be lower than or equal to 1 aA (1×10⁻¹⁸ A) or lower than or equal to 1 zA (1×10⁻²¹ A) at room temperature (25° C.). Since indium oxide has a smaller effective mass of electrons and a larger effective mass of holes than silicon as shown in Table 1, a transistor containing indium oxide can have higher field-effect mobility and lower off-state current than a transistor containing silicon (hereinafter referred to as a Si transistor).

TABLE 1
Effective mass of In₂O₃

| Electron | | | |
|---|---|---|---|
| [100] orientation | [110] orientation | [111] orientation | Hole |
| 0.17 | 0.18 | 0.19 | 3.56 |

Effective mass of Si

| Electron | Hole |
|---|---|
| 0.26 | 0.17 |

A seed layer is preferably provided in contact with at least part of the indium oxide film having crystallinity. A material of the seed layer is preferably selected such that the difference in a lattice constant (also referred to as lattice mismatch) between the crystal included in indium oxide and the crystal included in the material is small. In this case, the crystallinity of the indium oxide film can be improved. As a layer in contact with at least part of the indium oxide film having crystallinity, a substrate (e.g., a single crystal substrate) may be used.

One of methods for evaluating the degree of a lattice mismatch is a method using a value of a lattice mismatch degree described below. A lattice mismatch degree Δa [%] of a crystal included in a film to be formed (here, the indium oxide film) with respect to the crystal included in the seed layer is calculated by the formula: Δa=((L₁−L₂)/L₂)×100. Here, L₁ is the lattice constant or the length of the unit lattice vector of the crystal included in the film to be formed, and L₂ is the lattice constant or the length of the unit lattice vector of the crystal included in the seed layer.

The absolute value of the lattice mismatch degree Δa between the seed layer and the indium oxide film is preferably as small as possible, most preferably 0. For example, Δa can be greater than or equal to −5% and less than or equal to 5%, preferably greater than or equal to −4% and less than or equal to 4%, further preferably greater than or equal to −3% and less than or equal to 3%, further preferably greater than or equal to −2% and less than or equal to 2%.

An indium oxide crystal has a cubic crystal structure (a bixbyite structure). For example, an yttria-stabilized zirconia (YSZ) crystal can have a cubic crystal structure (a fluorite crystal structure). The lattice mismatch degree of an indium oxide crystal with respect to an YSZ crystal having the cubic crystal structure is within the range of −2% to 2%, which enables epitaxial growth of a single crystal film of indium oxide over the YSZ substrate.

The crystal structures of the seed layer and the indium oxide film do not necessarily have the same crystal system or crystal orientation in some cases. For example, a film including a crystal with a hexagonal crystal structure or a trigonal crystal structure can be provided below an indium oxide film including a crystal with a cubic crystal structure. For example, when the crystal orientation of a seed layer surface is set to [001] and the crystal orientation of a bottom surface of the indium oxide film is set to [111], the necessary condition for crystal orientation in epitaxial growth can be satisfied. Examples of a hexagonal or trigonal crystal structure include a wurtzite structure, a YbFe₂O₄-type structure, a Yb₂Fe₃O₇-type structure, and variations of these structures. An example of a crystal having a YbFe₂O₄-type structure or a Yb₂Fe₃O₇-type structure is IGZO. A single crystal film of indium oxide can be formed not only over a YSZ substrate but also over an insulating film. By contrast, a single crystal film of silicon is not easily formed over an insulating film. Note that a silicon crystal has a diamond structure. Thus, although indium oxide and silicon exhibit similar characteristics as single crystals, they differ in whether a single crystal can be formed over an insulating film.

### <Crystal Structure of Indium Oxide>

The crystal structure of a crystalline indium oxide layer, which is a metal oxide layer of one embodiment of the present invention, will be described below. Note that description is made here on a single crystal indium oxide (In₂O₃).

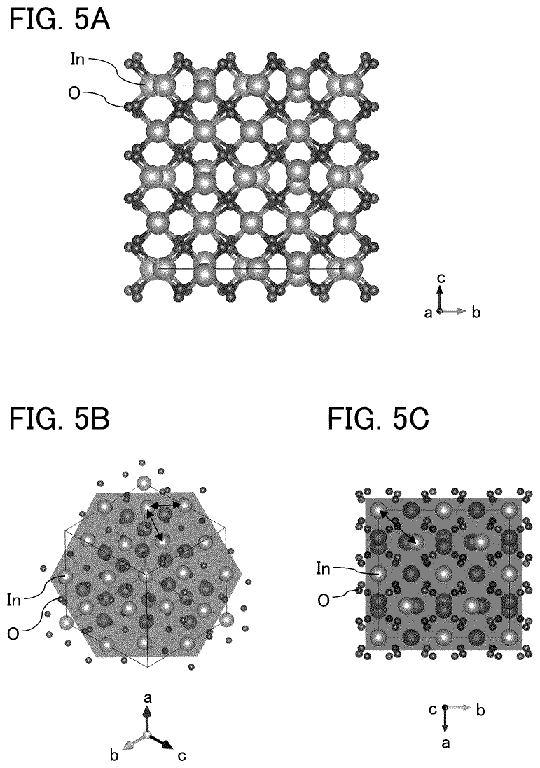

FIG. 5A is a diagram illustrating a crystal structure of a single crystal indium oxide (In₂O₃) and is a diagram of the crystal structure seen from the a-axis direction. Single crystal indium oxide has a cubic bixbyite crystal structure. Note that in FIG. 5A, indium atoms and oxygen atoms are shown with a size corresponding to the atomic radius. As illustrated in FIG. 5A, when the bixbyite indium oxide crystal is seen from a direction perpendicular to the c-axis (here, the a-axis direction), the layer of indium (In) and the layer of oxygen (O) are alternately stacked in the c-axis direction.

FIG. 5B is a diagram in which the crystal structure of the indium oxide in FIG. 5A seen from a direction perpendicular to the (111) plane (a plane corresponding to the hexagon in FIG. 5B). FIG. 5C is a diagram in which the crystal structure of indium oxide in FIG. 5A is seen from a direction perpendicular to the (001) plane (a plane corresponding to the quadrangle in FIG. 5C).

As described above, single crystal indium oxide (In₂O₃) has a cubic crystal structure. This crystal structure is the same as that of single crystal silicon (Si). It is known that in silicon, the (111) plane has a higher atomic density than the (001) plane; however, as illustrated in FIGS. 5B and 5C, the interatomic distance also in indium oxide is different depending on the crystal plane to be observed. That is, indium oxide has different atomic densities depending on the crystal plane.

In the case of single crystal indium oxide (In₂O₃), it is said that the In—In distances on the (111) plane (the arrows in FIG. 5B) are 0.334 nm and 0.385 nm, and the In—In distance on the (001) plane (the arrow in FIG. 5C) is 0.384 nm. Therefore, indium oxide can be regarded as having a crystal structure in which the atomic density at the (111) plane is higher than the atomic density at the (001) plane.

As described above, a difference in atomic density of indium oxide in the crystal plane probably reflects a difference in electron density of each crystal plane. That is, the crystal plane having a low atomic density may have a low electron density, and the crystal plane having a high atomic density may have a high electron density. Accordingly, indium oxide may have a higher electron density at the (111) plane than the electron density at the (001) plane.

The difference in electron density between crystal planes probably reflects a difference in ionic bonding strength of atoms in each crystal plane. This might be a factor that makes the crystal grains with random orientations have different etching rates depending on their crystal orientations in the case where a polycrystalline indium oxide film (the first crystallized film 108p1) is subjected to wet etching, as described above in <Method for forming indium oxide layer>. That is, in the case of an indium oxide layer, the ionic bonding of atoms on the (111) plane is stronger than that on the (001) plane. When wet etching is performed on a polycrystalline film containing both crystal grains with the (111) plane parallel to the substrate surface and crystal grains with the (001) plane parallel to the substrate surface, it is inferred that the crystal grains with the (001) plane parallel to the substrate surface are removed first.

Specific structure examples of a transistor in which a crystalline indium oxide layer, which is the metal oxide layer of one embodiment of the present invention, can be used are described below. The metal oxide layer of one embodiment of the present invention can be used as a semiconductor layer (mainly a channel formation region) of a transistor.

### Structure Example 1 of Transistor

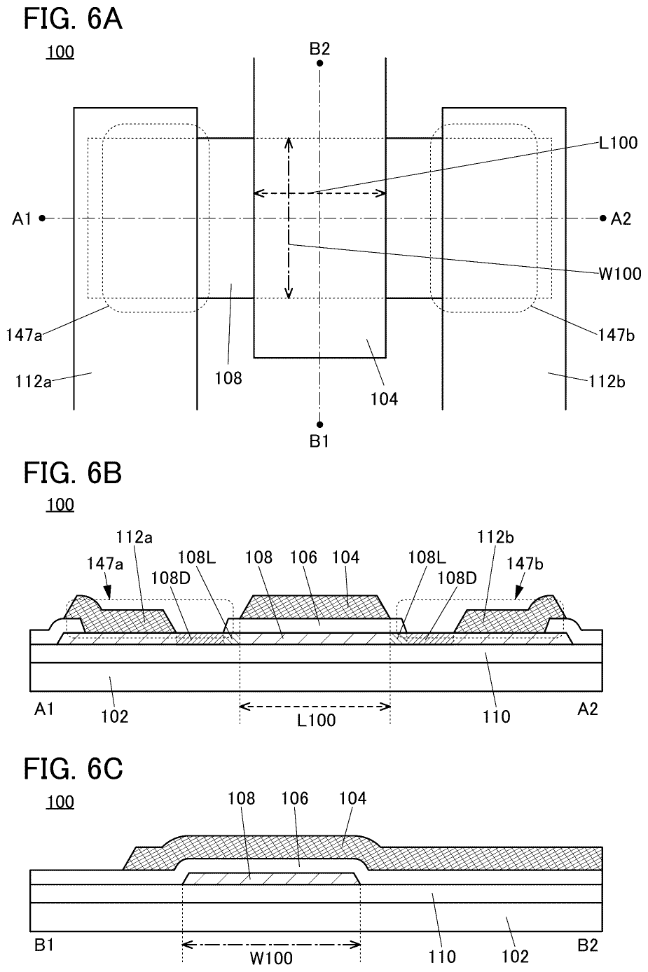

FIG. 6A is a plan view (also referred to as a top view) of a transistor 100. FIG. 6B is a cross-sectional view taken along the dashed-dotted line A1-A2 in FIG. 6A. FIG. 6C is a cross-sectional view taken along the dashed-dotted line B1-B2 in FIG. 6A. Note that some components of the transistor 100 (e.g., an insulating layer) are not illustrated in FIG. 6A. Some components are not illustrated in plan views of transistors in the following drawings in some cases, as in FIG. 6A.

The transistor 100 is provided over an insulating layer 110 provided over a substrate 102.

The transistor 100 includes a conductive layer 104, a conductive layer 112a, a conductive layer 112b, an insulating layer 106, and a semiconductor layer 108. The conductive layer 104 of the transistor 100 functions as a gate electrode. Part of the insulating layer 106 functions as a gate insulating layer. The conductive layer 112a functions as one of a source electrode and a drain electrode. The conductive layer 112b functions as the other of the source electrode and the drain electrode. Each layer included in the transistor 100 can have a single-layer structure or a stacked-layer structure.

The semiconductor layer 108 is provided in contact with the top surface of the insulating layer 110. The insulating layer 106 is provided over the semiconductor layer 108. Part of the insulating layer 106 (a region overlapping with the conductive layer 104) functions as a gate insulating layer of the transistor 100. The insulating layer 106 includes an opening portion 147a and an opening portion 147b in regions overlapping with the semiconductor layer 108. The opening portion 147a and the opening portion 147b are provided such that a region of the insulating layer 106 functioning as the gate insulating layer of the transistor 100 is sandwiched therebetween.

The conductive layers 104, 112a, and 112b are provided over the insulating layer 106. The conductive layer 104 has a region overlapping with the semiconductor layer 108 with the insulating layer 106 therebetween. The conductive layer 112a is provided to cover part of the opening portion 147a, and the conductive layer 112b is provided to cover part of the opening portion 147b. The conductive layer 112a includes a region in contact with the top surface of the semiconductor layer 108 in the opening portion 147a, and the conductive layer 112b includes a region in contact with the top surface of the semiconductor layer 108 in the opening portion 147b. The semiconductor layer 108 is electrically connected to the conductive layer 112a and the conductive layer 112b. The same material can be used for each of the conductive layers 112a and 112b. The conductive layers 104, 112a, and 112b can be formed in the same step. For example, a film to be the conductive layers 104, 112a, and 112b is formed and then processed, whereby the conductive layers 104, 112a, and 112b can be formed.

The region of the semiconductor layer 108 overlapping with the conductive layer 104 functions as a channel formation region of the transistor 100. The semiconductor layer 108 includes a pair of regions 108L between which a channel formation region is sandwiched and a pair of regions 108D outside the pair of regions 108L.

In the semiconductor layer 108, the region in contact with the conductive layer 112a functions as the one of the source region and the drain region of the transistor 100, and the region in contact with the conductive layer 112b functions as the other of the source region and the drain region. The source region and the drain region have lower electric resistance than the channel formation region. In other words, the source region and the drain region are each a region having a higher carrier concentration or a higher oxygen vacancy density than the channel formation region.

The regions 108L and the regions 108D each include an impurity element. As the impurity element, one or more of hydrogen, boron, carbon, nitrogen, fluorine, phosphorus, sulfur, arsenic, aluminum, magnesium, silicon, and a noble gas can be used. Note that typical examples of the noble gas include helium, neon, argon, krypton, and xenon. It is particularly preferable to use one or more of boron, phosphorus, aluminum, magnesium, and silicon as the impurity element.

An impurity element is supplied (or added or implanted) to the semiconductor layer 108 using the conductive layer 104, the conductive layer 112a, and the conductive layer 112b as masks. Thus, the region 108D is formed in a region of the semiconductor layer 108 that overlaps with none of the conductive layer 104, the conductive layer 112a, the conductive layer 112b, and the insulating layer 106, and the region 108L is formed in a region of the semiconductor layer 108 that overlaps with none of the conductive layer 104, the conductive layer 112a, and the conductive layer 112b and overlaps with the insulating layer 106.

In the semiconductor layer 108, a region in contact with the conductive layer 112a and the region 108D adjacent to the region function as one of a source region and a drain region. In the semiconductor layer 108, a region in contact with the conductive layer 112b and the region 108D adjacent to the region function as the other of the source region and the drain region.

The transistor 100 is a planar transistor in which the conductive layer 112a and the conductive layer 112b are placed on the same plane. The transistor 100 is what is called a top-gate transistor, in which the gate electrode is provided above the semiconductor layer 108. For example, an impurity element is supplied to the semiconductor layer 108 with the conductive layer 104 serving as a gate electrode used as a mask, so that the regions 108D serving as the source region and the drain region can be formed in a self-aligned manner. The transistor 100 can be referred to as a top-gate self-aligned (TGSA) transistor.

The channel length of the transistor 100 can be controlled by the length of the conductive layer 104. Accordingly, the channel length of the transistor 100 has a value larger than or equal to that of the minimum dimension of a light-exposure apparatus used for manufacture of the transistor. The transistor having a long channel length can have favorable saturation characteristics.

In this specification and the like, the state where the change in current is small in the saturation region of the drain current-drain voltage (Id-Vd) characteristics of a transistor is sometimes described using the expression “favorable saturation characteristics”.

A metal oxide exhibiting semiconductor characteristics is preferably used for the semiconductor layer 108 (mainly for the channel formation region). A transistor including a metal oxide (hereinafter referred to as an OS transistor) has much higher field-effect mobility than a transistor including amorphous silicon. In addition, the OS transistor has an extremely low off-state current, and charge accumulated in a capacitor that is connected in series to the transistor can be held for a long period. Furthermore, the power consumption of the semiconductor device can be reduced with the OS transistor. Note that in the case where a metal oxide is used for a semiconductor layer, the semiconductor layer can be referred to as an oxide semiconductor layer or a metal oxide layer.

The above-described indium oxide is preferably used for the semiconductor layer 108. With the use of the indium oxide for the semiconductor layer 108, a high-performance transistor having both a high on-state current and a low off-state current can be achieved. Note that the metal oxide can contain an impurity as a dopant.

The metal oxide used for the semiconductor layer 108 is preferably either a polycrystalline semiconductor or a single-crystal semiconductor. A transistor using a polycrystalline semiconductor or a single-crystal semiconductor can have a higher field-effect mobility and a higher on-state current than a transistor using an amorphous semiconductor. Furthermore, the use of a polycrystalline semiconductor can inhibit degradation of the transistor characteristics, which is preferable.

The band gap of a metal oxide used for the semiconductor layer 108 is preferably greater than or equal to 2.0 eV, further preferably greater than or equal to 2.5 eV.

The bandgap of the metal oxide can be evaluated by optical evaluation with a spectrophotometer, spectroscopic ellipsometry, a photoluminescence method, X-ray photoelectron spectrometry (XPS: X-ray Photoelectron Spectrometry or ESCA: Electron Spectrometry for Chemical Analysis)), or an X-ray Absorption Fine Structure (XAFS). Alternatively, these methods can be combined as appropriate for analysis. The electron affinity or the energy of the conduction band minimum can be obtained from a band gap and an ionization potential, which is the difference between a vacuum level and the energy of valence band maximum. The ionization potential can be evaluated by, for example, ultraviolet photoelectron spectrometry (UPS).

Note that as described in <Method for forming indium oxide layer>, the semiconductor layer 108 is formed in such a manner that the second amorphous film 108a2 formed over the seed crystal layer 108s grows in a crystal orientation reflecting the crystal structure of the seed crystal layer 108s through the second heat treatment. The semiconductor layer 108 is a layer formed of crystal grains laterally grown with the seed crystal layer 108s as a starting point. Accordingly, the existence of the seed crystal layer 108s can be confirmed by TEM observation or the like of the vicinity of the center portion of the crystal grain in a plan view, for example.

For the insulating layer 110, one or both of an inorganic insulating layer and an organic insulating layer can be used. Examples of materials that can be used for the organic insulating layer include an acrylic resin and a polyimide resin. The insulating layer 110 preferably includes one or more inorganic insulating layers. Examples of materials that can be used for the inorganic insulating layer include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

In this specification and the like, an oxynitride refers to a material that includes more oxygen than nitrogen in its composition. A nitride oxide refers to a material that includes more nitrogen than oxygen in its composition.

The insulating layer 110 includes a region in contact with the semiconductor layer 108. In the semiconductor layer 108, at least part of the region in contact with the insulating layer 110 functions as a channel formation region. Thus, when a metal oxide is used for the semiconductor layer 108, the insulating layer 110 preferably contains oxygen. This can improve the characteristics of the interface between the semiconductor layer 108 and the insulating layer 110. A film from which oxygen is released by heating is further preferably used as the insulating layer 110. When the insulating layer 110 releases oxygen by being heated during the manufacturing process of the transistor 100, the oxygen can be supplied to the semiconductor layer 108. When oxygen is supplied from the insulating layer 110 to the semiconductor layer 108, particularly to the channel formation region, oxygen vacancies (V_{O}) are repaired, resulting in a reduction of oxygen vacancies (V_{O}). Consequently, the transistor 100 can have favorable electrical characteristics and high reliability. For the insulating layer 110, one or more of the above oxide and oxynitride can be suitably used. Specifically, silicon and oxygen are preferably included in the insulating layer 110, and one or both of silicon oxide and silicon oxynitride can be suitably used for the insulating layer 110.

For example, oxygen can be supplied to the insulating layer 110 when heat treatment or plasma treatment is performed on the insulating layer 110 in an oxygen-containing atmosphere. Alternatively, oxygen can be supplied to the insulating layer 110 by forming an oxide film over the top surface of the insulating layer 110 by a sputtering method in an oxygen-containing atmosphere. After that, the oxide film can also be removed. Note that the method for supplying oxygen to the insulating layer 110 is described in <Example of method for forming transistor>.

In the insulating layer 110, a substance (e.g., an atom, a molecule, and an ion) is preferably easily diffused. In other words, the diffusion coefficient of a substance in the insulating layer 110 is preferably high. Preferably, oxygen in particular is easily diffused in the insulating layer 110. That is, the diffusion coefficient of oxygen in the insulating layer 110 is preferably high. Oxygen contained in the insulating layer 110 is diffused in the insulating layer 110 and supplied to the semiconductor layer 108 through the interface between the insulating layer 110 and the semiconductor layer 108. The insulating layer 110 in which oxygen easily diffuses contributes to the efficient supply of oxygen contained in the insulating layer 110 to the semiconductor layer 108 (channel formation region, in particular).

Although the insulating layer 110 has a single-layer structure in FIG. 6B and the like, the structure is not limited thereto, and a stacked-layer structure of two or more layers can be employed. For example, in the case where the insulating layer 110 has a two-layer stacked structure of a first insulating layer and a second insulating layer provided over the first insulating layer, an insulating material that contains oxygen and releases oxygen by heating is preferably used for at least the second insulating layer (i.e., the insulating layer in contact with the semiconductor layer 108). Accordingly, oxygen contained in the second insulating layer can be supplied to the semiconductor layer 108 (mainly a channel formation region).

For the first insulating layer, an insulating material through which a substance is less likely to pass is preferably used. That is, the first insulating layer preferably functions as a barrier film. Accordingly, impurities can be inhibited from diffusing into the insulating layer 110 from a layer below the insulating layer 110 (the substrate 102 side), and the impurities can be inhibited from diffusing into the semiconductor layer 108. Moreover, oxygen contained in the second insulating layer can be prevented from diffusing to the substrate 102 side, which can inhibit a reduction in the amount of oxygen supplied to the semiconductor layer 108.

Note that in this specification and the like, a barrier film refers to a film having a barrier property. A barrier property means one or both of a function of hindering diffusion of a target substance (also referred to as low permeability) and a function of capturing or fixing (also referred to as gettering) the substance. For example, an insulating layer having a barrier property can be referred to as a barrier insulating layer.

Next, the channel length and channel width of the transistor 100 are described with reference to FIGS. 6A to 6C. Here, a portion of the semiconductor layer 108 that overlaps with the conductive layer 104 is described as a channel formation region.

The channel length of the transistor 100 is the length of the region between the pair of regions 108D where the semiconductor layer 108 and the conductive layer 104 overlap with each other. In FIG. 6A and FIG. 6B, a channel length L100 of the transistor 100 is indicated by a dashed double-headed arrow. The channel length L100 of the transistor 100 depends on the length of the conductive layer 104 (the length in a direction parallel to the dashed-dotted line A1-A2) and has a value larger than or equal to that of the minimum dimension of a light-exposure apparatus used for manufacture of the transistor. For example, the channel length L100 can be greater than or equal to 1.5 μm. The transistor having a long channel length can have favorable saturation characteristics.

The channel width of the transistor 100 is the width of a region where the semiconductor layer 108 and the conductive layer 104 overlap with each other in the direction perpendicular to the channel length direction (the direction parallel to the dashed-dotted line B1-B2) in a plan view. In FIGS. 6A and 6C, a channel width W100 of the transistor 100 is indicated by the dashed-dotted double-headed arrow.

As illustrated in FIG. 6A and FIG. 6C, the conductive layer 104 preferably protrudes outward from the end portion of the semiconductor layer 108 in the channel width direction of the transistor 100. In that case, as illustrated in FIG. 6C, the whole of the semiconductor layer 108 in the channel width direction is covered with the conductive layer 104 with the insulating layer 106 therebetween. In such a structure, the semiconductor layer 108 can be electrically surrounded by an electric field generated by the conductive layer 104.

In the semiconductor layer 108, the region 108D is a region having lower electric resistance than the channel formation region. In other words, the region 108D is a region having a higher carrier concentration, a region having a higher oxygen vacancy density, or a region having a higher impurity concentration than the channel formation region.

The region 108L is a region whose electric resistance is substantially equal to or lower than that of the channel formation region. The region 108L can be referred to as a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Furthermore, the region 108L is a region whose electric resistance is substantially equal to or higher than that of the region 108D. The region 108L can also be referred to as a region whose carrier concentration is substantially equal to or lower than that of the region 108D, a region whose oxygen vacancy density is substantially equal to or lower than that of the region 108D, or a region whose impurity concentration is substantially equal to or lower than that of the region 108D.

The region 108L functions as a buffer region that relieves a drain electric field. The region 108L is a region not overlapping with the conductive layer 104 and thus is a region where a channel is hardly formed by application of a gate voltage to the conductive layer 104. The region 108L preferably has a higher carrier concentration than the channel formation region. Thus, the region 108L can function as an LDD (Lightly Doped Drain) region. The region 108L functioning as the LDD region is provided between the channel formation region and the region 108D, whereby the transistor 100 can have a high drain breakdown voltage.

The carrier concentration in the semiconductor layer 108 preferably has a distribution such that the concentration is lowest in the channel formation region and increases in the order of the region 108L and the region 108D. Providing the region 108L between the channel formation region and the region 108D can keep the carrier concentration of the channel formation region extremely low even when an impurity such as hydrogen is diffused from the region 108D in the manufacturing process, for example.

Note that the carrier concentration in the region 108L is not necessarily uniform and sometimes has a gradient such that the carrier concentration decreases from the region 108D side toward the channel formation region. For example, one or both of the hydrogen concentration and the oxygen vacancy (V_{O}) concentration in the region 108L can have a gradient such that the concentration decreases from the region 108D side to the channel formation region side.

As illustrated in FIG. 6B and the like, parts of the conductive layers 112a and 112b are preferably positioned on the inner sides of the opening portions 147a and 147b, respectively. In other words, it is preferable that, inside the opening portion 147a, part of the conductive layer 112a include a region in contact with the semiconductor layer 108 and inside the opening portion 147b, part of the conductive layer 112b include a region in contact with the semiconductor layer 108. In this manner, the region of the semiconductor layer 108 in contact with the conductive layer 112a can be adjacent to one of the pair of regions 108D and similarly, the region of the semiconductor layer 108 in contact with the conductive layer 112b can be adjacent to the other of the pair of regions 108D. In the semiconductor layer 108, a region in contact with the conductive layer 112a and one of the pair of the regions 108D function as the one of the source region and the drain region of the transistor 100. In the semiconductor layer 108, a region in contact with the conductive layer 112b and the other of the pair of the regions 108D function as the other of the source region and the drain region of the transistor 100.

There is no limitation on the top surface shapes of the opening portions 147a and 147b. Although the top surface shapes of the opening portions 147a and 147b are quadrangles with rounded corners in FIG. 6A and the like, one embodiment of the present invention is not limited to this. Each of the top surface shapes of the opening portions 147a and 147b can be a circle, an ellipse, a polygon such as a triangle, a tetragon (including a rectangle, a rhombus, and a square), or a pentagon, or any of these polygons with rounded corners, for example. Note that the polygon can be a concave polygon (a polygon at least one of the interior angles of which is greater than 180°) or a convex polygon (a polygon all the interior angles of which are less than or equal to 180°). In this specification and the like, a circular shape is not necessarily a perfect circular shape.

Although the conductive layers 112a and 112b are formed in the same process as the conductive layer 104 here, one embodiment of the present invention is not limited to this. The conductive layer 112a and the conductive layer 112b can be formed in a step different from that for the conductive layer 104. For example, the conductive layer 104 is formed over the insulating layer 106 and an impurity element is supplied to the semiconductor layer 108 with the use of the conductive layer 104 as a mask, whereby the source region and the drain region are formed. Next, an opening portion reaching the source region and an opening portion reaching the drain region are formed in the insulating layer 106, and the conductive layer 112a and the conductive layer 112b can be formed to cover these opening portions.

Although the thickness of the semiconductor layer 108 is uniform without varying from place to place in the example illustrated in FIG. 6B and the like, one embodiment of the present invention is not limited thereto. A structure can be employed where the thickness of the semiconductor layer 108 is different between the region overlapping with the insulating layer 106 and the region not overlapping with the insulating layer 106. For example, when the opening portion 147a and the opening portion 147b are formed, the semiconductor layer 108 is sometimes partly removed, so that the semiconductor layer 108 has a thickness that is smaller in the region not overlapping with the insulating layer 106 than in the region overlapping with the insulating layer 106. Alternatively, the thickness of the semiconductor layer 108 can be different between the region overlapping with any of the insulating layer 106, the conductive layer 112a, and the conductive layer 112b and the region overlapping with none of them. For example, when the conductive layer 112a and the conductive layer 112b are formed, the semiconductor layer 108 is sometimes partly removed, so that the semiconductor layer 108 has a thickness that is smaller in the region overlapping with none of the insulating layer 106, the conductive layer 112a, and the conductive layer 112b than in the region overlapping with any of them. Alternatively, the thickness of the semiconductor layer 108 can be different among the region overlapping with the insulating layer 106, the region overlapping with any of the insulating layer 106, the conductive layer 112a, and the conductive layer 112b, and the region overlapping with none of them.

The metal oxide used for the semiconductor layer 108 is preferably highly purified intrinsic or substantially highly purified intrinsic; specifically, in the metal oxide, which the number of defects (hereinafter referred to as V_{O}H) in which hydrogen has entered an oxygen vacancy (V_{O}) is reduced as much as possible. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to fill oxygen vacancies (V_{O}). When a metal oxide in which impurities such as V_{O}H are sufficiently reduced is used for a channel formation region of a transistor, stable electrical characteristics can be achieved. Supplying oxygen to a metal oxide to fill oxygen vacancies (V_{O}) is sometimes referred to as oxygen adding treatment.

When a metal oxide is used for each of the semiconductor layer 108, the carrier concentration of the channel formation region is preferably lower than or equal to 1×10¹⁸ cm⁻³, further preferably lower than 1×10¹⁷ cm⁻³, further preferably lower than 1×10¹⁶ cm⁻³, further preferably lower than 1×10¹³ cm⁻³, yet further preferably lower than 1×10¹² cm⁻³. Note that the lower limit of the carrier concentration in the channel formation region is not particularly limited and can be, for example, 1×10⁻⁹ cm⁻³.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Materials that can be used for the components of the transistor 100 other than the above-described semiconductor layer 108 and insulating layer 110 are described below.

### [Conductive Layer 112a, Conductive Layer 112b, and Conductive Layer 104]

The conductive layer 112a, the conductive layer 112b, and the conductive layer 104 can each have a single-layer structure or a stacked-layer structure. Examples of the materials that can be used for the conductive layer 112a, the conductive layer 112b, and the conductive layer 104 include one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, and the conductive layer 104, a conductive material with low electrical resistivity that contains one or more of copper, silver, gold, and aluminum can be suitably used. Copper or aluminum is particularly preferable because of its high mass-productivity.

For each of the conductive layer 112a, the conductive layer 112b, and the conductive layer 104, a conductive metal oxide (also referred to as an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. An oxide conductor containing indium is particularly preferable because of its high conduction property.

When an oxygen vacancy (V_{O}) is formed in a metal oxide having semiconductor characteristics and hydrogen is added to the oxygen vacancy (V_{O}), a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a, the conductive layer 112b, and the conductive layer 104 can each have a stacked-layer structure of a conductive film including the above-described oxide conductor and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) can be used for each of the conductive layer 112a, the conductive layer 112b, and the conductive layer 104. The use of a Cu—X alloy film enables the manufacturing cost to be reduced because a wet etching method can be used in the processing.

Note that the same material can be used for the conductive layer 112a, the conductive layer 112b, and the conductive layer 104. Alternatively, different materials can be used for some or all of these conductive layers.

The conductive layer 112a and the conductive layer 112b each include a region in contact with the semiconductor layer 108. In the case where a metal oxide is used for the semiconductor layer 108, use of a metal that is easily oxidized (e.g., aluminum) for the conductive layer 112a and the conductive layer 112b allows an insulating oxide (e.g., aluminum oxide) to be formed between the conductive layer 112a and the semiconductor layer 108 and between the conductive layer 112b and the semiconductor layer 108, which might hinder electrical continuity between these layers. Thus, a conductive material that is not easily oxidized, a conductive material that maintains low electric resistance even after being oxidized, or an oxide conductive material is preferably used for the conductive layer 112a and the conductive layer 112b.

For each of the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are not easily oxidized or materials that maintain low electric resistance even when being oxidized.

Any of the above-described oxide conductors can be used for each of the conductive layer 112a and the conductive layer 112b. Specifically, a metal oxide such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For each of the conductive layer 112a and the conductive layer 112b, a nitride conductor can be used. Examples of the nitride conductor include tantalum nitride and titanium nitride. Each of the conductive layers 112a, 112b, and 104 can have a stacked-layer structure. In the case where each of the conductive layers 112a and 112b has a stacked-layer structure, a conductive material that is less likely to be oxidized is preferably used for at least a layer of the conductive layer 112a and a layer of the conductive layer 112b which are in contact with the semiconductor layer 108.

### [Insulating Layer 106]

The insulating layer 106 preferably includes one or more inorganic insulating layers. For the insulating layer 106, a material that can be used for the insulating layer 110 can be used.

The insulating layer 106 includes regions in contact with the semiconductor layer 108, the conductive layer 112a, the conductive layer 112b, the conductive layer 104, and the insulating layer 110. In the case where the semiconductor layer 108 is formed using a metal oxide, at least the film that is included in the insulating layer 106 and in contact with the semiconductor layer 108 is preferably formed using any of the above-described oxides and oxynitrides. In the case where the insulating layer 106 has a single-layer structure, silicon oxide, silicon oxynitride, or aluminum oxide can be suitably used for the insulating layer 106.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material usable for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. Alternatively, a material that can have ferroelectricity can be used for the gate insulating layer. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. For example, the atomic ratio of hafnium to the element J1 can be 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. For example, the atomic ratio of zirconium to the element J2 can be 1:1 or the neighborhood thereof. Alternatively, as the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, can be used.

Although the insulating layer 106 has a single-layer structure in FIG. 6B and the like, one embodiment of the present invention is not limited thereto. The insulating layer 106 can have a stacked-layer structure.

### [Substrate 102]

There is no particular limitation on the properties of the material of the substrate 102 as long as the material has heat resistance high enough to withstand at least heat treatment to be performed later. For example, a single-crystal semiconductor substrate or a polycrystalline semiconductor substrate of silicon or silicon carbide, a compound semiconductor substrate of silicon germanium or the like, a silicon-on-insulator (SOI) substrate, a glass substrate, a quartz substrate, a sapphire substrate, a ceramic substrate, or an organic resin substrate can be used as the substrate 102. The substrate 102 can be provided with a semiconductor element. Note that the shape of the semiconductor substrate and the insulating substrate can be circular or square.

A flexible substrate may be used as the substrate 102, and the transistor 100 and the like can be formed directly on the flexible substrate. Alternatively, for example, a separation layer can be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

In this specification and the like, flexibility refers to a property of an object being flexible and bendable. In other words, it is a property of an object that can be changed in form in accordance with external force applied to the object, and elasticity or restorability to the former shape is not taken into consideration.

For example, a flexible electronic device can be changed in form in accordance with external force. A flexible electronic device can be used with its shape fixed in a state of being changed in form, can be used while repeatedly changed in form, and can be used in a state of not changed in form. A flexible display device (also referred to as a flexible display device, a flexible display, or the like) can be changed in shape in accordance with external force. A flexible display device can be used with its shape fixed in a state of being changed in form, can be used while repeatedly changed in form, and can be used in a state of not changed in form. A flexible substrate can be changed in shape in accordance with external force. A flexible substrate can be used with its shape fixed in a state of being changed in form, can be used while repeatedly changed in form, and can be used in a state of not changed in form. Note that the expression “changed in form in accordance with external force” above means changing in form without requiring excessive force by the average adult's hand. Note that the flexibility can be quantified by a tester (e.g., a tensile tester or a compressive tester) capable of stress-distortion measurement as a modification of an object with respect to external force.

In this specification, the expression “an object has flexibility” means that at least part of the object has flexibility. That is, the flexible object can include a portion that is not flexible (also referred to as a hard portion).

In this specification, when two objects are changed in shape with the same external force, the object greatly changed in shape is referred to as an object having high flexibility. When the first portion and the second portion of an object are changed in shape with the same external force, a portion that is greatly changed in shape can be referred to as a portion having high flexibility.

A structure example of a transistor for which the metal oxide layer of one embodiment of the present invention can be used and which is different from the above-described transistor 100 is described below. Note that description of the same portions as those in the above-described transistor 100 is omitted in some cases. In the drawings that are referred to later, the same hatching pattern is applied to portions having functions similar to those of the aforementioned transistor 100, and the portions are not denoted by reference numerals in some cases.

### Structure Example 2 of Transistor

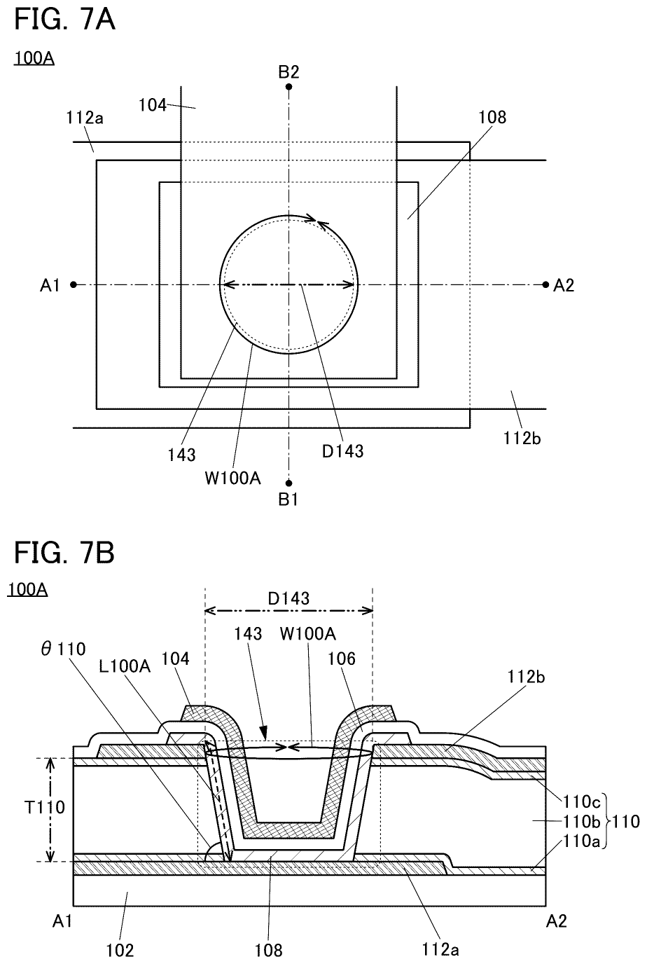

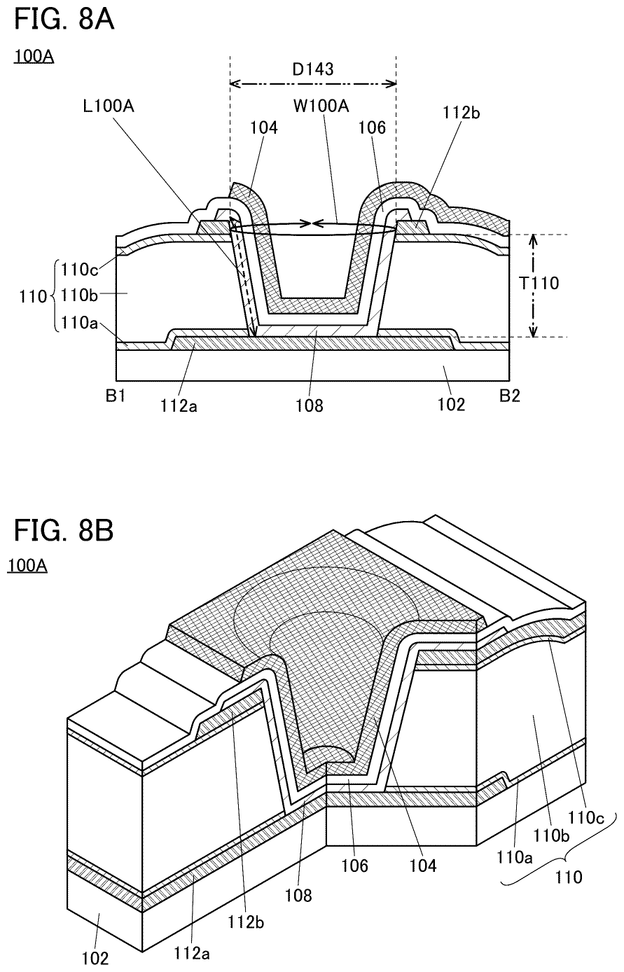

FIG. 7A is a plan view of a transistor 100A. FIG. 7B is a cross-sectional view taken along the dashed-dotted line A1-A2 in FIG. 7A. FIG. 8A is a cross-sectional view taken along the dashed-dotted line B1-B2 in FIG. 7A. FIG. 8B is a perspective view of a portion of the transistor 100A part of which is taken out. Note that some components of the transistor 100A (e.g., an insulating layer) are not illustrated in FIG. 7A.

The transistor 100A is different from the planar transistor 100 described in <Structure example 1 of transistor> in that the transistor 100A is a vertical transistor in which the source electrode and the drain electrode are arranged at different heights. The transistor 100A is different from the transistor 100 also in that the insulating layer 110 in contact with the channel formation region of the transistor 100A has a stacked-layer structure.

The transistor 100A is provided over the substrate 102. The transistor 100A includes the conductive layer 104, the insulating layer 106, the conductive layer 112a, the conductive layer 112b, and the semiconductor layer 108. The conductive layer 104 functions as a gate electrode. Part of the insulating layer 106 functions as a gate insulating layer. The conductive layer 112a functions as one of a source electrode and a drain electrode. The conductive layer 112b functions as the other of the source electrode and the drain electrode. In the semiconductor layer 108, a region in contact with the source electrode functions as a source region and a region in contact with the drain electrode functions as a drain region. A region of the semiconductor layer 108 that is sandwiched between the source region and the drain region functions as a channel formation region. That is, in the semiconductor layer 108, between the source region and the drain region, the entire region that overlaps with the gate electrode with the gate insulating layer therebetween can function as a channel formation region.

The structure of the transistor 100A is described in detail.

The conductive layer 112a is provided over the substrate 102. An insulating layer 110a is provided over the conductive layer 112a and the substrate 102. The insulating layer 110b is provided over the insulating layer 110a. An insulating layer 110c is provided over the insulating layer 110b. The conductive layer 112b is provided over the insulating layer 110c. Note that the insulating layers 110a, 110b, and 110c are collectively referred to as an insulating layer 110 in some cases.

The conductive layer 112a, the insulating layer 110, and the conductive layer 112b include an overlap region. In this region, the insulating layer 110 is provided to be sandwiched between the conductive layer 112a and the conductive layer 112b.

The insulating layer 110 and the conductive layer 112b include an opening portion 143 reaching the conductive layer 112a. The opening portion 143 is provided to have a region overlapping with the conductive layer 112a and a region overlapping with the conductive layer 112b.

The semiconductor layer 108 is provided in contact with the top surface of the conductive layer 112a inside the opening portion 143, the side surface of the insulating layer 110 inside the opening portion 143, the side surface of the conductive layer 112b inside the opening portion 143, and the top surface of the conductive layer 112b. The semiconductor layer 108 is provided to include a region overlapping with the opening portion 143 in a plan view.

Here, the insulating layer 110b preferably contains oxygen. Moreover, the insulating layer 110b is preferably an insulating layer from which oxygen is released by heating. That is, for the insulating layer 110b, it is preferable to use the insulating materials that can be used for the insulating layer 110 described in <Structure example 1 of transistor>. Accordingly, in the case where a metal oxide is used for the semiconductor layer 108, for example, oxygen contained in the insulating layer 110b can be supplied to the metal oxide. Thus, oxygen vacancies in the metal oxide can be repaired, so that the electrical characteristics and reliability of the transistor 100A can be improved.

Meanwhile, the insulating layers 110a and 110c are preferably insulating layers having a barrier property against a gas such as oxygen and hydrogen. In that case, oxygen contained in the insulating layer 110b can be inhibited from being released to the outside through the insulating layer 110a or the insulating layer 110c.

A material containing more nitrogen than the insulating layer 110b can be used for the insulating layers 110a and 110c. The insulating layers 110a and 110c with a high nitrogen content can have a high barrier property against oxygen and hydrogen.

The insulating layers 110a and 110c may each include a region having a lower hydrogen concentration than the insulating layer 110b.

The film densities of the insulating layers 110a and 110c are preferably higher than that of the insulating layer 110b. The insulating layers 110a and 110c having a high film density can have a high barrier property against oxygen and hydrogen.

For example, in the case where silicon oxide or silicon oxynitride is used for the insulating layer 110b, silicon nitride or silicon nitride oxide can be used for each of the insulating layers 110a and 110c. In addition, hafnium oxide or aluminum oxide can be suitably used for each of the insulating layers 110a and 110c.

Each of the insulating layers 110a and 110c can be a stack of two or more layers selected from silicon nitride, silicon nitride oxide, hafnium oxide, and aluminum oxide layers.

The insulating layer 106 is provided over the semiconductor layer 108. The insulating layer 106 includes a region in contact with the top surface of the semiconductor layer 108.

The conductive layer 104 is provided over the insulating layer 106. The conductive layer 104 includes a region in contact with the top surface of the insulating layer 106.

The semiconductor layer 108, the insulating layer 106, and the conductive layer 104 are each provided to include a region overlapping with the opening portion 143. The semiconductor layer 108, the insulating layer 106, and the conductive layer 104 are each provided to cover the opening portion 143.

As illustrated in FIG. 7B and the like, one surface of the semiconductor layer 108 inside the opening portion 143 includes a region facing the conductive layer 104 with the insulating layer 106 therebetween. The other surface of the semiconductor layer 108 inside the opening portion 143 includes a region in contact with the top surface of the conductive layer 112a, a region in contact with the side surface of the insulating layer 110, and a region in contact with the side surface of the conductive layer 112b. Furthermore, outside the opening portion 143, the other surface of the semiconductor layer 108 includes a region in contact with the top surface of the conductive layer 112b.

In the transistor 100A, the source electrode and the drain electrode are positioned at different levels with respect to the surface of the substrate 102 over which the transistor 100A is formed, and a drain current flows in a direction perpendicular or substantially perpendicular to the surface of the substrate 102. In the transistor 100A, the drain current can also be regarded as flowing in the vertical direction or the substantially vertical direction. Accordingly, the transistor 100A can be referred to as a vertical transistor, a vertical-channel transistor, or a VFET (Vertical Field Effect Transistor).

In the transistor 100A, the source electrode and the drain electrode can be provided to overlap with each other; thus, the transistor size can be reduced and the area occupied by the transistor in the substrate plane can be significantly reduced as compared to a planar transistor.

The top surface shape of the opening portion 143 can be circular or elliptic, for example. Examples of the top surface shape of the opening portion 143 can include polygons such as a triangle, a tetragon (including a rectangle, a rhombus, and a square), and a pentagon; and polygons with rounded corners. The top surface shape of the opening portion 143 is preferably circular as illustrated in FIG. 7A. When the top surface shape of the opening portion 143 is circular, processing accuracy at the time of formation of the opening portion 143 can be high, whereby the opening portion 143 can be formed to have a minute size. In this specification and the like, a circular shape is not necessarily a perfect circular shape.

The channel length and the channel width of the transistor 100A are described.

In the semiconductor layer 108, a region in contact with the conductive layer 112a functions as one of a source region and a drain region, a region in contact with the conductive layer 112b functions as the other of the source region and the drain region, and a region between the source region and the drain region functions as a channel formation region.

The channel length of the transistor is a distance between the source region and the drain region. In FIG. 7B and FIG. 8A, a channel length L100A of the transistor 100A is indicated by a dashed double-headed arrow. In FIG. 7B and FIG. 8A, the distance along the semiconductor layer 108 between the top surface of the conductive layer 112a and the top surface of the conductive layer 112b is shown as the channel length L100A of the transistor 100A.

Note that as the channel length L100A of the transistor 100A, a thickness T110 that is the total thickness of the insulating layer 110a, the insulating layer 110b, and the insulating layer 110c in a region between the top surface of the conductive layer 112a and the bottom surface of the conductive layer 112b (the thickness T110 is indicated by a dashed-dotted double-headed arrow in FIG. 7B and FIG. 8A) is sometimes used. Alternatively, the sum of the thickness T110 and the thickness of the conductive layer 112b is sometimes used as the channel length L100A of the transistor 100A.

Here, the channel length L100A of the transistor 100A is determined, for example, by the thicknesses of the insulating layer 110a, the insulating layer 110b, the insulating layer 110c, and the conductive layer 112b or an angle θ110 between the formation surface of the semiconductor layer 108 in the opening portion 143 (here, the side surfaces of the insulating layer 110a, the insulating layer 110b, the insulating layer 110c, and the conductive layer 112b) and the formation surface of the insulating layer 110a (here, the top surface of the conductive layer 112a). The channel length L100A is not affected by the performance of a light-exposure apparatus used for forming the transistor. Hence, the channel length L100A can be a smaller value than the resolution limit of the light-exposure apparatus and thus the transistor can be miniaturized.

The channel length L100A can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm. For example, the channel length L100 can be greater than or equal to 100 nm and less than or equal to 1 μm.

The thickness T110 can be, for example, greater than or equal to 5 nm and less than 3 μm, greater than or equal to 7 nm and less than or equal to 2.5 μm, greater than or equal to 10 nm and less than or equal to 2 μm, greater than or equal to 10 nm and less than or equal to 1.5 μm, greater than or equal to 10 nm and less than or equal to 1.2 μm, greater than or equal to 10 nm and less than or equal to 1 μm, greater than or equal to 10 nm and less than or equal to 500 nm, greater than or equal to 10 nm and less than or equal to 300 nm, greater than or equal to 10 nm and less than or equal to 200 nm, greater than or equal to 10 nm and less than or equal to 100 nm, greater than or equal to 10 nm and less than or equal to 50 nm, greater than or equal to 10 nm and less than or equal to 30 nm, or greater than or equal to 10 nm and less than or equal to 20 nm.

The angle θ110 can be, for example, greater than or equal to 300 and less than or equal to 90°, greater than or equal to 350 and less than or equal to 85°, greater than or equal to 40° and less than or equal to 80°, greater than or equal to 450 and less than or equal to 80°, greater than or equal to 500 and less than or equal to 80°, greater than or equal to 550 and less than or equal to 80°, greater than or equal to 600 and less than or equal to 80°, greater than or equal to 650 and less than or equal to 80°, or greater than or equal to 700 and less than or equal to 80°. The smaller angle θ110 is preferable because the coverage with a layer (e.g., semiconductor layer 108) formed along a side wall of the opening portion 143 (here, the side surfaces of the insulating layer 110a, the insulating layer 110b, the insulating layer 110c, and the conductive layer 112b) can be improved. Meanwhile, the angle θ110 closer to 900 is preferable because of a smaller area occupied by the transistor in the substrate plane.

Reducing the channel length L100A can increase the on-state current of the transistor 100A. For example, with the use of the transistor 100A in a semiconductor device such as a display device or a memory device, a circuit capable of high-speed operation can be formed. Furthermore, the area occupied by the circuit can be reduced. Accordingly, with the use of the transistor 100A in a semiconductor device such as a display device or a memory device, the semiconductor device can be downsized.

For example, when the transistor 100A is used in a display device, the bezel of the display device can be narrowed. Even in a large-sized or high-definition display device with an increased number of wirings, for example, the use of the transistor 100A can reduce signal delay in wirings and can reduce display unevenness.

The channel width of the transistor 100A is the length of the source region or the length of the drain region in the plan view (FIG. 7A). In other words, the channel width of the transistor 100A is the length of a region where the semiconductor layer 108 is in contact with the conductive layer 112a or the length of a region where the semiconductor layer 108 is in contact with the conductive layer 112b in the plan view. Alternatively, as the channel width of the transistor 100A, an intermediate value between the length of the region where the semiconductor layer 108 and the conductive layer 112a are in contact with each other in the plan view and the length of the region where the semiconductor layer 108 and the conductive layer 112b are in contact with each other in the plan view is used in some cases.

Here, the channel width of the transistor 100A is described as the length of the perimeter of the region where the semiconductor layer 108 and the conductive layer 112b are in contact with each other in the plan view. In FIGS. 7A, 7B, and 8A, the channel width W100 of the transistor 100A is indicated by a solid double-headed arrow. The channel width W100 can also be referred to as the length of the perimeter of the opening portion 143 in the plan view.

The channel width W100 is determined by the top surface shape of the opening portion 143, for example. In FIGS. 7A and 7B and FIG. 8A, a width D143 of the opening portion 143 is indicated by a dashed-two-dotted double-headed arrow. The width D143 is the shorter side of the smallest rectangle circumscribing the opening portion 143 in the plan view. In the case where the opening portion 143 is formed by a photolithography method, the width D143 of the opening portion 143 is larger than or equal to the resolution limit of a light-exposure apparatus. The width D143 is, for example, greater than or equal to 0.20 μm and less than 5.0 μm. Note that when the top surface shape of the opening portion 143 is circular, the width D143 corresponds to the diameter of the opening portion 143, and the channel width W100 can be calculated to be “D143×π”.

The description of the transistor 100 in <Structure example 1 of transistor> can be referred to for the components of the transistor 100A other than the above.

### Structure Example 3 of Transistor

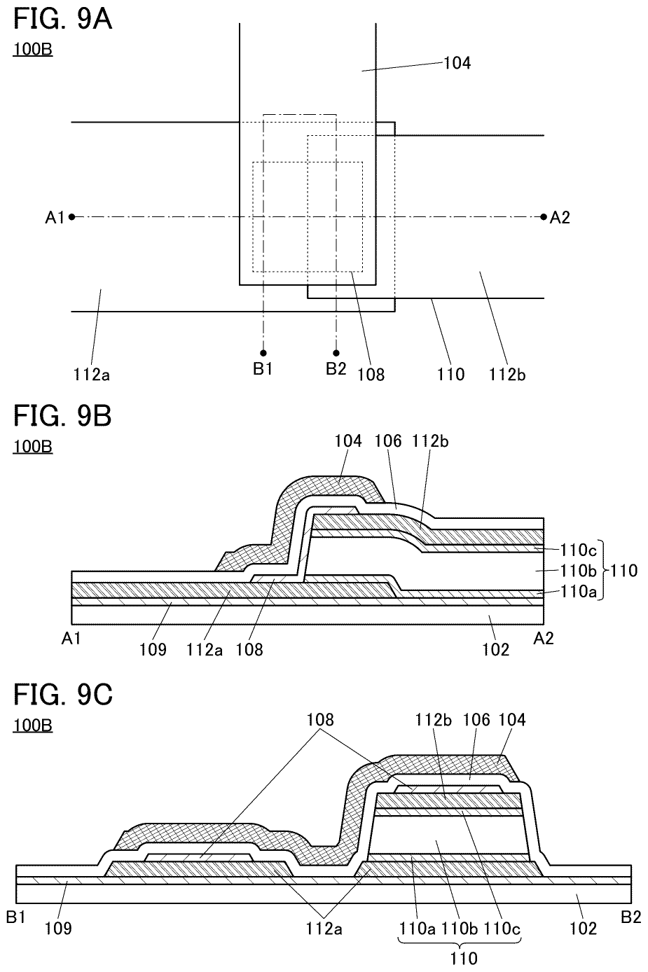

FIG. 9A is a plan view of a transistor 100B. FIG. 9B is a cross-sectional view taken along the dashed-dotted line A1-A2 in FIG. 9A. FIG. 9C is a cross-sectional view taken along the dashed-dotted line B1-B2 in FIG. 9A. Note that some components of the transistor 100B (e.g., an insulating layer) are not illustrated in FIG. 9A.

Like the transistor 100A, the transistor 100B is a vertical transistor. However, in the transistor 100A, the semiconductor layer 108 is provided along the opening portion 143 formed in the insulating layer 110 and the conductive layer 112b, whereas in the transistor 100B, the semiconductor layer 108 is provided along the side surfaces of the island-shaped insulating layer 110 and conductive layer 112b, which is different from the transistor 100A.

The transistor 100B is provided over an insulating layer 109 provided over the substrate 102.

The transistor 100B includes the conductive layer 104, the insulating layer 106, the semiconductor layer 108, the conductive layer 112a, and the conductive layer 112b. The conductive layer 104 functions as a gate electrode, and part of the insulating layer 106 functions as a gate insulating layer. The conductive layer 112a functions as one of a source electrode and a drain electrode, and the conductive layer 112b functions as the other of the source electrode and the drain electrode. In the semiconductor layer 108, between the source electrode and the drain electrode, the region that overlaps with the gate electrode with the gate insulating layer therebetween functions as a channel formation region. In the semiconductor layer 108, a region in contact with the source electrode functions as a source region and a region in contact with the drain electrode functions as a drain region.

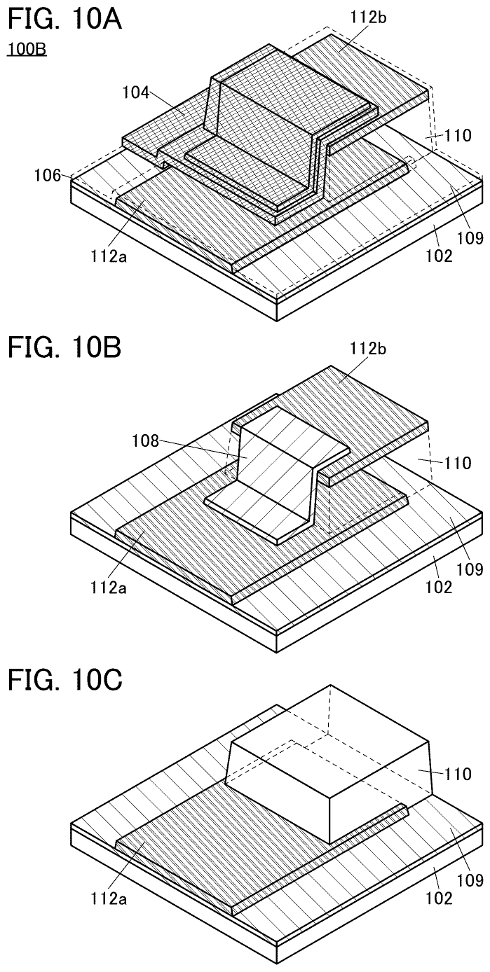

FIGS. 10A to 10C are perspective views of a structure including the transistor 100B. FIG. 10A is a perspective view of the structure. Note that some insulating layers (the insulating layer 110 and the insulating layer 106) are transparent and only outlines thereof are indicated by dashed lines. FIG. 10B is a perspective view obtained by omitting the conductive layer 104 and the insulating layer 106 from the perspective view in FIG. 10A. FIG. 10C is a perspective view obtained by omitting the semiconductor layer 108 and the conductive layer 112b from the perspective view in FIG. 10B. Note that in the perspective view in FIG. 10C, the outline of the insulating layer 110 is indicated by a solid line.

The conductive layer 112a is provided over the insulating layer 109. The insulating layer 110 is provided over the conductive layer 112a and the insulating layer 109 to include a region overlapping with the conductive layer 112a. The conductive layer 112b is provided over the insulating layer 110. The conductive layer 112a includes a region in contact with the insulating layer 109. The insulating layer 110 is in contact with the conductive layer 112a and the conductive layer 112b and includes a region sandwiched therebetween. The conductive layer 112a has a region overlapping with the conductive layer 112b with the insulating layer 110 therebetween.

As illustrated in FIG. 9B, the conductive layer 112a includes a region where the insulating layer 110 is provided and a region where the insulating layer 110 is not provided. The side surface of the insulating layer 110 is positioned in a region overlapping with the conductive layer 112a.

The semiconductor layer 108 is provided over the conductive layer 112a, the conductive layer 112b, and the insulating layer 110. The semiconductor layer 108 includes a region in contact with the top and side surfaces of the conductive layer 112b, the side surface of the insulating layer 110, and the top surface of the conductive layer 112a. The semiconductor layer 108 is connected to the conductive layer 112a and the conductive layer 112b. The semiconductor layer 108 has a shape along the shapes of the top and side surfaces of the conductive layer 112b, the side surface of the insulating layer 110, and the top surface of the conductive layer 112a. The semiconductor layer 108 is provided across a region where the insulating layer 110 is provided over the conductive layer 112a and a region where the insulating layer 110 is not provided over the conductive layer 112a.

The semiconductor layer 108 includes a first region in contact with the conductive layer 112a, a second region in contact with the side surface of the insulating layer 110, and a third region in contact with the conductive layer 112b. The first region is in contact with the second region, and the second region is in contact with the third region. It can be said that the first region is continuous with the second region, and the second region is continuous with the third region. The first region functions as one of a source region and a drain region, and the third region functions as the other of the source region and the drain region. The channel formation region is positioned in the second region.

As illustrated in FIG. 9C, the insulating layer 110 includes a side surface that is not in contact with the semiconductor layer 108. The side surface is in contact with the insulating layer 106. In other words, the insulating layer 110 includes the side surface in contact with the semiconductor layer 108 and the insulating layer 106 in the cross-sectional view along the dashed-dotted line A1-A2, and the side surface in contact with the insulating layer 106 in the cross-sectional view along the dashed-dotted line B1-B2.

The insulating layer 106 functioning as the gate insulating layer of the transistor 100B is provided to cover the semiconductor layer 108. The insulating layer 106 includes a region in contact with the top surface and a side surface of the semiconductor layer 108 and the side surface of the insulating layer 110. The insulating layer 106 includes a region in contact with the top surface and a side surface of the semiconductor layer 112a, the top surface and the side surface of the conductive layer 112b, and the top surface of the insulating layer 109.

The conductive layer 104 functioning as the gate electrode of the transistor 100B is provided over the insulating layer 106 and include a region in contact with the top surface of the insulating layer 106. The conductive layer 104 has a region overlapping with the semiconductor layer 108 with the insulating layer 106 therebetween. In addition, the conductive layer 104 includes a region facing the side surface of the insulating layer 110 with the insulating layer 106 and the semiconductor layer 108 therebetween. The conductive layer 104 is provided to cover at least a region where the semiconductor layer 108 is in contact with the side surface of the insulating layer 110. In this manner, the region can serve as the channel formation region of the transistor 100B.

The conductive layer 104 preferably covers the entire semiconductor layer 108. As illustrated in FIG. 9A, the conductive layer 104 preferably covers the semiconductor layer 108 in the plan view. The semiconductor layer 108 covered with the conductive layer 104 can inhibit damage to the semiconductor layer 108 caused when the layer is formed over the transistor 100B. Consequently, the transistor 100B with favorable electrical characteristics and high reliability can be obtained. Note that the semiconductor layer 108 may include a region not covered with the conductive layer 104.

Over the conductive layer 112a, a step is formed between a region where the insulating layer 110 and the conductive layer 112b are provided and a region where neither the insulating layer 110 nor the conductive layer 112b is provided, and the semiconductor layer 108, the insulating layer 106, and the conductive layer 104 can be provided along the step.

As described above, the transistor 100B is a vertical transistor like the transistor 100A. Thus, the effect of the transistor 100B can be similar to that of the above-described transistor 100A.

The insulating layer 109 is provided between the substrate 102 and each of the transistor 100B and the insulating layer 110. The insulating layer 109 includes a region in contact with the conductive layer 112a, a region in contact with the insulating layer 110, and a region in contact with the insulating layer 106. For the insulating layer 109, any of the materials that can be used for the insulating layer 110 given above can be used.

The insulating layer 109 preferably has a barrier property. For the insulating layer 109, a material that does not easily allow diffusion of impurities (e.g., water and hydrogen) contained in the substrate 102 is preferably used. Thus, diffusion of impurities from the substrate 102 into the transistor 100B can be inhibited.

For the insulating layer 109 functioning as a barrier film, one or more of an oxide containing one or both of aluminum and hafnium, an oxide containing magnesium, an oxide containing gallium, a nitride containing aluminum, a nitride containing silicon, and a nitride oxide containing silicon can be used, for example. Specifically, for the insulating layer 109, one or more of aluminum oxide, hafnium oxide, hafnium aluminate, magnesium oxide, gallium oxide, gallium zinc oxide, aluminum nitride, silicon nitride, and silicon nitride oxide can be suitably used, for example.

For the insulating layer 109, it is preferable to use a material that contains impurities (e.g., water and hydrogen) that reduce the electric resistance of the semiconductor layer 108 and releases the impurities by heat treatment or the like. The impurities released from the insulating layer 109 are diffused into a region of the conductive layer 112a that is in contact with the insulating layer 109. When the impurities diffused into the conductive layer 112a are diffused into the region of the semiconductor layer 108 that is in contact with the conductive layer 112a, the region contains the impurities and can have reduced electric resistance. That is, the electric resistance of one of the source region and the drain region can be reduced. Accordingly, the transistor can have a high on-state current and the semiconductor device can operate at high speed.

Since a metal oxide layer is used as the semiconductor layer 108 in one embodiment of the present invention, an impurity released from the insulating layer 109 preferably contains hydrogen. When hydrogen contained in the insulating layer 109 is diffused into the semiconductor layer 108 through the conductive layer 112a, the region of the semiconductor layer 108 in contact with the conductive layer 112a contains hydrogen and has a higher carrier concentration. That is, the electric resistance of one of the source region and the drain region can be reduced. The insulating layer 109 preferably contains silicon and hydrogen, for example. Typically, silicon nitride containing hydrogen can be suitably used for the insulating layer 109.

It is further preferable that for the insulating layer 109, a material that releases impurities that reduce the electric resistance of the conductive layer 112a be used. Consequently, the electric resistance of the conductive layers 112a can be reduced.

The thickness of the insulating layer 109 is preferably greater than or equal to 5 nm and less than or equal to 100 nm, further preferably greater than or equal to 10 nm and less than or equal to 100 nm, further preferably greater than or equal to 20 nm and less than or equal to 100 nm, further preferably greater than or equal to 20 nm and less than or equal to 50 nm.

In the case where the thickness of the insulating layer 109 is large and the amount of impurities released from the insulating layer 109 is too large, the amount of impurities diffusing into the semiconductor layer 108 is increased, so that the amount of oxygen vacancies (V_{O}) and V_{O}H generated by the impurities might be larger than the amount of V_{O} and V_{O}H repaired by oxygen supplied from the insulating layer 110b. Meanwhile, in the case where the thickness of the insulating layer 109 is small, the amount of impurities diffusing into the conductive layer 112a and the semiconductor layer 108 is small, which might increase the electric resistance of the conductive layer 112a and the electrical resistance of one of the source region and the drain region. Setting the thickness of the insulating layer 109 within the above range, an increase in V_{O} and V_{O}H in the channel formation region can be inhibited and the electric resistance of the conductive layer 112a and the electrical resistance of one of the source region and the drain region can be reduced. Note that the thickness of the insulating layer 109 is not limited to the above range.

The insulating layer 110a includes a region in contact with the top surface of the insulating layer 109 and the top surface and the side surface of the conductive layer 112a. Thus, impurities contained in the insulating layer 109 and the conductive layer 112a can be inhibited from being diffused into the channel formation region in the semiconductor layer 108 through the insulating layer 110b.

The insulating layer 109 preferably includes a region having a higher hydrogen content than the insulating layer 110a. The film density of the insulating layer 110a is preferably higher than the film density of the insulating layer 109.

Note that impurities released from the insulating layer 109 are diffused into the channel formation region through the conductive layer 112a and one of the source region and the drain region of the semiconductor layer 108 in some cases. However, oxygen is supplied from the insulating layer 110b to at least the region of the semiconductor layer 108 that is in contact with the insulating layer 110b, so that oxygen vacancies (V_{O}) and V_{O}H in the channel formation region can be reduced. This inhibits the threshold voltage shift and allows the transistor to have both a low cut-off current (a drain current at the time of the gate voltage being OV) and a high on-state current. Consequently, the semiconductor device can have both low power consumption and high performance.

The insulating layer 109 preferably includes a region having a higher hydrogen content than the insulating layer 110a. The hydrogen content of the insulating layer 110 or the like can be analyzed by secondary ion mass spectrometry (SIMS), for example.

When the film formation conditions for the insulating layer 109 are different from those for the insulating layer 110a, the amount of released hydrogen can be adjusted. Specifically, the film formation conditions for the insulating layer 109 may be different from those for the insulating layer 110a in any one or more of a film formation power (film formation power density), a film formation pressure, the kind of a film formation gas, the flow rate ratio of a film formation gas, a film formation temperature, and the distance between the substrate and an electrode. For example, the film formation power density for the insulating layer 109 may be lower than that for the insulating layer 110a, in which case the insulating layer 109 can have a higher hydrogen content than the insulating layer 110a. Accordingly, the amount of hydrogen released from the insulating layer 109 due to heat applied thereto can be increased.

The film formation gas used for the insulating layer 109 preferably contains a larger amount of hydrogen than the film formation gas used for the insulating layer 110a. Specifically, in the case where a silicon nitride film or a silicon nitride oxide film is formed over the insulating layer 109 and the insulating layer 110a by a plasma-enhanced chemical vapor deposition (PECVD) method, the proportion of the flow rate of an ammonia gas to the whole film formation gas used for the insulating layer 109 (hereinafter also referred to as ammonia flow rate ratio) is preferably higher than the proportion of the flow rate of an ammonia gas used for the insulating layer 110a. The formation of the insulating layer 109 under the condition where the ammonia flow rate ratio is high can increase the hydrogen content in the insulating layer 109. Furthermore, the amount of hydrogen released from the insulating layer 109 due to heat applied thereto can be increased.

The film density of the insulating layer 110a is preferably higher than the film density of the insulating layer 109. In that case, hydrogen contained in the insulating layer 109 can be inhibited from being diffused into the channel formation region of the semiconductor layer 108 through the insulating layer 110a and the insulating layer 110b. The film density can be evaluated by Rutherford backscattering spectrometry (RBS) or X-ray reflection (XRR), for example. A difference in film density can be evaluated using a TEM image of a cross section in some cases. In the TEM observation, a transmission electron (TE) image is dark-colored (dark) when the film density is high, and a transmission electron (TE) image is pale (bright) when the film density is low. Thus, the transmission electron (TE) image of the insulating layer 110a is a dark-colored (dark) image compared to that of the insulating layer 109 in some cases. Note that since the insulating layer 109 and the insulating layer 110a have different film densities even when containing the same materials, it is sometimes possible to identify the boundary between these insulating layers by a difference in contrast in a TEM image of a cross section.

Although the structure where the insulating layer 110 has a stacked-layer structure of three layers is described here, one embodiment of the present invention is not limited thereto. The insulating layer 110 preferably includes at least the insulating layer 110b. A structure where one or both of the insulating layer 110a and the insulating layer 110c are not included can also be employed. Alternatively, the insulating layer 110 can have a stacked-layer structure of four or more layers.

The top surface shape of the conductive layer 112b is preferably the same or substantially the same as the top surface shape of the insulating layer 110. FIG. 9A and the like illustrate a structure in which the top surface shape of the conductive layer 112b is the same as the top surface shape of the insulating layer 110. The conductive layer 112b and the insulating layer 110 can be formed using the same mask layer. For example, an insulating film to be the insulating layer 110 and a conductive film to be the conductive layer 112b over the insulating film are formed, and a mask layer (e.g., a resist mask) is formed over the conductive film. Then, the conductive film and the insulating film are processed using the mask layer as a mask, whereby the conductive layer 112b and the insulating layer 110 having the same or substantially the same top surface shapes can be formed. Processing the insulating film to be the insulating layer 110 and the conductive film to be the conductive layer 112b in the same step can reduce the manufacturing cost. Although the top surface shapes of the conductive layer 112b and the insulating layer 110 are rectangular in FIG. 9A and the like, there is no particular limitation on the top surface shapes of the conductive layer 112b and the insulating layer 110.

For the components of the transistor 100B other than the above, the description of the transistor 100 in <Structure example 1 of transistor> and the description of the transistor 100A in <Structure example 2 of transistor> can be referred to.

### Example of Method for Forming Transistor

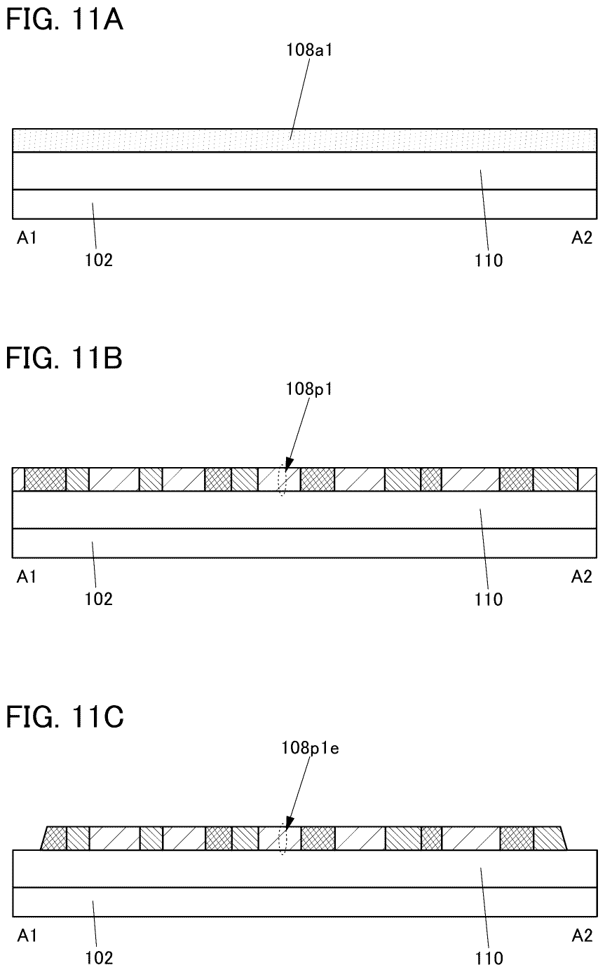

An example of a method for forming a transistor of one embodiment of the present invention is described below with reference to FIGS. 11A to 11C, FIGS. 12A to 12C, FIGS. 13A to 13C, and FIGS. 14A to 14C. Note that as for materials and formation methods of components included in the transistor, portions similar to those described in <Structure example 1 of transistor> and the like are not described in some cases.

Thin films included in the transistor (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of the CVD method include a PECVD method and a thermal CVD method. An example of the thermal CVD method is a metal organic CVD (MOCVD) method.

Thin films included in the transistor (e.g., insulating films, semiconductor films, and conductive films) can be formed by a wet film formation method such as spin coating, dipping, spray coating, inkjetting, dispensing, screen printing, or offset printing, a doctor knife method, slit coating, roll coating, curtain coating, or knife coating.

Thin films included in the transistor can be processed by a photolithography method or the like. Besides, a nanoimprinting method, a sandblasting method, a lift-off method, or the like can be employed to process the thin films. Alternatively, island-shaped thin films can be directly formed by a deposition method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by light exposure and development.

As light used for exposure in the photolithography method, for example, light with an i-line (wavelength: 365 nm), light with a g-line (wavelength: 436 nm), light with an h-line (wavelength: 405 nm), or light in which the i-line, the g-line, and the h-line are mixed can be used. Alternatively, ultraviolet rays, KrF laser light, ArF laser light, or the like can be used. Exposure can also be performed by liquid immersion exposure technique. As the light for exposure, extreme ultraviolet (EUV) light or X-rays can also be used. Furthermore, instead of the light used for the exposure, an electron beam can also be used. It is preferable to use EUV light, X-rays, or an electron beam because extremely minute processing can be performed. Note that a photomask is not needed when exposure is performed by scanning with a beam such as an electron beam.

For etching of thin films, one or more of a dry etching method, a wet etching method, and a sandblast method can be used.

An example of a method for forming the transistor 100 illustrated in FIGS. 6A to 6C is described below with reference to FIGS. 11A to 11C, FIGS. 12A to 12C, FIGS. 13A to 13C, and FIGS. 14A to 14C. Each of these drawings is a cross-sectional view taken along the dashed-dotted line A1-A2 in FIG. 6B.

First, the insulating layer 110 is formed over the substrate 102. A sputtering method or a PECVD method can be suitably used for the formation of the insulating layer 110.

The substrate temperature at the time of forming the insulating layer 110 by a PECVD method is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C., further preferably higher than or equal to 350° C. and lower than or equal to 400° C. With the substrate temperature at the time of forming the insulating layer 110 in the above range, impurities (e.g., water and hydrogen) released from the insulating layer 110 itself can be decreased, which inhibits the diffusion of the impurities into the semiconductor layer 108. Consequently, the transistor 100 can have favorable electrical characteristics and high reliability. In the case where the insulating layer 110 is formed by a sputtering method, the substrate temperature at the time of the formation can be room temperature.

Since the formation of the insulating layer 110 precedes the formation of the semiconductor layer 108, heat applied in the formation of the insulating layer 110 is unlikely to cause the release of oxygen from the semiconductor layer 108.

After the insulating layer 110 is formed, treatment for supplying oxygen to the insulating layer 110 can be performed. Oxygen can be supplied by, for example, an ion implantation method, an ion doping method, a plasma immersion ion implantation method, or plasma treatment. For the plasma treatment, an apparatus in which an oxygen gas is made to be plasma by high-frequency power can be suitably used. Examples of the apparatus in which gas is made to be plasma by high-frequency power include a PECVD apparatus, a plasma etching apparatus, and a plasma ashing apparatus. The plasma treatment is preferably performed in an atmosphere containing oxygen. For example, plasma treatment is preferably performed in an atmosphere containing one or more of oxygen, dinitrogen monoxide (N₂O), nitrogen dioxide (NO₂), carbon monoxide, and carbon dioxide.

Note that the plasma treatment can be performed without exposure of the surface of the insulating layer 110 to the air. For example, in the case where a PECVD apparatus is used to form the insulating layer 110, the plasma treatment is preferably performed with the PECVD apparatus. In that case, productivity can be improved. Specifically, after the insulating layer 110 is formed with the PECVD apparatus, N₂O plasma treatment can be successively performed with the same apparatus.

Next, treatment for supplying oxygen to the insulating layer 110 is preferably performed. For example, when a film containing oxygen is formed over the insulating layer 110, oxygen can be supplied to the insulating layer 110. Alternatively, when heat treatment is performed after a film containing oxygen is formed, oxygen can be supplied to the insulating layer 110. For example, when a film of aluminum oxide, hafnium oxide, hafnium aluminate, indium oxide, indium tin oxide (ITO), indium tin oxide containing silicon (ITSO), or a metal oxide material that can be used for the semiconductor layer 108 is formed over the insulating layer 110, oxygen can be effectively supplied to the insulating layer 110.

In the case where heat treatment is performed after the film containing oxygen is formed over the insulating layer 110, the temperature of the heat treatment is preferably higher than or equal to 150° C. and lower than the strain point of the substrate, higher than or equal to 200° C. and lower than or equal to 450° C., higher than or equal to 230° C. and lower than or equal to 400° C., higher than or equal to 250° C. and lower than or equal to 350° C., or higher than or equal to 250° C. and lower than or equal to 300° C., for example. The heat treatment can be performed in an atmosphere containing one or more of a noble gas, nitrogen, and oxygen. As a nitrogen-containing atmosphere or an oxygen-containing atmosphere, clean dry air (CDA) can be used. Note that the content of hydrogen, water, or the like in the atmosphere is preferably as low as possible. As the atmosphere, a high-purity gas with a dew point of −60° C. or lower, preferably −100° C. or lower is preferably used. With the use of an atmosphere where the content of hydrogen, water, or the like is as low as possible, entry of hydrogen, water, or the like into the insulating layer 110 can be prevented as much as possible. An oven, an RTA apparatus, or the like can be used for the heat treatment. With the RTA apparatus, the heat treatment time can be shortened.

After the oxygen supply treatment, the film containing oxygen formed over the insulating layer 110 is preferably removed.

The treatment for supplying oxygen to the insulating layer 110 is not limited to the above-described method. For example, an oxygen radical, an oxygen atom, an oxygen atomic ion, or an oxygen molecular ion is supplied to the insulating layer 110 by an ion doping method, an ion implantation method, or plasma treatment. Furthermore, a film that suppresses oxygen release is formed over the insulating layer 110 and then, oxygen can be supplied to the insulating layer 110 through the film. After the supply of oxygen, the film is preferably removed. As the film that suppresses oxygen release, a conductive film or a semiconductor film containing one or more of indium, zinc, gallium, tin, aluminum, chromium, tantalum, titanium, molybdenum, nickel, iron, cobalt, and tungsten.

The amount of oxygen released from the insulating layer 110 to the channel formation region of the transistor 100 is preferably large. Supplying oxygen to the insulating layer 110 increases the amount of oxygen contained in the insulating layer 110, which can increase the amount of oxygen supplied from the insulating layer 110 to the semiconductor layer 108. This allows the transistor 100 having a short channel length to have favorable electrical characteristics.

Next, the first amorphous film 108a1 is formed over the insulating layer 110 (FIG. 11A). This film formation corresponds to Step S1 in the flow chart shown in FIG. 3. As described above, the first amorphous film 108a1 is an amorphous indium oxide film. The description of FIG. 1A can be referred to for the details of the film formation method and the like.

Next, the first amorphous film 108a1 is subjected to the first heat treatment to be crystallized, whereby the first crystallized film 108p1 is formed (FIG. 11B). This heat treatment corresponds to Step S2 in the flow chart shown in FIG. 3. As described above, the first crystallized film 108p1 is a polycrystalline indium oxide film formed of randomly aligned crystal grains with a variety of grain diameters. The description of FIG. 1B can be referred to for the details of the temperature, the atmosphere, and the like of the heat treatment.

In this formation method example, the first amorphous film 108a1 is formed over the insulating layer 110 (FIG. 11A) and then the first heat treatment is performed, so that the first crystallized film 108p1 is formed from the first amorphous film 108a1 (FIG. 11B); however, one embodiment of the present invention is not limited thereto. For example, a film having crystallinity (a film corresponding to the first crystallized film 108p1) can be formed over the insulating layer 110 by a sputtering method or an ALD method. In that case, the first heat treatment becomes unnecessary and thus the number of steps can be reduced.

Note that in the case where a film having crystallinity is formed by a sputtering method or an ALD method, the film formation is performed at a substrate temperature higher than that for forming the first amorphous film 108a1, whereby a film with high crystallinity can be formed. For example, in the case of using a sputtering method, a film with high crystallinity can be formed by reducing the content of hydrogen (H₂) in the sputtering gas or using a sputtering gas that does not contain hydrogen. For another example, in the case of employing an ALD method, the use of the first oxidizer that does not contain water (H₂O), hydrogen peroxide (H₂O₂), or the like enables formation of a film with high crystallinity.

Next, part of the first crystallized film 108p1 is removed to form a crystallized layer 108p1e (FIG. 11C). For the formation of the crystallized layer 108p1e, for example, a wet etching method can be suitably used (first wet etching). The crystallized layer 108p1e is preferably formed into an island shape in a region overlapping with the channel formation region of the transistor 100. Accordingly, the seed crystal layer 108s to be formed later can be selectively formed in a region overlapping with the channel formation region.

Note that the crystallized layer 108p1e can be omitted. This can reduce the number of steps for forming the transistor 100.

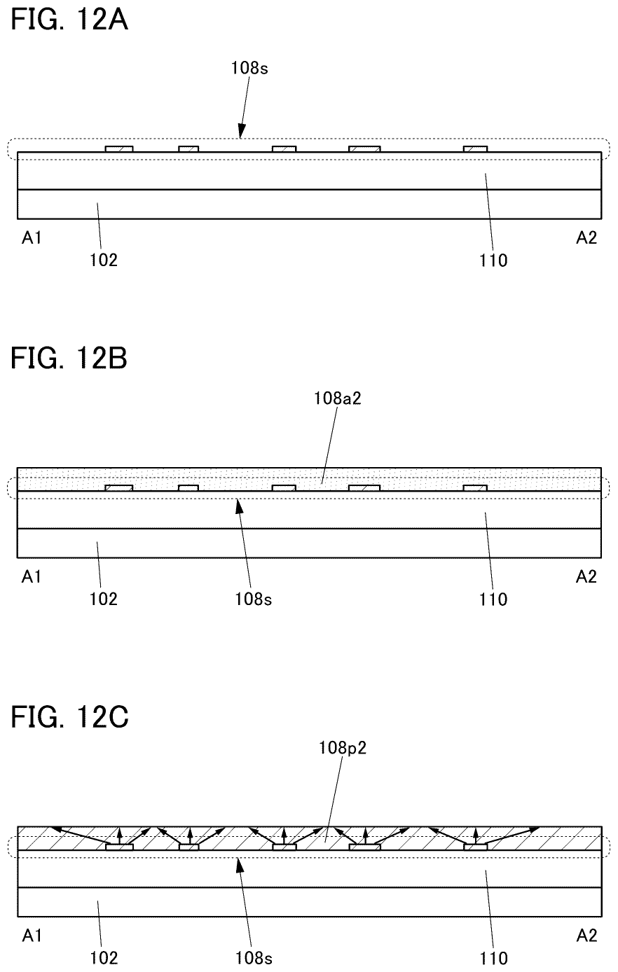

Next, wet etching (second wet etching) is performed on the crystallized layer 108p1e. This wet etching corresponds to Step S3 in the flow chart shown in FIG. 3. By the wet etching, part of the crystallized layer 108p1e is removed, specifically, the crystal grains other than the crystal grains with the crystal orientation having the lowest etching rate with respect to an etchant are removed, whereby the seed crystal layer 108s is formed (FIG. 12A). That is, the seed crystal layer 108s is a layer formed of crystal grains with the crystal orientation having the lowest etching rate with respect to an etchant (such a crystal orientation can be referred to as having the highest etching resistance to the etchant) among crystal grains having a variety of crystal orientations included in the crystallized layer 108p1e. For details of an etchant or the like that can be used for this wet etching, the description of FIG. 1C can be referred to.

Next, the second amorphous film 108a2 is formed over the seed crystal layer 108s and the insulating layer 110 (FIG. 12B). This film formation corresponds to Step S4 in the flow chart shown in FIG. 3. As described above, the second amorphous film 108a2 is an amorphous indium oxide film. The description of FIGS. 2A1 and 2A2 can be referred to for the details of the film formation method and the like.

Next, the second amorphous film 108a2 is subjected to the second heat treatment to be crystallized, whereby the second crystallized film 108p2 is formed (FIG. 12C). This heat treatment corresponds to Step S5 in the flow chart shown in FIG. 3. As described above, the second crystallized film 108p2 is an indium oxide film obtained in such a manner that the second amorphous film 108a2 grows in a crystal orientation reflecting the crystal structure of the seed crystal layer 108s, with respect to the top surface of the seed crystal layer 108s. In FIG. 12C, crystal growth progress is schematically shown with arrows. The crystal grains included in the second crystallized film 108p2 have the same crystal orientation as the crystal orientation of the seed crystal layer 108s. The description of FIGS. 2B1 and 2B2 can be referred to for the details of the temperature, the atmosphere, and the like of the heat treatment.

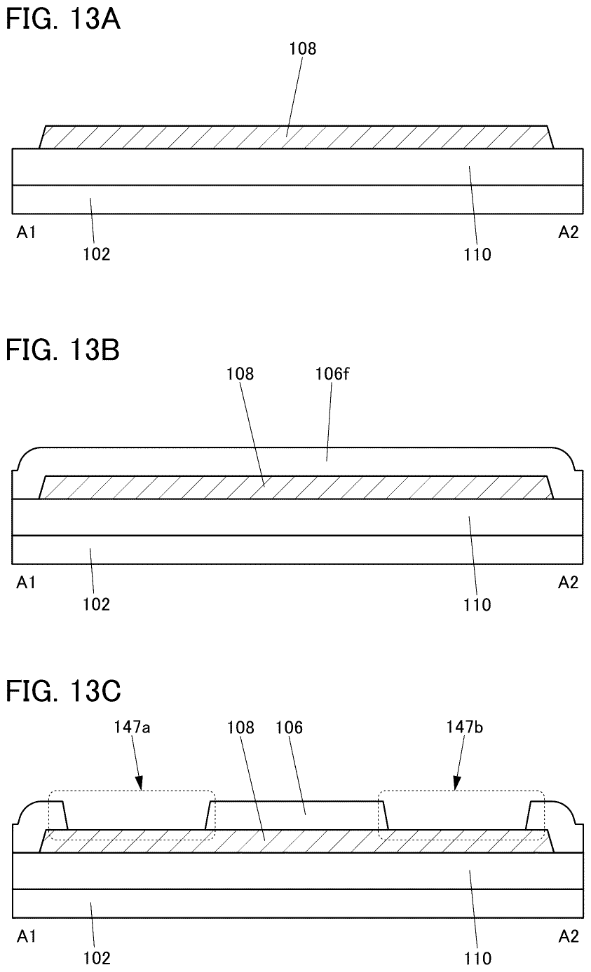

Next, part of the second crystallized film 108p2 is removed to form the semiconductor layer 108 (FIG. 13A). For the formation of the semiconductor layer 108, for example, a wet etching method can be suitably used (third wet etching). The semiconductor layer 108 is formed into an island shape in a region overlapping with the channel formation region of the transistor 100.

After the second crystallized film 108p2 is formed or processed into the semiconductor layer 108, heat treatment that can be performed after the formation of a film containing oxygen over the insulating layer 110 is preferably performed. By the heat treatment, hydrogen and water contained in the second crystallized film 108p2 or the semiconductor layer 108 or adsorbed on a surface thereof can be removed. Furthermore, by the heat treatment, the film quality of the second crystallized film 108p2 or the semiconductor layer 108 is improved (e.g., the number of defects is reduced or the crystallinity is increased) in some cases.

Oxygen can be supplied from the insulating layer 110 to the second crystallized film 108p2 or the semiconductor layer 108 by the heat treatment. Thus, oxygen vacancies (V_{O}) in the channel formation region of the transistor 100 can be reduced. At this time, it is further preferable that the heat treatment be performed before the semiconductor layer 108 is processed into the second crystallized film 108p2. Note that supply of oxygen to the channel formation region of the transistor 100 may be performed not only through the heat treatment but also in a heat application step in and after the formation of the second crystallized film 108p2 (e.g., the step of forming the insulating layer 106).

Note that the heat treatment can be omitted if not needed. The heat treatment can be omitted in this step, and heat treatment performed in a later step can also serve as the heat treatment in this step. In some cases, treatment at a high temperature (e.g., film formation step) in a later step can serve as the heat treatment in this step.

Next, an insulating film 106f to be the insulating layer 106 is formed to cover the semiconductor layer 108 and the insulating layer 110 (FIG. 13B). For formation of the insulating film 106f, a PECVD method or an ALD method can be suitably used, for example.

Since a metal oxide is used for the semiconductor layer 108, the insulating layer 106 preferably functions as a barrier film that inhibits diffusion of oxygen. When the insulating layer 106 has a function of inhibiting diffusion of oxygen, oxygen contained in the semiconductor layer 108 is inhibited from diffusing to above the insulating layer 106, and an increase in oxygen vacancies (V_{O}) in the semiconductor layer 108 can be inhibited. Consequently, the transistor 100 can have favorable electrical characteristics and high reliability.

When the temperature at the time of forming the insulating film 106f is increased, defects in the insulating layer 106 can be reduced. However, the high temperature at the time of forming the insulating film 106f sometimes allows release of oxygen from the semiconductor layer 108, which increases the amounts of oxygen vacancies (V_{O}) and V_{O}H in the semiconductor layer 108. The substrate temperature at the time of forming the insulating film 106f is preferably higher than or equal to 180° C. and lower than or equal to 450° C., further preferably higher than or equal to 200° C. and lower than or equal to 450° C., further preferably higher than or equal to 250° C. and lower than or equal to 450° C., further preferably higher than or equal to 300° C. and lower than or equal to 450° C., further preferably higher than or equal to 300° C. and lower than or equal to 400° C. When the substrate temperature at the time of forming the insulating film 106f is in the above range, release of oxygen from the semiconductor layer 108 can be inhibited while the defects in the insulating layer 106 can be reduced. Consequently, the transistor 100 can have favorable electrical characteristics and high reliability.

Before the formation of the insulating film 106f, a surface of the semiconductor layer 108 can be subjected to plasma treatment. By the plasma treatment, impurities (e.g., water) adsorbed on the surface of the semiconductor layer 108 can be reduced. Accordingly, impurities at the interface between the semiconductor layer 108 and the insulating layer 106 can be reduced, enabling the transistor 100 to have high reliability. Performing the plasma treatment in this manner is particularly favorable in the case where the surface of the semiconductor layer 108 is exposed to the air after the formation of the semiconductor layer 108 before the formation of the insulating film 106f. The plasma treatment can be performed in an atmosphere of oxygen, ozone, nitrogen, dinitrogen monoxide, argon, or the like. The plasma treatment and the formation of the insulating film 106f are preferably performed successively without exposure to the air.

Next, the insulating film 106f is processed to form the insulating layer 106 (FIG. 13C). The opening portion 147a and the opening portion 147b reaching the semiconductor layer 108 are provided in the insulating layer 106. The insulating layer 106 can be suitably formed by a dry etching method.

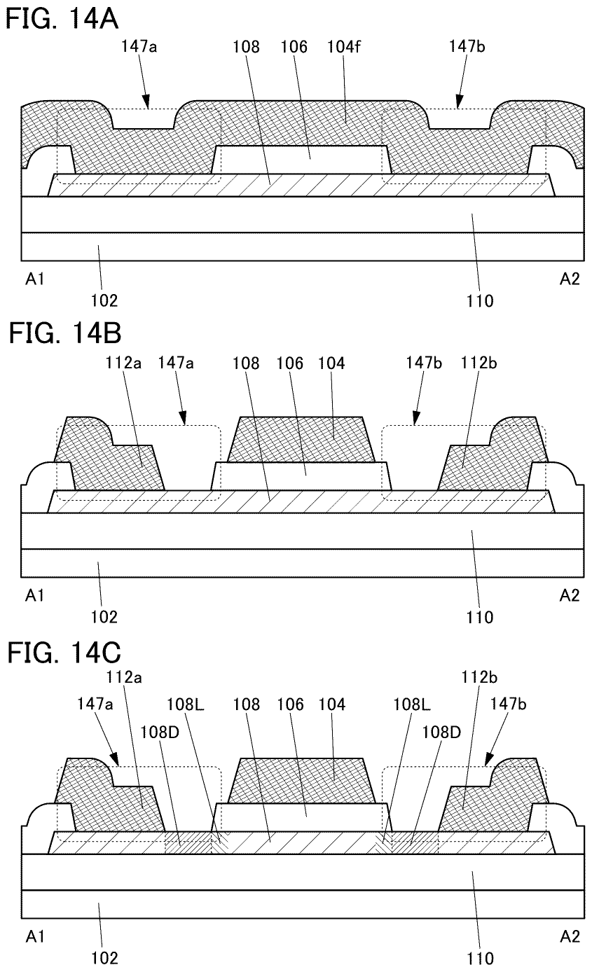

Next, a conductive film 104f to be the conductive layer 104, the conductive layer 112a, and the conductive layer 112b is formed over the insulating layer 106 (FIG. 14A). For the formation of the conductive film 104f, a sputtering method, a thermal CVD method (including an MOCVD method), or an ALD method can be suitably used, for example.

Next, the conductive film 104f is processed to form the conductive layer 104, the conductive layer 112a, and the conductive layer 112b (FIG. 14B). The conductive layer 104 is formed to include a region overlapping with the semiconductor layer 108 and the insulating layer 106. The conductive layer 112a is formed to include a region overlapping with the opening portion 147a. The conductive layer 112b is formed to include a region overlapping with the opening portion 147b.

An impurity is supplied (or added or implanted) to the semiconductor layer 108 using the conductive layer 104, the conductive layer 112a, and the conductive layer 112b as masks. Thus, the region 108D is formed in a region of the semiconductor layer 108 that overlaps with none of the conductive layer 104, the conductive layer 112a, the conductive layer 112b, and the insulating layer 106, and the region 108L is formed in a region of the semiconductor layer 108 that overlaps with none of the conductive layer 104, the conductive layer 112a, and the conductive layer 112b and overlaps with the insulating layer 106 (FIG. 14C). At this time, the conditions of the treatment for supplying the impurity are preferably determined in consideration of the material and thickness of the conductive layer 104 serving as a mask so that the amount of the impurity which is supplied to the region of the semiconductor layer 108 overlapping with the conductive layer 104 is as small as possible. Thus, a channel formation region with sufficiently reduced impurity concentration can be formed in the region of the semiconductor layer 108 overlapping with the conductive layer 104.

A plasma ion doping method or an ion implantation method can be suitably used for the supply of the impurity element. In the above methods, the concentration profile in the depth direction can be controlled with high accuracy by the acceleration voltage and the dose of ions, for example. The use of a plasma ion doping method can increase productivity. When an ion implantation method using mass separation is employed, the purity of an impurity to be supplied can be increased.

The conditions for supplying the impurity are preferably adjusted such that the impurity concentration is highest at a surface of the semiconductor layer 108 or a portion near the surface.

As a source material used for supplying the impurity, a gas containing the above impurity element can be used, for example. In the case where boron is supplied, one or both of a B₂H₆ gas and a BF₃ gas can be typically used. In the case where phosphorus is supplied, a PH₃ gas can be typically used. A mixed gas in which any of these source gases is diluted with a noble gas can also be used.

Alternatively, as the source material used for supplying the impurity, CH₄, N₂, NH₃, AlH₃, AlCl₃, SiH₄, Si₂H₆, F₂, HF, H₂, (C₅H₅)₂Mg, or a noble gas can be used, for example. Note that the source material is not limited to a gas, and a solid or a liquid can also be employed by being vaporized by heating.

The supply of the impurity can be controlled by setting the conditions such as the acceleration voltage and the dose in consideration of the compositions, the densities, the thicknesses, and the like of the insulating layer 106 and the semiconductor layer 108.

In the case where boron is supplied by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dose can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus is supplied by an ion implantation method or a plasma ion doping method, the acceleration voltage can be higher than or equal to 10 kV and lower than or equal to 100 kV, preferably higher than or equal to 30 kV and lower than or equal to 90 kV, further preferably higher than or equal to 40 kV and lower than or equal to 80 kV. The dose can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

Note that the method for supplying the impurity is not limited to the above methods; plasma treatment, treatment employing thermal diffusion by heating, or the like can be used, for example. In the case of a plasma treatment method, an impurity can be supplied in such a manner that plasma is generated in a gas atmosphere containing the impurity to be supplied and plasma treatment is performed. A dry etching apparatus, an ashing apparatus, a plasma CVD apparatus, a high-density plasma CVD apparatus, or the like can be used to generate the plasma.

For example, when plasma treatment is performed with a plasma CVD apparatus in an atmosphere containing a gas containing hydrogen, hydrogen can be supplied as the impurity to the region of the semiconductor layer 108 that does not overlap with the conductive layer 104.

Through the above steps, the transistor 100 of one embodiment of the present invention can be formed.

This embodiment can be combined with the other embodiments as appropriate. In this specification, in the case where a plurality of structure examples are shown in one embodiment, the structure examples can be combined as appropriate.

### Embodiment 2

The transistors (e.g., the transistors 100, 100A, and 100B) for which the metal oxide layer of one embodiment of the present invention is usable can be used for a display device, for example. In this embodiment, a circuit and the like that can be employed in the display device of one embodiment of the present invention will be described.

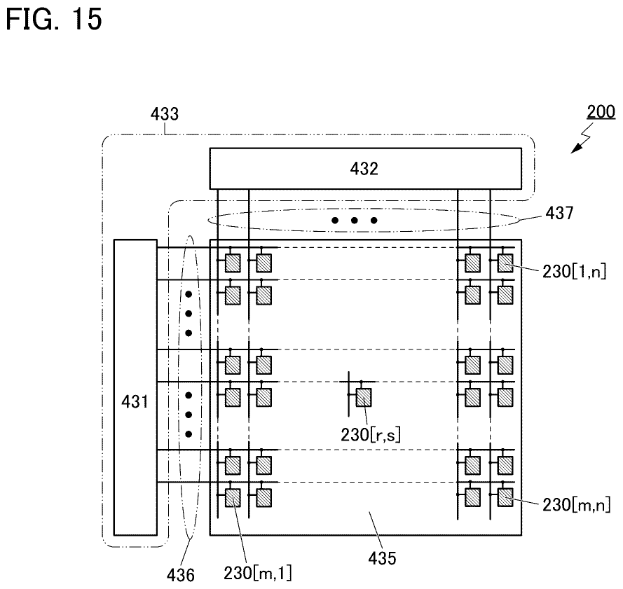

FIG. 15 is a block diagram illustrating a display device 200. The display device 200 includes a display portion 435, a first driver circuit portion 431, and a second driver circuit portion 432.

The display portion 435 includes a plurality of pixels 230 arranged in a matrix of m rows (m is an integer greater than or equal to 1) and n columns (n is an integer greater than or equal to 1).

In FIG. 15, the pixel 230 in the first row and the n-th column is denoted as a pixel 230[1,n], the pixel 230 in the m-th row and the first column is denoted as a pixel 230[m,1], and the pixel 230 in the m-th row and the n-th column is denoted as a pixel 230[m,n]. A given pixel 230 included in the display portion 435 is denoted as a pixel 230[r,s] in some cases. Note that r is an integer greater than or equal to 1 and less than or equal to m, and s is an integer greater than or equal to 1 and less than or equal to n.

A circuit included in the first driver circuit portion 431 functions as a scan line driver circuit (also referred to as a gate driver), for example. A circuit included in the second driver circuit portion 432 functions as a signal line driver circuit (also referred to as a source driver), for example. A given circuit can be provided to face the first driver circuit portion 431 with the display portion 435 placed therebetween. A given circuit can be provided to face the second driver circuit portion 432 with the display portion 435 placed therebetween. Note that the circuits included in the first driver circuit portion 431 and the second driver circuit portion 432 are collectively referred to as a peripheral driver circuit 433.

As the peripheral driver circuit 433, a variety of circuits such as a shift register circuit, a level shifter circuit, an inverter circuit, a latch circuit, an analog switch circuit, a multiplexer circuit, a demultiplexer circuit, and a logic circuit can be used. In the peripheral driver circuit 433, the transistor 100 and the like of one embodiment of the present invention can be used. Note that a transistor included in the peripheral driver circuit and a transistor included in the pixel 230 can be formed through the same process.

The display device 200 includes m wirings 436 which are arranged substantially parallel to each other and whose potentials are controlled by the circuit included in the first driver circuit portion 431, and n wirings 437 which are arranged substantially parallel to each other and whose potentials are controlled by the circuit included in the second driver circuit portion 432.

FIG. 15 illustrates an example in which the wiring 436 and the wiring 437 are connected to the pixel 230. Note that the wirings 436 and 437 are merely examples, and wirings connected to the pixel 230 are not limited to the wirings 436 and 437.

### Structure Example of Pixel Circuit

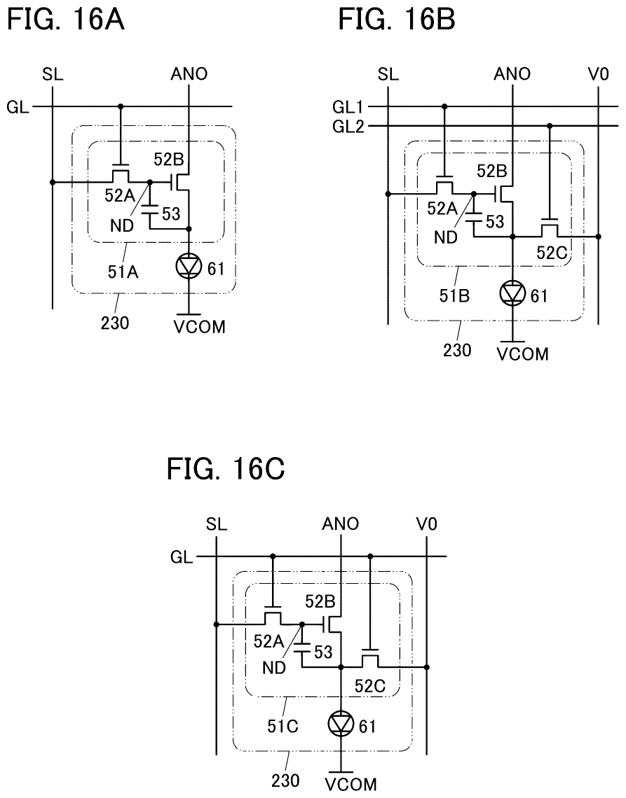

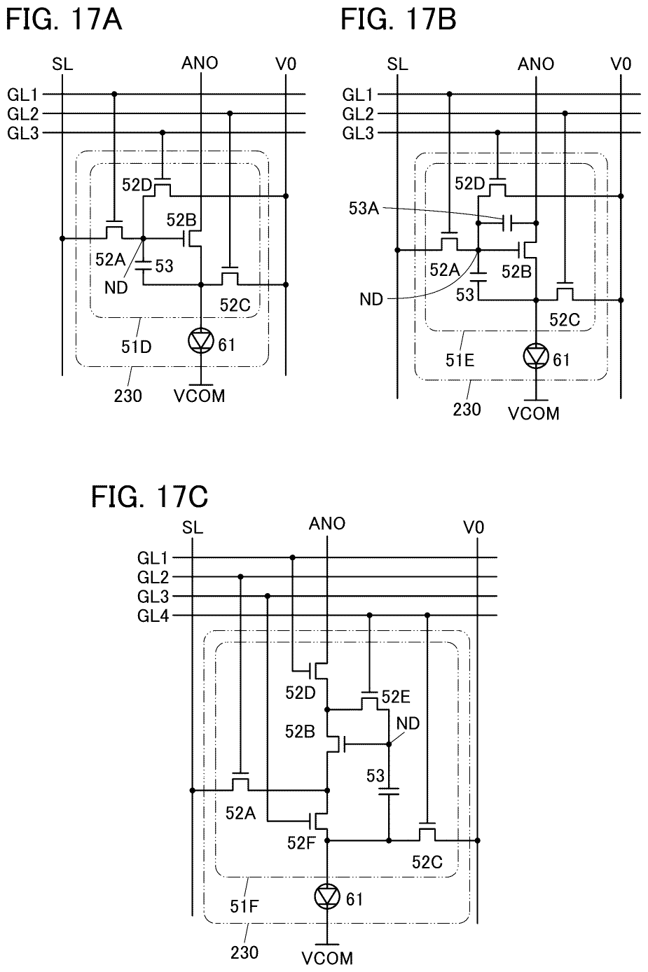

FIGS. 16A to 16C and FIGS. 17A to 17C illustrate structure examples of the pixel 230. The pixel 230 includes a pixel circuit 51 (a pixel circuit 51A, a pixel circuit 51B, a pixel circuit 51C, a pixel circuit 51D, a pixel circuit 51E, or a pixel circuit 51F) and a light-emitting element 61.

A light-emitting element described in this embodiment and the like is a self-luminous display element such as an organic light-emitting diode. Note that a light-emitting element connected to the pixel circuit can be a self-luminous light-emitting element such as an LED, a micro LED, a quantum-dot LED (QLED), or a semiconductor laser.

The pixel circuit 51A illustrated in FIG. 16A is a 2Tr1C pixel circuit including a transistor 52A, a transistor 52B, and a capacitor 53.

One of a source and a drain of the transistor 52A is connected to a wiring SL, and a gate of the transistor 52A is connected to a wiring GL. The other of the source and the drain of the transistor 52A is connected to a gate of the transistor 52B and one terminal of the capacitor 53. One of a source and a drain of the transistor 52B is connected to a wiring ANO. The other of the source and the drain of the transistor 52B is connected to the other terminal of the capacitor 53 and an anode of the light-emitting element 61. A cathode of the light-emitting element 61 is connected to a wiring VCOM. A region where the other of the source and the drain of the transistor 52A, the gate of the transistor 52B, and the one terminal of the capacitor 53 are connected serves as a node ND.

The wiring GL corresponds to the wiring 436, and the wiring SL corresponds to the wiring 437. The wiring VCOM supplies a potential for supplying a current to the light-emitting element 61. The transistor 52A has a function of controlling electrical continuity (a conduction state in which a current can flow and a non-conduction state in which a current cannot flow) between the wiring SL and the gate of the transistor 52B in accordance with the potential of the wiring GL. For example, VDD is supplied to the wiring ANO, and VSS is supplied to the wiring VCOM. The transistor 52A serves as a switch that is used to select and deselect the pixel 230 and thus can be referred to as a selection transistor.

When the transistor 52A is turned on, an image signal is supplied from the wiring SL to the node ND. Then, the transistor 52A is turned off, whereby the image signal is held at the node ND. In order to surely hold the image signal supplied to the node ND, a transistor with a low off-state current is preferably used as the transistor 52A. For example, an OS transistor is preferably used as the transistor 52A.

The transistor 52B has a function of controlling the amount of current flowing through the light-emitting element 61. Thus, the transistor 52B can be referred to as a driving transistor. The capacitor 53 has a function of holding a gate potential of the transistor 52B. The intensity of light emitted from the light-emitting element 61 is controlled in accordance with an image signal supplied to the gate of the transistor 52B (the node ND).

For example, the transistor 100, the transistor 100A, the transistor 100B, and the like described in Embodiment 1 can be used as some or all of the transistors included in the pixel circuit 51A.

The pixel circuit 51B illustrated in FIG. 16B is a 3Tr1C pixel circuit including the transistor 52A, the transistor 52B, a transistor 52C, and the capacitor 53. The pixel circuit 51B illustrated in FIG. 16B has a structure in which the transistor 52C is added to the pixel circuit 51A illustrated in FIG. 16A, and a wiring connected to the gate of the transistor 52A and a wiring connected to a gate of the transistor 52C are each independently provided.

The gate of the transistor 52A is connected to a wiring GL1, and the gate of the transistor 52C is connected to a wiring GL2. When the wiring connected to the gate of the transistor 52A and the wiring connected to the gate of the transistor 52C are provided separately, potentials with different levels can be applied to the gates of the two transistors, so that the two transistors can operate independently.

One of a source and a drain of the transistor 52C is connected to the other of the source and the drain of the transistor 52B. The other of the source and the drain of the transistor 52C is connected to a wiring V0. For example, a reference potential is supplied to the wiring V0.

The transistor 52C has a function of controlling electrical continuity between the other of the source or the drain of the transistor 52B and the wiring V0 in accordance with the potential of the wiring GL2. When an n-channel transistor is used as the transistor 52B, variations in the gate-source voltage of the transistor 52B can be reduced by the reference potential of the wiring V0 supplied through the transistor 52C.

A current value that can be used for setting pixel parameters can be obtained with the use of the wiring V0. Specifically, the wiring V0 can function as a monitor line for outputting a current flowing through the transistor 52B or a current flowing through the light-emitting element 61 to the outside. A current output to the wiring V0 is converted into a voltage by a source follower circuit or the like and can be output to the outside. Alternatively, the current is converted into a digital signal by an A/D converter or the like and can be output to the outside.

For example, the transistor 100, the transistor 100A, the transistor 100B, and the like described in Embodiment 1 can be used as some or all of the transistors included in the pixel circuit 51B.

The pixel circuit 51C illustrated in FIG. 16C has a structure in which the wiring connected to the gate of the transistor 52A and the wiring connected to the gate of the transistor 52C in the pixel circuit 51B illustrated in FIG. 16B correspond to one common wiring (the wiring GL). When the pixel circuit 51C has such a structure, the number of wirings can be smaller than the number of wirings in the pixel circuit 51B; thus, the number of power sources connected to the wirings can be reduced. Accordingly, the number of steps for manufacturing the display device and the size of the display device can be smaller in the display device including the pixel circuit 51C than in the display device including the pixel circuit 51B.

For example, the transistor 100, the transistor 100A, the transistor 100B, and the like described in Embodiment 1 can be used as some or all of the transistors included in the pixel circuit 51C.

The pixel circuit 51D illustrated in FIG. 17A has a configuration in which a transistor 52D is added to the pixel circuit 51B in FIG. 16B. The pixel circuit 51D illustrated in FIG. 17A is a 4Tr1C pixel circuit including the transistor 52A, the transistor 52B, the transistor 52C, the transistor 52D, and the capacitor 53.

One of a source and a drain of the transistor 52D is connected to the node ND, and the other of the source and the drain is connected to the wiring V0.

A wiring GL1, a wiring GL2, and a wiring GL3 are connected to the pixel circuit 51D. The wiring GL1 is connected to the gate of the transistor 52A, the wiring GL2 is connected to the gate of the transistor 52C, and the wiring GL3 is connected to a gate of the transistor 52D.

In this embodiment, the wirings GL1, GL2, and GL3 are collectively referred to as the wiring GL in some cases. Thus, the number of wirings GL is not limited to one as in the pixel circuit 51A, the pixel circuit 51C, or the like and may be plural as in the pixel circuit 51B, the pixel circuit 51D, or the like.

When the transistors 52C and 52D are turned on at the same time, the source and the gate of the transistor 52B have the same potential, so that the transistor 52B can be turned off. Thus, a current flowing to the light-emitting element 61 can be blocked forcibly. Such a pixel circuit is suitable for the case of using a display method in which a display period and an off period are alternately provided.

The pixel circuit 51E illustrated in FIG. 17B is an example in which a capacitor 53A is added to the pixel circuit 51D illustrated in FIG. 17A. The capacitor 53A functions as a storage capacitor. The pixel circuit 51D illustrated in FIG. 17A is a 4Tr1C pixel circuit. The pixel circuit 51E illustrated in FIG. 17B is a 4Tr2C pixel circuit.

The pixel circuit 51F illustrated in FIG. 17C is a 6Tr1C pixel circuit including the transistor 52A, the transistor 52B, the transistor 52C, the transistor 52D, a transistor 52E, a transistor 52F, and the capacitor 53.

One of the source and the drain of the transistor 52A is connected to the wiring SL, and the gate of the transistor 52A is connected to the wiring GL2. One of the source and the drain of the transistor 52D is connected to the wiring ANO, and the gate of the transistor 52D is connected to the wiring GL1. The other of the source and the drain of the transistor 52D is connected to one of the source and the drain of the transistor 52B. The other of the source and the drain of the transistor 52B is connected to the other of the source and the drain of the transistor 52A and one of a source and a drain of the transistor 52F. A gate of the transistor 52F is connected to the wiring GL3.

One of a source and a drain of the transistor 52E is connected to the other of the source and the drain of the transistor 52D and the one of the source and the drain of the transistor 52B. The other of the source and the drain of the transistor 52E is connected to the gate of the transistor 52B and one terminal of the capacitor 53. The other terminal of the capacitor 53 is connected to the other of the source and the drain of the transistor 52F, the anode of the light-emitting element 61, and one of the source and the drain of the transistor 52C. A gate of the transistor 52E and the gate of the transistor 52C are connected to a wiring GL4. The other of the source and the drain of the transistor 52C is connected to the wiring V0. A region where the other of the source and the drain of the transistor 52E, the gate of the transistor 52B, and the one terminal of the capacitor 53 are connected serves as the node ND.

For example, the transistor 100, the transistor 100A, the transistor 100B, and the like described in Embodiment 1 can be used as some or all of the transistors included in each of the pixel circuit 51D, the pixel circuit 51E, and the pixel circuit 51F.

For example, when a TGSA transistor (e.g., the transistor 100) is used as a driving transistor in a pixel circuit of a display device including a light-emitting element, the emission luminance of the light-emitting element can be stable owing to the high saturation of the TGSA transistor.

For example, when a vertical transistor (e.g., the transistor 100A or the transistor 100B) is used as a driving transistor in a pixel circuit of a display device including a light-emitting element, the emission luminance of the light-emitting element can be increased owing to the high on-state current of the vertical transistor.

For example, when a vertical transistor (e.g., the transistor 100A or the transistor 100B) is used in a pixel circuit of a display device, the area occupied by the pixel circuit can be reduced. Thus, the resolution of the display device can be increased. For example, it is possible to achieve a display device with a resolution higher than or equal to 1000 ppi and lower than or equal to 10000 ppi, preferably higher than or equal to 2000 ppi and lower than or equal to 9000 ppi, further preferably higher than or equal to 3000 ppi and lower than or equal to 8000 ppi, further preferably higher than or equal to 4000 ppi and lower than or equal to 8000 ppi, further preferably higher than or equal to 5000 ppi and lower than or equal to 8000 ppi, further preferably higher than or equal to 6000 ppi and lower than or equal to 8000 ppi.

The reduction in the area occupied by the pixel circuit can increase the number of pixels (definition) of the display device. For example, it is possible to achieve a display device with an extremely high definition of HD (number of pixels: 1280×720), FHD (number of pixels: 1920×1080), WQHD (number of pixels: 2560×1440), WQXGA (number of pixels: 2560×1600), 4K2K (number of pixels: 3840×2160), or 8K4K (number of pixels: 7680×4320).

For example, when a vertical transistor (e.g., the transistor 100A or the transistor 100B) is used in a peripheral driver circuit (e.g., a scan line driver circuit or a signal line driver circuit) of a display device, the display device can operate at high speed with a narrow bezel.

For example, when an OS transistor (e.g., the transistor 100, the transistor 100A, or the transistor 100B) is used in a pixel circuit and a peripheral driver circuit of a display device, the power consumption of the display device can be reduced owing to the low off-state current of the OS transistor.

The structures described in this embodiment can be used in combination with any of the structures described in the other embodiments as appropriate.

### Embodiment 3

The transistors (e.g., the transistors 100, 100A, and 100B) for which the metal oxide layer of one embodiment of the present invention is usable can be used in a variety of semiconductor devices other than the display device. In this embodiment, a semiconductor device 900 for which the transistor of one embodiment of the present invention can be used will be described. The semiconductor device 900 can function as a memory device.

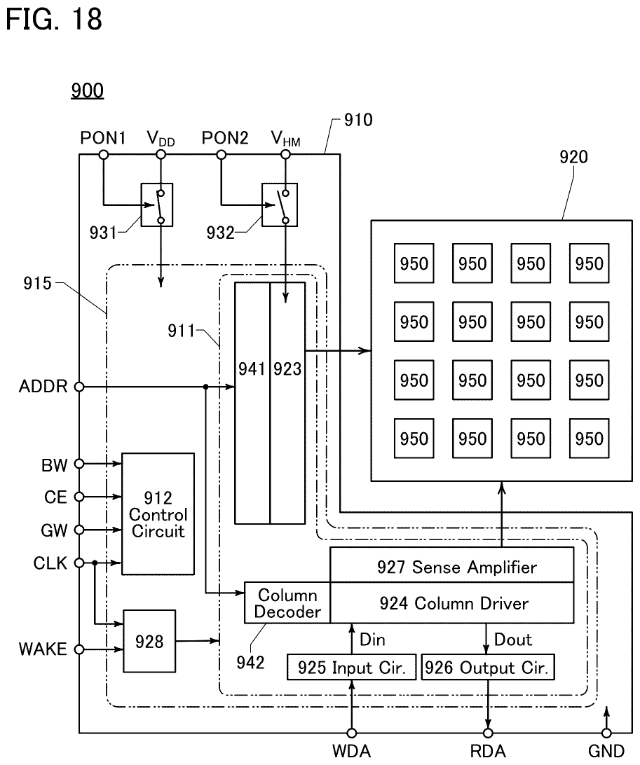

FIG. 18 is a block diagram illustrating a structure example of the semiconductor device 900. The semiconductor device 900 illustrated in FIG. 18 includes a driver circuit 910 and a memory array 920. The memory array 920 includes at least one memory cell 950. FIG. 18 illustrates an example in which the memory array 920 includes a plurality of memory cells 950 arranged in a matrix.

The transistor of one embodiment of the present invention (e.g., the transistor 100, 100A, or 100B) described in Embodiment 1 as an example can be used in the memory cell 950. With the use of the transistor that can include the metal oxide layer of one embodiment of the present invention, the operation speed of the memory device can be increased. This also enables further miniaturization and higher integration of the memory device. In addition, the capacity per area of the memory device can be increased.

The driver circuit 910 includes a power switch (PSW) 931, a PSW 932, and a peripheral circuit 915. The peripheral circuit 915 includes a peripheral circuit 911, a control circuit 912 (Control Circuit), and a voltage generator circuit 928.

In the semiconductor device 900, whether to provide or use each circuit, each signal, and each voltage can be selected as appropriate. Alternatively, another circuit or another signal can be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signals BW, CE, and GW are control signals. The signal CE is a chip enable signal, the signal GW is a global write enable signal, and the signal BW is a byte write enable signal. The signal ADDR is an address signal. The signal WDA is a write data signal, and the signal RDA is a read data signal. The signal PON1 and the signal PON2 are power gating control signals. Note that the signals PON1 and PON2 can be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used to set the word line to the H level and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 18 but can be more than one. In that case, a power switch is provided for each power domain.

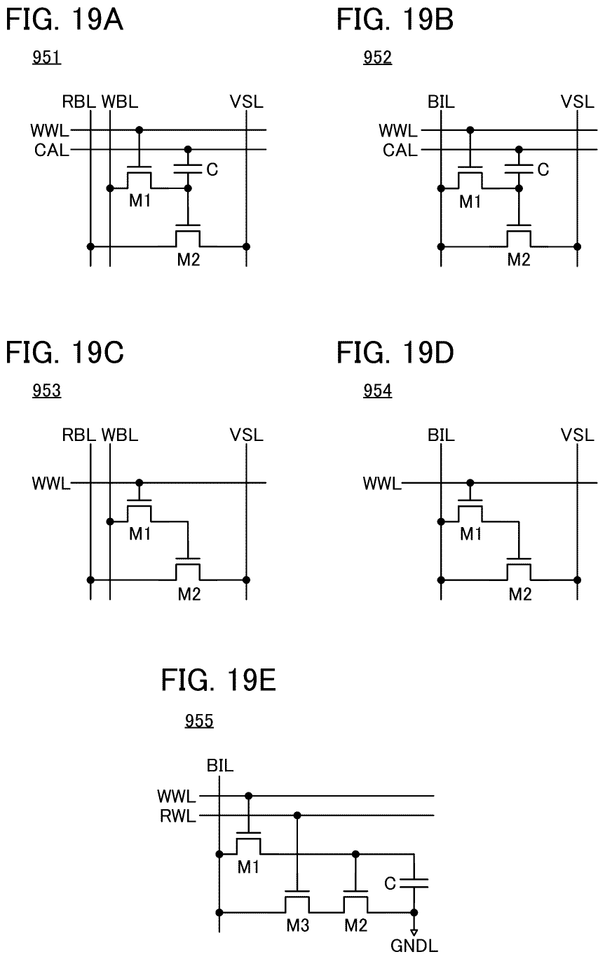

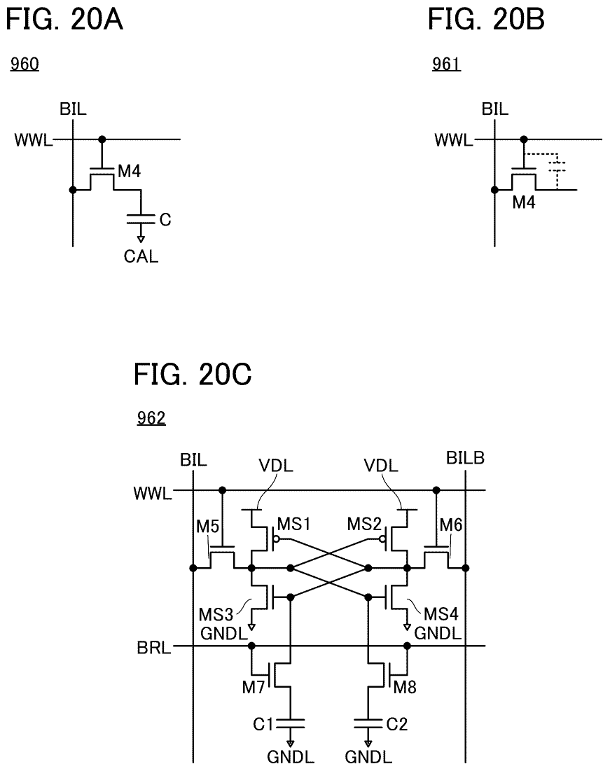

Structure examples of other memory cells each of which can be used as the memory cell 950 are described with reference to FIGS. 19A to 19E and FIGS. 20A to 20C.

### [NOSRAM]

FIG. 19A illustrates a circuit structure example of a gain memory cell including two transistors and one capacitor. A memory cell 951 includes a transistor M1, a transistor M2, and a capacitor C. The transistor M1 functions as a transistor for data writing. The transistor M2 functions as a transistor for data reading. The capacitor C functions as a storage capacitor of data. In this specification and the like, a memory device including a gain memory cell using an OS transistor as the transistor M1 is referred to as a nonvolatile oxide semiconductor random access memory (NOSRAM).

A first terminal (one of a source and a drain) of the transistor M1 is electrically connected to a first terminal (one electrode) of the capacitor C; a second terminal (the other of the source or the drain) of the transistor M1 is connected to the wiring WBL; and a gate of the transistor M1 is connected to the wiring WWL. A second terminal (the other electrode) of the capacitor C is connected to a wiring CAL. A first terminal (one of a source and a drain) of the transistor M2 is connected to a wiring RBL, a second terminal (the other of the source and the drain) of the transistor M2 is connected to a wiring VSL, and a gate of the transistor M2 is connected to a first terminal of the capacitor C.

The wiring WBL functions as a write bit line, the wiring RBL functions as a read bit line, and the wiring WWL functions as a word line. The wiring CAL functions as a wiring for applying a predetermined potential to the second terminal of the capacitor C. At the time of data writing, data retention, and data reading, a low-level potential (sometimes referred to as a reference potential) is preferably applied to the wiring CAL.

Data writing is performed by applying a high-level potential to the wiring WWL to turn on the transistor M1, thereby connecting the wiring WBL to the first terminal of the capacitor C. Specifically, when the transistor M1 is on, a potential corresponding to data to be stored is applied to the wiring WBL, and the potential is written to the first terminal of the capacitor C and the gate of the transistor M2. Then, a low-level potential is applied to the wiring WWL to turn off the transistor M1, whereby the potential of the first terminal of the capacitor C and the potential of the gate of the transistor M2 are retained.

Data reading is performed by applying a predetermined potential to the wiring VSL. A current flowing between the source and the drain of the transistor M2 and the potential of the first terminal of the transistor M2 are determined by the potential of the gate of the transistor M2 and the potential of the second terminal of the transistor M2. Accordingly, by reading a potential of the wiring RBL connected to the first terminal of the transistor M2, a potential retained at the first terminal of the capacitor C (or the gate of the transistor M2) can be read. That is, data written to the memory cell can be read on the basis of the potential retained at the first terminal of the capacitor C (or the gate of the transistor M2).

As another example, one wiring BIL can be provided instead of the wiring WBL and the wiring RBL. A circuit structure example of the memory cell is illustrated in FIG. 19B. In a memory cell 952, one wiring BIL is provided instead of the wiring WBL and the wiring RBL in the memory cell 951, and the second terminal of the transistor M1 and the first terminal of the transistor M2 are connected to the wiring BIL. In other words, one wiring BIL operates as the write bit line and the read bit line in the memory cell 952.

A memory cell 953 illustrated in FIG. 19C is an example in which the capacitor C and the wiring CAL in the memory cell 951 are omitted. A memory cell 954 illustrated in FIG. 19D is an example in which the capacitor C and the wiring CAL in the memory cell 952 are omitted. Such structures enable high integration of memory cells.

In the memory cells 951 to 954 illustrated in FIGS. 19A to 19D, respectively, the transistor 100, the transistor 100A, the transistor 100B, and the like described in Embodiment 1 can be used as one or both of the transistor M1 and the transistor M2.

Since the OS transistor has a characteristic of an extremely low off-state current, the transistor M1 enables written data to be retained for a long time, and thus the frequency of refresh operation for the memory cell can be decreased. Alternatively, refresh operation for the memory cell can be omitted. Therefore, the power consumption of the memory device can be reduced. In addition, owing to an extremely low leakage current, multilevel data or analog data can be retained in the memory cells 951, 952, 953, and 954.

As described in Embodiment 1, the transistor 100, the transistor 100A, the transistor 100B, and the like which can include the metal oxide layer of one embodiment of the present invention has high field-effect mobility and high on-state current. Accordingly, a memory device with a high operation speed (a data writing speed and a data reading speed) can be achieved.

The memory cells 951, 952, 953, and 954 each using the OS transistors as the transistors M1 and M2 are embodiments of NOSRAMs.

Note that the transistor M2 can be a Si transistor. The Si transistor can have a high field-effect mobility and can be formed as a p-channel transistor, so that circuit design flexibility can be increased.

When the OS transistor is used as the transistor M2, the memory cell can be configured with the transistors having the same conductivity type.

FIG. 19E illustrates a gain memory cell 955 including three transistors and one capacitor. The memory cell 955 includes the transistor M1, the transistor M2, the transistor M3, and the capacitor C. The transistor M3 functions as a transistor for data reading. That is, each of the memory cells 951 to 954 has a structure including only one transistor for data reading (the transistor M2), whereas the memory cell 955 has a structure including two transistors for data reading (the transistor M2 and the transistor M3).

The first terminal of the transistor M1 is connected to the first terminal of the capacitor C, the second terminal of the transistor M1 is connected to the wiring BIL, and the gate of the transistor M1 is connected to the wiring WWL. The second terminal of the capacitor C is connected to a first terminal of the transistor M2 and a wiring GNDL. A second terminal of the transistor M2 is connected to a first terminal (one of a source and a drain) of the transistor M3, and the gate of the transistor M2 is connected to the first terminal of the capacitor C. A second terminal (the other of the source and the drain) of the transistor M3 is connected to the wiring BIL, and a gate of the transistor M3 is connected to a wiring RWL.

The wiring BIL functions as a bit line. The wiring WWL functions as a write word line. The wiring RWL functions as a read word line. The wiring GNDL is a wiring for supplying a low-level potential.

Data writing is performed by applying a high-level potential to the wiring WWL to turn on the transistor M1, thereby connecting the wiring BIL to the first terminal of the capacitor C. Specifically, when the transistor M1 is on, a potential corresponding to data to be stored is applied to the wiring BIL, and the potential is written to the first terminal of the capacitor C and the gate of the transistor M2. Then, a low-level potential is applied to the wiring WWL to turn off the transistor M1, whereby the potential of the first terminal of the capacitor C and the potential of the gate of the transistor M2 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M3 is turned on, so that the wiring BIL is connected to the second terminal of the transistor M2. At this time, the potential of the wiring BIL is applied to the second terminal of the transistor M2; the potential of the second terminal of the transistor M2 and the potential of the wiring BIL change depending on the potential retained at the first terminal of the capacitor C (or the gate of the transistor M2). Here, the potential retained at the first terminal of the capacitor C (or the gate of the transistor M2) can be read by reading the potential of the wiring BIL. That is, data written to the memory cell can be read on the basis of the potential retained at the first terminal of the capacitor C (or the gate of the transistor M2).

In the memory cell 955 illustrated in FIG. 19E, the transistor 100, the transistor 100A, the transistor 100B, and the like described in Embodiment 1 can be used as one or both of the transistor M1 and the transistor M2.

An OS transistor is preferably used also as the transistor M3. For example, an OS transistor formed using the same material as the transistor M1 can be used as the transistor M3. Alternatively, an OS formed using the same material as the transistor M2 can be used. Alternatively, an OS transistor formed using a material different from those of the transistor M1 and the transistor M2 can be used.

In particular, an OS transistor formed using the same material as the transistor M1 is preferably used as the transistor M3. Thus, the transistor M3 can have normally-off characteristics. The transistor M3 in a memory cell that is not subjected to data reading (i.e., a memory cell in which a high-level potential is not applied to the wiring RWL) can be prevented from being turned on, and thus a malfunction such as incorrect data reading can be inhibited from occurring.

Note that Si transistors can also be used as the transistors M2 and M3. As described above, a Si transistor may have higher field-effect mobility than the OS transistor depending on the crystal state of silicon used in a semiconductor layer, for example. Therefore, the reading speed of the memory device can be sometimes higher than that in the case where OS transistors are used as the transistors M2 and M3. Note that an OS transistor can be used as one of the transistors M2 and M3, and a Si transistor can be used as the other.

When OS transistors are used as the transistors M2 and M3, the memory cell can be configured with the transistors having the same conductivity type.

### [DOSRAM]

FIG. 20A illustrates a circuit structure example of a memory cell for a dynamic random access memory (DRAM). In this specification and the like, a DRAM using an OS transistor is referred to as a dynamic oxide semiconductor random access memory (DOSRAM). A memory cell 960 includes a transistor M4 and the capacitor C.

Note that the transistor M4 can include a front gate (simply referred to as a gate in some cases) and a back gate. In that case, the back gate can be connected to a wiring to which a constant potential or a signal is supplied, or the front gate and the back gate can be connected to each other.

A first terminal (one of a source and a drain) of the transistor M4 is electrically connected to a first terminal (one electrode) of the capacitor C; a second terminal (the other of the source or the drain) of the transistor M4 is connected to the wiring BIL; and a gate of the transistor M4 is connected to the wiring WWL. A second terminal (the other electrode) of the capacitor C is connected to a wiring CAL.

The wiring BIL functions as a bit line and the wiring WWL functions as a word line. The wiring CAL functions as a wiring for applying a predetermined potential to the second terminal of the capacitor C. At the time of data writing and data reading, a low-level potential (sometimes referred to as a reference potential) is preferably applied to the wiring CAL.

Data writing and data reading are performed by applying a high-level potential to the wiring WWL to turn on the transistor M4, thereby connecting the wiring BIL to the first terminal of the capacitor C.

The memory cell that can be used as the memory cell 950 is not limited to the memory cell 960, and the circuit structure can be changed. For example, a structure of a memory cell 961 illustrated in FIG. 20B can be employed. The memory cell 961 is an example including neither the capacitor C nor the wiring CAL. The first terminal of the transistor M4 is in an electrically floating state.

In the memory cell 961, a potential written through the transistor M4 is retained in a capacitor (also referred to as parasitic capacitance) between the first terminal and the gate, which is shown by a dashed line. With such a structure, the structure of the memory cell can be greatly simplified.

Note that the OS transistor described in Embodiment 1 (e.g., the transistor 100, the transistor 100A, or the transistor 100B) is preferably used as the transistor M4. With the use of the OS transistor, the operating speed of the memory device can be increased. It also enables a reduction in the area occupied by the memory cell. An OS transistor has a characteristic of an extremely low off-state current. When an OS transistor is used as the transistor M4, the leakage current of the transistor M4 can be extremely low. That is, with the use of the transistor M4, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 960 and 961.

In the memory cell 960 illustrated in FIG. 20A and the memory cell 961 illustrated in FIG. 20B, the transistor 100, the transistor 100A, the transistor 100B, or the like described in Embodiment 1 can be used as the transistor M4.

### [OS-SRAM]

FIG. 20C illustrates an example of a static random access memory (SRAM) using an OS transistor. In this specification and the like, an SRAM using an OS transistor is referred to as an oxide semiconductor SRAM (OS-SRAM). A memory cell 962 illustrated in FIG. 20C is a memory cell of an SRAM capable of backup operation.

The memory cell 962 includes transistors M5 to M8, transistors MS1 to MS4, a capacitor C1, and a capacitor C2. The transistors MS1 and MS2 are p-channel transistors, and the transistors MS3 and MS4 are n-channel transistors.

A first terminal (one of a source and a drain) of the transistor M5 is connected to the wiring BIL, and a second terminal (the other of the source and the drain) of the transistor M5 is connected to a first terminal (one of a source and a drain) of the transistor MS1, a first terminal (one of a source and a drain) of the transistor MS3, a gate of the transistor MS2, a gate of the transistor MS4, and a first terminal (one of a source and a drain) of the transistor M8. A gate of the transistor M5 is connected to the wiring WWL. A first terminal (one of a source and a drain) of the transistor M6 is connected to a wiring BILB, and a second terminal (the other of the source and the drain) of the transistor M6 is connected to a first terminal (one of a source and a drain) of the transistor MS2, a first terminal (one of a source and a drain) of the transistor MS4, a gate of the transistor MS1, a gate of the transistor MS3, and a first terminal (one of a source and a drain) of the transistor M7. A gate of the transistor M6 is connected to the wiring WWL.

A second terminal of the transistor MS1 (the other of the source and the drain) is connected to the wiring VDL. A second terminal (the other of the source and the drain) of the transistor MS2 is connected to the wiring VDL. A second terminal (the other of the source and the drain) of the transistor MS3 is connected to the wiring GNDL. A second terminal (the other of the source and the drain) of the transistor MS4 is connected to the wiring GNDL.

A second terminal (the other of the source and the drain) of the transistor M7 is connected to a first terminal (one electrode) of the capacitor C1, and a gate of the transistor M7 is connected to a wiring BRL. A second terminal (the other of the source and the drain) of the transistor M8 is connected to a first terminal (one electrode) of the capacitor C2, and a gate of the transistor M8 is connected to the wiring BRL.

A second terminal (the other electrode) of the capacitor C1 is connected to the wiring GNDL, and a second terminal (the other electrode) of the capacitor C2 is connected to a wiring GNDL.

The wiring BIL and the wiring BILB function as bit lines. The wiring WWL functions as a word line. The wiring BRL controls the on/off states of the transistors M7 and M8.

The wiring VDL supplies a high-level potential. The wiring GNDL supplies a low-level potential.

Data writing is performed by applying a high-level potential to the wiring WWL and the wiring BRL. Specifically, when the transistor M8 is on, a potential corresponding to data to be stored is applied to the wiring BIL, and the potential is written to the second terminal side of the transistor M8.

In the memory cell 962, the transistors MS1 and MS4 form an inverter loop; hence, an inversion signal of a data signal corresponding to the potential is input to the second terminal side of the transistor M6. Since the transistor M6 is on, an inversion signal of the potential applied to the wiring BIL (i.e., the signal input to the wiring BIL) is output to the wiring BILB. Since the transistor M7 and the transistor M8 are on, the potential of the second terminal of the transistor M5 is retained at the first terminal of the capacitor C2, and the potential of the second terminal of the transistor M6 is retained at the first terminal of the capacitor C1. After that, a low-level potential is applied to the wiring WWL and the wiring BRL to turn off the transistors M5 to M8, whereby the potential of the first terminal of the capacitor C1 and the potential of the first terminal of the capacitor C2 are retained.

Data reading is performed by precharging the wiring BIL and the wiring BILB with a predetermined potential, and then applying a high-level potential to the wiring WWL and the wiring BRL, whereby the potential of the first terminal of the capacitor C1 is refreshed by the inverter loop in the memory cell 962 and output to the wiring BILB. Furthermore, the potential of the first terminal of the capacitor C2 is refreshed by the inverter loop in the memory cell 962 and output to the wiring BIL. Since the potentials of the wiring BIL and the wiring BILB are changed from the precharged potentials to the potentials of the first terminal of the capacitor C2 and the first terminal of the capacitor C1, the potential retained in the memory cell can be read on the basis of the potentials of the wiring BIL and the wiring BILB.

Note that the transistors M5 to M8 are preferably OS transistors. In that case, with the use of the transistors M5 to M8, written data can be retained for a long time, and thus the frequency of refresh operation for the memory cell can be decreased. Alternatively, refresh operation for the memory cell can be omitted. When the OS transistor described in Embodiment 1 (e.g., the transistor 100, the transistor 100A, or the transistor 100B) is used as each of the transistors M5 to M8, the operation speed of the memory device can be improved. It also enables a reduction in the area occupied by the memory cell.

Note that the transistors MS1 to MS4 can be Si transistors.

The transistor 100, the transistor 100A, the transistor 100B, and the like described in Embodiment 1 can be used as some or all of the transistors M5 to M8, MS3, and MS4 in the memory cell 962 illustrated in FIG. 20C.

Accordingly, when the transistor of one embodiment of the present invention is used in the memory cell 962, the memory cell 962 can have excellent retention characteristics and high operation speed, i.e., the memory cell 962 can have extremely high performance.

At least part of this embodiment can be implemented as appropriate in combination with any of the other embodiments described in this specification.

### Embodiment 4

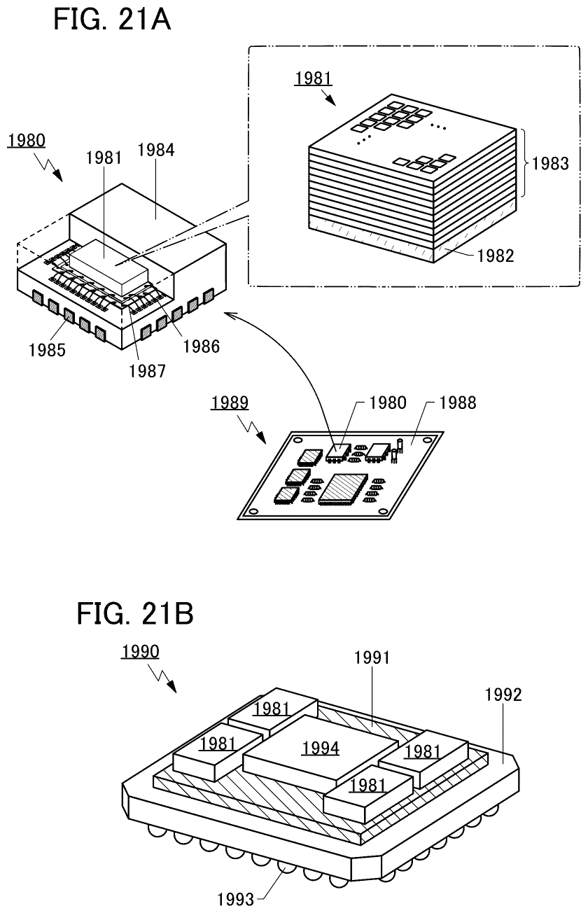

In this embodiment, application examples of the semiconductor device of one embodiment of the present invention will be described with reference to FIG. 21A to FIG. 25F.

The semiconductor device of one embodiment of the present invention can be used for an electronic component, a large computer, space equipment, a data center (also referred to as DC), and a variety of electronic devices, for example. With the use of the semiconductor device of one embodiment of the present invention, an electronic component, a large computer, space equipment, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop computers, a monitor of a computer and the like, digital signage, and a large game machine such as a pachinko machine.

In particular, the display device of one embodiment of the present invention can have a high resolution, and thus can be suitably used for an electronic device having a relatively small display portion. Examples of such an electronic device include watch-type and bracelet-type information terminal devices (wearable devices) and wearable devices that can be worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, higher than or equal to 300 ppi, higher than or equal to 500 ppi, higher than or equal to 1000 ppi, higher than or equal to 2000 ppi, higher than or equal to 3000 ppi, higher than or equal to 5000 ppi, or higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, a current, a voltage, electric power, radiation, a flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 21A is a perspective view of a substrate (a circuit board 1989) provided with an electronic component 1980. The electronic component 1980 illustrated in FIG. 21A includes a semiconductor device 1981 in a mold 1984. FIG. 21A omits some components to show the inside of the electronic component 1980. The electronic component 1980 includes a land 1985 outside the mold 1984. The land 1985 is connected to an electrode pad 1986, and the electrode pad 1986 is connected to the semiconductor device 1981 through a wire 1987. The electronic component 1980 is mounted on a printed circuit board 1988, for example. A plurality of such electronic components are combined and connected to each other on the printed circuit board 1988, which forms the circuit board 1989.

The semiconductor device 1981 includes a driver circuit layer 1982 and a memory layer 1983. The memory layer 1983 has a structure in which a plurality of memory cell arrays are stacked. A stacked-layer structure of the driver circuit layer 1982 and the memory layer 1983 can be a monolithic stacked-layer structure. In the monolithic stacked-layer structure, layers can be connected to each other without using a through electrode technique such as a through silicon via (TSV) technique and a bonding technique such as Cu—Cu direct bonding. Monolithically stacking the driver circuit layer 1982 and the memory layer 1983 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 1983 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. In the case where the memory layer 1983 is formed with Si transistors, the monolithic stacked-layer structure is difficult to form as compared with the case where the memory layer 1983 is formed with OS transistors. Thus, an OS transistor is superior to a Si transistor in the monolithic stacked-layer structure.

The semiconductor device 1981 may be called a die. In this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 21B is a perspective view of an electronic component 1990. The electronic component 1990 is an example of a system in package (SiP) or a multi-chip module (MCM). In the electronic component 1990, an interposer 1991 is provided over a package substrate 1992 (printed circuit board), and a semiconductor device 1994 and a plurality of semiconductor devices 1981 are provided over the interposer 1991.

The electronic component 1990 using the semiconductor device 1981 as a high bandwidth memory (HBM) is illustrated as an example. The semiconductor device 1994 can be used for an integrated circuit such as a central processing unit (CPU), a graphics processing unit (GPU), or a field programmable gate array (FPGA).

As the package substrate 1992, a ceramic substrate, a plastic substrate, or a glass epoxy substrate can be used, for example. As the interposer 1991, a silicon interposer or a resin interposer can be used, for example.

The interposer 1991 includes a plurality of wirings and has a function of connecting a plurality of integrated circuits with different terminal pitches. The plurality of wirings are provided in a single layer or multiple layers. In addition, the interposer 1991 has a function of connecting an integrated circuit provided on the interposer 1991 to an electrode provided on the package substrate 1992. Accordingly, the interposer is referred to as a “redistribution substrate” or an “intermediate substrate” in some cases. Furthermore, a through electrode is provided in the interposer 1991 and the through electrode is used to connect an integrated circuit and the package substrate 1992 in some cases. Moreover, in the case of using a silicon interposer, a TSV can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is unlikely to occur. Furthermore, a surface of a silicon interposer has high flatness; thus, poor connection between the silicon interposer and an integrated circuit provided on the silicon interposer is unlikely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width of the terminal pitch and the like is needed. Accordingly, in the case where the size of the electronic component 1990 is to be reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

A heat sink (a radiator plate) may be provided to overlap with the electronic component 1990. In the case of providing a heat sink, the heights of integrated circuits provided on the interposer 1991 are preferably equal to each other. For example, in the electronic component 1990 described in this embodiment, the heights of the semiconductor devices 1981 and the semiconductor device 1994 are preferably equal to each other.

To mount the electronic component 1990 on another substrate, an electrode 1993 may be provided on a bottom portion of the package substrate 1992. FIG. 21B illustrates an example in which the electrode 1993 is formed of a solder ball. Solder balls are provided in a matrix on the bottom portion of the package substrate 1992, so that ball grid array (BGA) mounting can be achieved. Alternatively, the electrode 1993 may be formed of a conductive pin. When conductive pins are provided in a matrix on the bottom portion of the package substrate 1992, pin grid array (PGA) mounting can be achieved.

The electronic component 1990 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

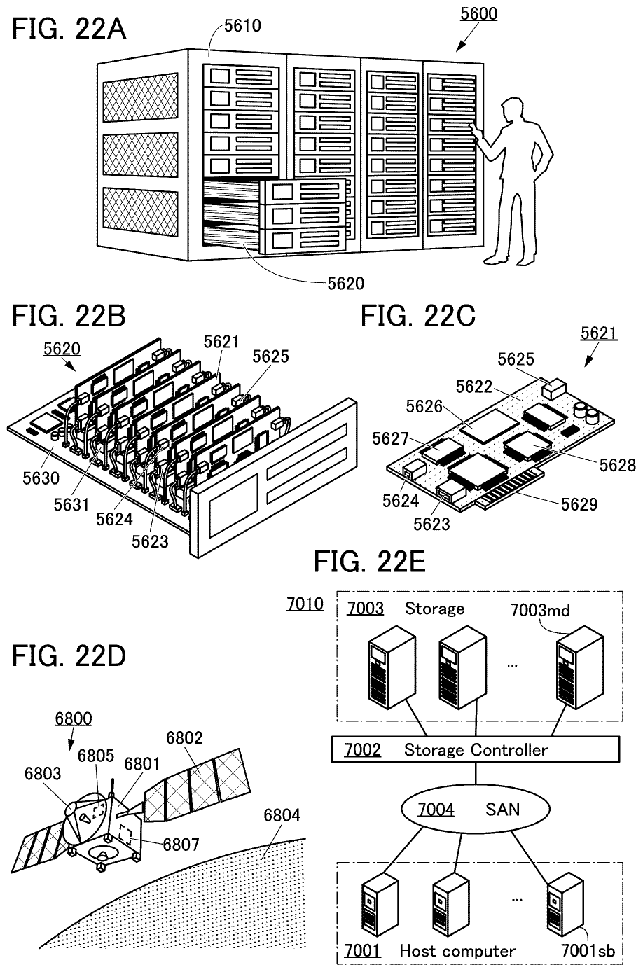

FIG. 22A is a perspective view of a large computer 5600. In the large computer 5600 illustrated in FIG. 22A, a plurality of rack mount computers 5620 are stored in a rack 5610. Note that the large computer 5600 may be referred to as a supercomputer.

The computer 5620 can have a structure illustrated in a perspective view of FIG. 22B, for example. In FIG. 22B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 22C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 22C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can each serve as, for example, an interface for performing power supply, signal input, or the like to the PC card 5621. For another example, they can each serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is IDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 1990 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 1990 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment.

The semiconductor device of one embodiment of the present invention includes an OS transistor. A change in electrical characteristics due to radiation irradiation is smaller in an OS transistor than in a Si transistor. That is, the OS transistor is highly resistant to radiation, and thus has high reliability and can be suitably used in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of thermosphere, mesosphere, and stratosphere.

FIG. 22D illustrates an artificial satellite 6800 as an example of space equipment. The artificial satellite 6800 includes a body 6801, a solar panel 6802, an antenna 6803, a secondary battery 6805, and a control device 6807. In FIG. 22D, a planet 6804 in outer space is illustrated as an example.

Although not illustrated in FIG. 22D, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention can be suitably used for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention can be suitably used for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high temperature environment. Thus, the reliability of the data center can be increased.

FIG. 22E illustrates a storage system that can be used in a data center. A storage system 7010 illustrated in FIG. 22E includes a plurality of servers 7001sb as a host 7001 (indicated by “Host computer” in the drawing). The storage system 7010 includes a plurality of memory devices 7003md as a storage 7003 (indicated by “Storage” in the drawing). In the illustrated example, the host 7001 and the storage 7003 are connected to each other through a storage area network 7004 (SAN: Storage Area Network in the drawing) and a storage control circuit 7002 (indicated by “Storage Controller” in the drawing).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

### [Electronic Device]

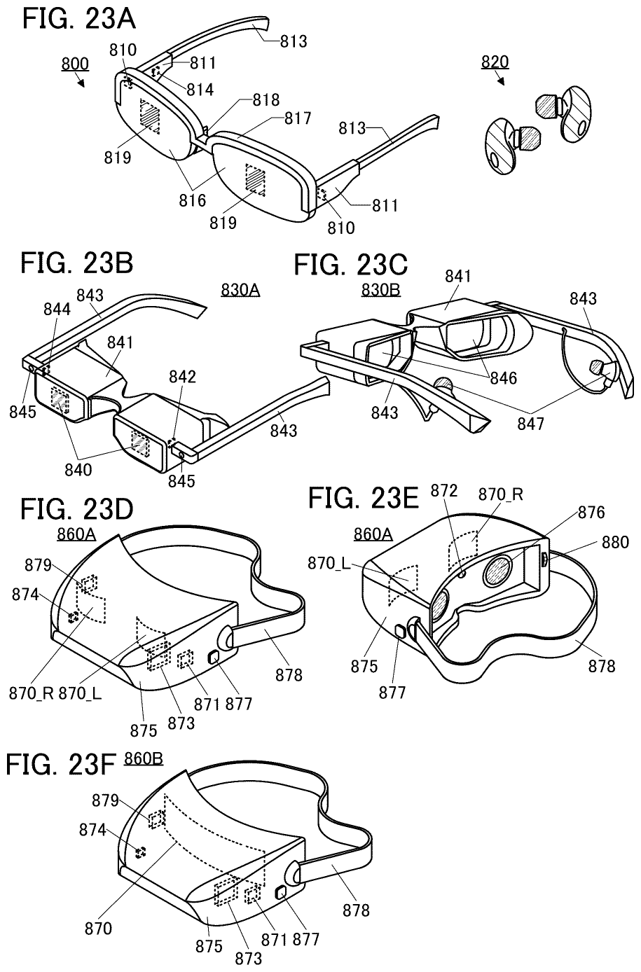

Examples of wearable devices that can be worn on a head will be described with reference to FIGS. 23A to 23F. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 800 illustrated in FIG. 23A includes a pair of display panels 810, a pair of housings 811, a communication portion (not illustrated), a pair of wearing portions 813, a control portion 814, an image capturing portion (not illustrated), a pair of optical members 816, a frame 817, and a pair of nose pads 818.

The display device of one embodiment of the present invention can be used for the display panels 810. Thus, the electronic device is capable of performing ultrahigh-resolution display. The semiconductor device of one embodiment of the present invention can be used for the control portion 814. In that case, the power consumption of the electronic device can be reduced.

The electronic device 800 can project images displayed on the display panels 810 onto display regions 819 of the optical members 816. Since the optical members 816 have a light-transmitting property, the user can see images displayed on the display regions, which are superimposed on transmission images seen through the optical members 816. Accordingly, the electronic device 800 is capable of AR display.

In the electronic device 800, a camera capable of capturing images of the front side may be provided as the image capturing portion. When the electronic device 800 is provided with an acceleration sensor such as a gyroscope sensor, the orientation of the user's head can be sensed and an image corresponding to the orientation can be displayed on the display regions 819.

The communication portion includes a wireless communication device, and a video signal and the like can be supplied by the wireless communication device. Instead of or in addition to the wireless communication device, a connector that can be connected to a cable for supplying a video signal and a power supply voltage may be provided.

The electronic device 800 is provided with a battery so that charging can be performed wirelessly and/or by wire.

A touch sensor module may be provided in the housing 811. The touch sensor module has a function of detecting a touch on the outer surface of the housing 811. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 811, the range of the operation can be increased.

An electronic device 830A illustrated in FIG. 23B and an electronic device 830B illustrated in FIG. 23C each include a pair of display portions 840, a housing 841, a communication portion 842, a pair of wearing portions 843, a control portion 844, a pair of image capturing portions 845, and a pair of lenses 846.

The display device of one embodiment of the present invention can be used for the display portions 840. Thus, the electronic devices can perform ultrahigh-resolution display. Such electronic devices provide a high level of immersion to the user. The semiconductor device of one embodiment of the present invention can be used for the control portion 844. In that case, the power consumption of the electronic devices can be reduced.

The display portions 840 are positioned inside the housing 841 so as to be seen through the lenses 846. When the pair of display portions 840 display different images, three-dimensional display using parallax can be performed.

The electronic devices 830A and 830B can be regarded as electronic devices for VR. The user wearing the electronic device 830A or the electronic device 830B can see images displayed on the display portions 840 through the lenses 846.

The electronic devices 830A and 830B preferably include a mechanism for adjusting the lateral positions of the lenses 846 and the display portions 840 so that the lenses 846 and the display portions 840 are positioned optimally in accordance with the positions of the user's eyes. Moreover, the electronic devices 830A and 830B preferably include a mechanism for adjusting focus by changing the distance between the lenses 846 and the display portions 840.

The electronic device 830A or the electronic device 830B can be mounted on the user's head with the wearing portions 843. FIG. 23B and the like illustrate examples in which the wearing portion 843 has a shape like a temple of glasses; however, one embodiment of the present invention is not limited thereto. The wearing portion 843 may have any shape with which the user can wear the electronic device, such as a shape of a helmet or a band.

The image capturing portion 845 has a function of obtaining information on the external environment. Data obtained by the image capturing portion 845 can be output to the display portion 840. An image sensor can be used for the image capturing portion 845. Moreover, a plurality of cameras may be provided so as to cover a plurality of fields of view, such as a telescope field of view and a wide field of view.

Although an example in which the image capturing portions 845 are provided is illustrated here, a range sensor (hereinafter, also referred to as a sensing portion) capable of measuring a distance between the user and an object just needs to be provided. That is, the image capturing portion 845 is one embodiment of the sensing portion. As the sensing portion, an image sensor or a range image sensor such as a light detection and ranging (LiDAR) sensor can be used, for example. By using images obtained by the camera and images obtained by the range image sensor, more pieces of information can be obtained and a gesture operation with higher accuracy is possible.

The electronic device 830A may include a vibration mechanism that functions as bone-conduction earphones. For example, at least one of the display portion 840, the housing 841, and the wearing portion 843 can include the vibration mechanism. Thus, without additionally requiring an audio device such as headphones, earphones, or a speaker, the user can enjoy videos and sound only by wearing the electronic device 830A.

The electronic devices 830A and 830B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 820. The earphones 820 include a communication portion (not illustrated) and have a wireless communication function. The earphones 820 can receive information (e.g., audio data) from the electronic device with the wireless communication function. For example, the electronic device 800 in FIG. 23A has a function of transmitting information to the earphones 820 with the wireless communication function.

The electronic device may include earphone portions. The electronic device 830B in FIG. 23C includes earphone portions 847. For example, the earphone portion 847 can be connected to the control portion 844 by wire. Part of a wiring that connects the earphone portion 847 and the control portion 844 may be positioned inside the housing 841 or the wearing portion 843. Alternatively, the earphone portions 847 and the wearing portions 843 may include magnets. This is preferable because the earphone portions 847 can be fixed to the wearing portions 843 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 23D and 23E are perspective views of a goggles-type electronic device 860A for VR. FIGS. 23D and 23E illustrate an example in which a housing 875 includes a pair of curved display devices 870 (a display device 870_R and a display device 870_L). The electronic device 860A includes a motion detection portion 871, an eye-gaze detection portion 872, an arithmetic portion 873, a communication portion 874, lenses 876, an operation button 877, a wearing tool 878, a sensor 879, a dial 880, and the like.

When the two display devices 870 are provided, the user's eyes can see the respective display devices. This allows a high-definition video to be displayed even when three-dimensional display using parallax or the like is performed. In addition, the display device 870 is curved around an arc with an approximate center at the user's eye. This keeps a certain distance between the user's eye and the display surface of the display device 870, enabling the user to see a more natural video. Even when having what is called viewing angle dependence where the luminance or chromaticity of light changes depending on a viewing angle, the display device 870 can have a structure in which the user's eye is positioned in the normal direction of the display surface of the display device 870; accordingly, the influence of the viewing angle dependence particularly in the horizontal direction can be practically ignored, enabling display of a more realistic video.

As illustrated in FIG. 23E, the lenses 876 are positioned between the display devices 870 and the user's eyes. FIG. 23E illustrates an example in which the dial 880 for changing the positions of the lenses for visibility adjustment is provided. In the case where the electronic device 860A has an autofocus function, the dial 880 for visibility adjustment is not necessarily provided.

FIG. 23F illustrates a goggles-type electronic device 860B including one display device 870. Such a structure can reduce the number of components.

The display device 870 can display an image for the right eye and an image for the left eye side by side on a right region and a left region, respectively. Thus, a three-dimensional video using binocular parallax can be displayed. Note that the display device 870 may display two different images side by side using parallax, or may display two same images side by side without using parallax.

One image which can be seen with both eyes may be displayed on the entire display device 870. Thus, a panorama video can be displayed from end to end of the field of view, which can provide a higher sense of reality.

The display device of one embodiment of the present invention can be used as the display device 870. Since the display device of one embodiment of the present invention has an extremely high resolution, even when an image is magnified using the lenses 876, the pixels are not perceived by the user and thus a more realistic video can be displayed.

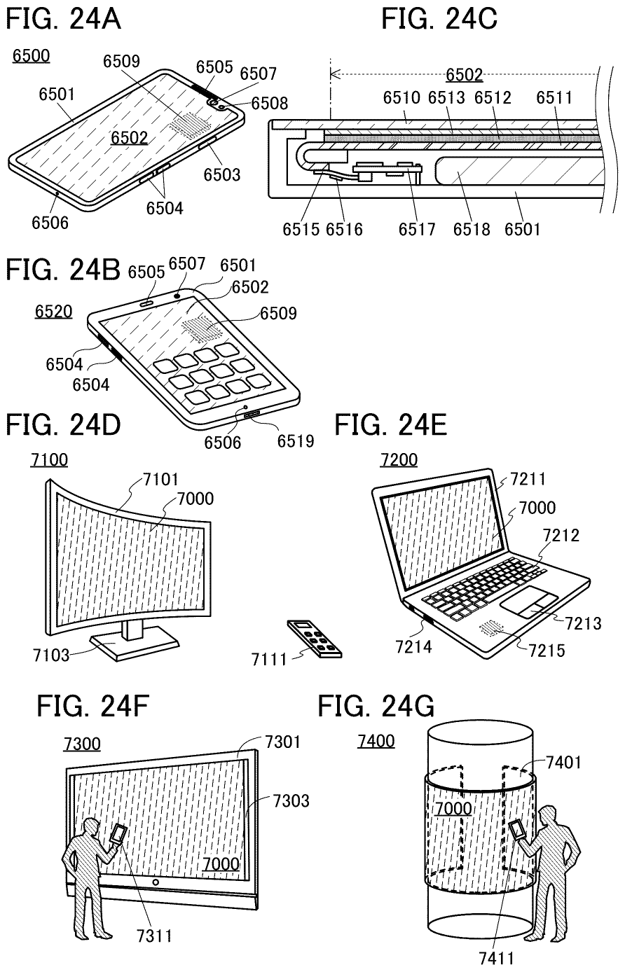

An electronic device 6500 in FIG. 24A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 24B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. The control device 6509 includes, for example, one or more selected from a CPU, a GPU, and a memory device. The semiconductor device of one embodiment of the present invention can be used for one or both of the display portion 6502 and the control device 6509.

FIG. 24C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. An electronic device with a narrow bezel can be obtained when part of the display panel 6511 is folded back such that the portion connected to the FPC 6515 is provided on the back side of a pixel portion.

FIG. 24D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

The television device 7100 illustrated in FIG. 24D can be operated with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 24E illustrates an example of a laptop computer. A laptop computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 24F and 24G illustrate examples of digital signage.

Digital signage 7300 illustrated in FIG. 24F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 24G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 24F and 24G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 24F and 24G, it is preferable that the digital signage 7300 or the digital signage 7400 be capable of working with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

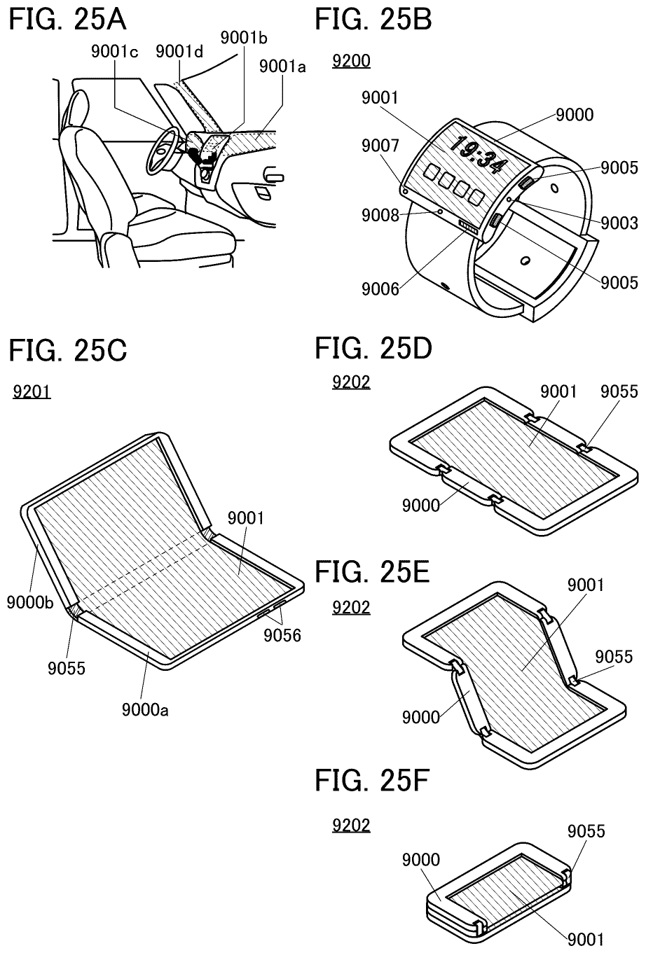

FIG. 25A illustrates the vicinity of a windshield inside a car. FIG. 25A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panels, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying a video taken by an imaging unit provided for the car body. That is, displaying an image taken by the imaging unit provided on the outside of the car body leads to elimination of blind areas and enhancement of safety. Moreover, displaying a video to compensate for the area that a driver cannot see makes it possible for the driver to confirm safety more easily and comfortably. The display panel 9001d can also be used as a lighting device.

FIG. 25B is a perspective view of a watch-type portable information terminal 9200. The portable information terminal 9200 can be used as a Smartwatch (registered trademark), for example. The display surface of a display portion 9001 is curved, and display can be performed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 25B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, a current, a voltage, electric power, radiation, a flow rate, humidity, gradient, oscillation, a smell, or infrared rays), a microphone 9008, and the like.

FIG. 25C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housings 9000a and 9000b) joined together with the hinge 9055.

FIGS. 25D to 25F are perspective views illustrating a foldable portable information terminal 9202. FIG. 25D is a perspective view of an opened state of the portable information terminal 9202, FIG. 25F is a perspective view of a folded state thereof, and FIG. 25E is a perspective view of a state in the middle of change from one of FIG. 25D and FIG. 25F to the other. In this manner, the portable information terminal 9202 can be folded in three.

The display portion 9001 of the portable information terminal 9202 is supported by three housings 9000 joined together with the hinges 9055.

In FIGS. 25C to 25F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate. In this specification, in the case where a plurality of structure examples are shown in one embodiment, the structure examples can be combined as appropriate.

### Example

In this example, in a method for forming an indium oxide having crystallinity (FIGS. 1A to 1C and FIGS. 2A1 to 2B2), which is the metal oxide layer of one embodiment of the present invention, steps illustrated in FIGS. 1A to 1C (i.e., from the formation of the first crystallized film 108p1 to the first wet etching on the film) were conducted, and the surfaces of the samples after the steps were observed.

### <Formation of Samples>

In this example, four samples (Samples A to D) subjected to the first wet etching under different conditions were formed.

First, the first amorphous film 108a1 with a thickness of 50 nm was formed over a quartz substrate prepared as the substrate 101 by a sputtering method (corresponding to FIG. 1A). The film formation was performed using an In₂O₃ target at room temperature in an atmosphere containing 1% of an O₂ gas and 5% of an H₂ gas. The first amorphous film 108a1 is an amorphous indium oxide film.

Next, first heat treatment was performed to form the first crystallized film 108p1 (corresponding to FIG. 1). The heat treatment was performed with an oven apparatus in a dry air atmosphere at 350° C. for one hour. The first crystallized film 108p1 is a polycrystalline indium oxide film.

The formation steps up to this point are common to Samples A to D.

Next, the first crystallized film 108p1 was subjected to first wet etching (corresponding to FIG. 1C). The wet etching was performed with an etchant containing oxalic acid at a liquid temperature of 60° C. The processing time of the wet etching (the immersion time of the etchant) was 30 minutes for Sample A, 1 hour for Sample B, 2 hours for Sample C, and 3 hours for Sample D.

Through the above steps, Samples A to D were formed.

### <SEM Observation>

Surfaces of Samples A to D formed in the above manner were subjected to SEM observation.

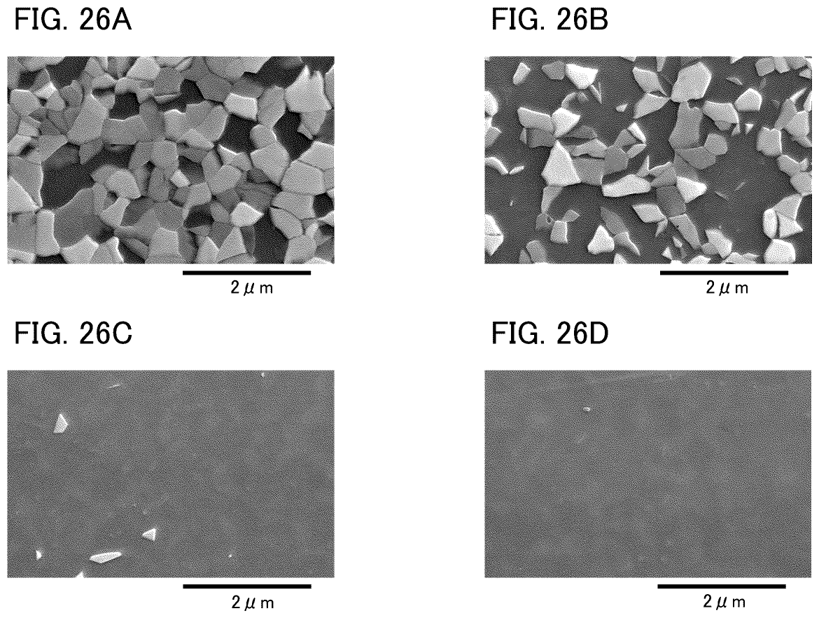

FIGS. 26A to 26D show surface SEM images of Samples A to D. FIG. 26A shows a surface SEM image of Sample A, FIG. 26B shows a surface SEM image of Sample B, FIG. 26C shows a surface SEM image of Sample C, and FIG. 26D shows a surface SEM image of Sample D. Each SEM image is a result of observation at a magnification of 25000 times.

As shown in FIGS. 26A to 26D, as the processing time for wet etching becomes longer, remaining crystal grains tends to decrease in number and size. It is suggested that among crystal grains with random orientations included in the first crystallized film 108p1, etching probably proceeds earlier on crystal grains with the crystal orientation having a higher etching rate. It was found that grains with a size of several hundreds of nanometers were slightly scattered when the processing time was 2 hours (FIG. 26C), but almost all the crystal grains were etched when the processing time was 3 hours (FIG. 26D).

### <EBSD Measurement>

Among Samples A to D, the sample C (FIG. 26C) in which slightly remaining crystal grains were observed by the above SEM observation was subjected to EBSD measurement.

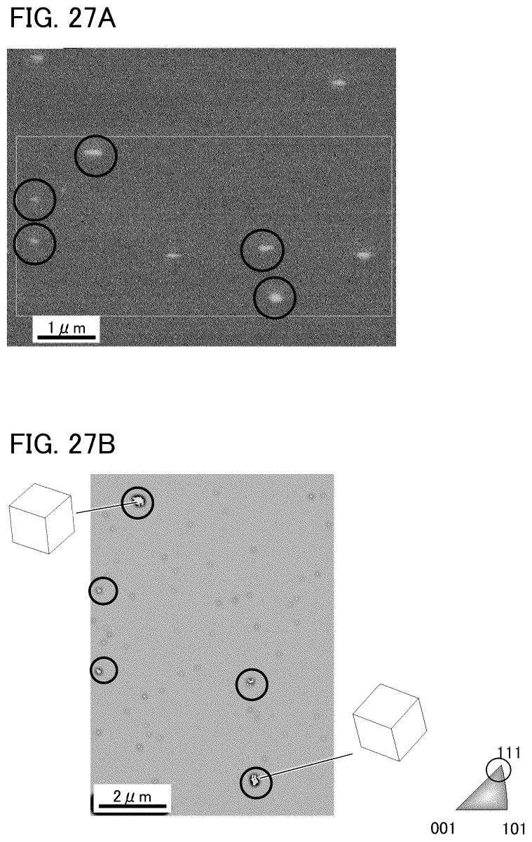

FIG. 27A shows a surface SEM image of Sample C, and FIG. 27B shows the EBSD measurement results of Sample C. In the SEM image in FIG. 27A, a region surrounded by a square frame is a measurement region of the EBSD measurement result shown in FIG. 27B. In addition, five crystal grains each surrounded by a circle in the SEM image in FIG. 27A correspond to regions each surrounded by a circle in the EBSD measurement result in FIG. 27B.

According to the EBSD measurement result, it was confirmed that the crystal grains remaining in Sample C had a crystal orientation in the vicinity of <111>. The crystal grains may correspond to the seed crystal layer 108s illustrated in FIG. 1C.

According to this example, it was confirmed that a polycrystalline indium oxide film having a randomly aligned crystal grains is subjected to wet etching with an etchant containing acid (here, oxalic acid), so that the crystal grains having a specific crystal orientation (here, the <111> orientation) with respect to the formation surface can remain.

After that, it was found that the treatment (i.e., the formation of the second amorphous film 108a2 and the second heat treatment) in FIGS. 2A1 to 2B2 enables the second amorphous film 108a2 to grow to a specific crystal orientation (here, the <111> orientation) with respect to the top surface of the crystal grain with the above crystal grain as a seed crystal. This application is based on Japanese Patent Application Serial No. 2024-195959 filed with Japan Patent Office on Nov. 8, 2024, the entire contents of which are hereby incorporated by reference.

What is claimed is:

1. A method for forming a metal oxide layer, comprising:
a first step of forming a first amorphous film;
a second step of forming a first crystallized film from the first amorphous film by first heat treatment;
a third step of removing a part of the first crystallized film by wet etching to form a seed crystal layer;
a fourth step of forming a second amorphous film over the seed crystal layer; and
a fifth step of forming a second crystallized film from the second amorphous film by second heat treatment,
wherein each of the first amorphous film, the first crystallized film, the seed crystal layer, the second amorphous film, and the second crystallized film comprises indium and oxygen,
wherein the first crystallized film comprises crystal grains having random orientations,
wherein the seed crystal layer has a first crystal orientation with respect to a formation surface, and
wherein the second crystallized film is formed of crystal grains having the first crystal orientation.

2. The method for forming a metal oxide layer, according to claim 1,
wherein each of the first amorphous film and the second amorphous film is formed by a sputtering method in an atmosphere containing oxygen and a rare gas at a substrate temperature higher than or equal to 25° C. and lower than or equal to 140° C.,
wherein each of the first heat treatment and the second heat treatment is performed in an atmosphere containing one or both of nitrogen and oxygen at a temperature higher than or equal to 150° C. and lower than or equal to 650° C., and
wherein the wet etching is performed using one or more of phosphoric acid, oxalic acid, nitric acid, and hydrochloric acid.

3. The method for forming a metal oxide layer, according to claim 1,
wherein each of the first amorphous film and the second amorphous film is formed by a sputtering method in an atmosphere containing oxygen and hydrogen at a substrate temperature higher than or equal to 25° C. and lower than or equal to 140° C.,
wherein each of the first heat treatment and the second heat treatment is performed in an atmosphere containing one or both of nitrogen and oxygen at a temperature higher than or equal to 150° C. and lower than or equal to 650° C., and
wherein the wet etching is performed using one or more of phosphoric acid, oxalic acid, nitric acid, and hydrochloric acid.

4. The method for forming a metal oxide layer, according to claim 1,
wherein the seed crystal layer comprises a seed crystal.

5. The method for forming a metal oxide layer, according to claim 1,
wherein the seed crystal layer comprises a plurality of seed crystals, and
wherein the plurality of crystals have the first crystal orientation.

6. The method for forming a metal oxide layer, according to claim 1,
wherein the first crystal orientation is <111>, and
wherein the second crystallized film has a crystal orientation of <111> with respect to a top surface of the seed crystal layer.

7. The method for forming a metal oxide layer, according to claim 2,
wherein the first crystal orientation is <111>, and
wherein the second crystallized film has a crystal orientation of <111> with respect to a top surface of the seed crystal layer.

8. The method for forming a metal oxide layer, according to claim 3,
wherein the first crystal orientation is <111>, and
wherein the second crystallized film has a crystal orientation of <111> with respect to a top surface of the seed crystal layer.

9. A transistor comprising:
a metal oxide layer formed by the method for forming a metal oxide layer according to claim 1;
an insulating layer; and
a conductive layer,
wherein the metal oxide layer comprises a region overlapping with the conductive layer with the insulating layer therebetween,
wherein the metal oxide layer is configured to serve as a channel formation region of the transistor,
wherein the insulating layer is configured to serve as a gate insulating layer of the transistor, and
wherein the conductive layer is configured to serve as a gate electrode of the transistor.
